(19) United States
(12) Patent Application Publication
(10) Pub. No.: US 2026/0143909 A1
(43) Pub. Date: May 21, 2026

(54) RECONFIGURABLE THIN-FILM PHOTONIC FILTER BANKS FOR NEUROMORPHIC OPTO-ELECTRONIC SYSTEMS AND METHODS

(71) Applicants: The Trustees of Princeton University, Princeton, NJ (US); Universal Display Corporation, Ewing, NJ (US)

(72) Inventors: Simon Bilodeau, Princeton, NJ (US); Eli A. Doris, Princeton, NJ (US); Thormas Ferreira de Lima, Princeton, NJ (US); Michael Hack, Carmel, CA (US); Paul Prucnal, Princeton, NJ (US)

(21) Appl. No.: 19/450,157

(22) Filed: Jan. 15, 2026

Related U.S. Application Data
(63) Continuation of application No. 18/050,539, filed on Oct. 28, 2022.
(60) Provisional application No. 63/280,436, filed on Nov. 17, 2021.
(60) Provisional application No. 63/318,957, filed on Mar. 11, 2022.
(60) Provisional application No. 63/318,968, filed on Mar. 11, 2022.

(51) Int. Cl. H10K 50/856; H10K 59/60; H10K 71/00

(52) U.S. Cl. CPC H10K 50/856; H10K 59/60; H10K 71/00

(57) ABSTRACT

A reconfigurable thin-film photonic filter weight bank comprises at least one photodetector and at least one optical filtering device comprising a pair of reflective thin film stacks with an interstitial medium cavity therebetween forming an optical cavity. Operation of a bank occurs when the reflective film is more selectively reflective to a range of frequencies and is more translucent to frequencies outside the range. The bank can reconfigurably weight signals by varying the cavity sizes or complex indices of refraction, with one photodetector integrating the weighted signals. Detectors can also be embedded inside the individual cavities to output unweighted, but demultiplexed, electrical signals. A neuromorphic opto-electronic system comprises a plurality of interconnected artificial optical neurons, each including at least one thin film neuromorphic opto-electronic device with a reconfigurable thin-film photonic filter weight bank. Related methods are also disclosed.

### CROSS-REFERENCE TO RELATED APPLICATIONS

This application is a continuation of U.S. patent application Ser. No. 18/050,539, filed on Oct. 28, 2022, now pending, which claims priority to U.S. provisional application No. 63/280,436 filed on Nov. 17, 2021, U.S. provisional application No. 63/318,957 filed on Mar. 11, 2022, and U.S. provisional application No. 63/318,968 filed on Mar. 11, 2022, each hereby incorporated herein by reference in their entirety.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety. One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

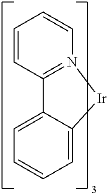

In this, and later figures herein, the dative bond from nitrogen to metal (here, Ir) is depicted as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

Over the last decade, artificial intelligence (AI) has reached expert level in image recognition, playing games, and natural language processing, among other endeavors. This is allowing the automation of increasingly more cognitive tasks, spurring ahead a new industrial revolution. Augmented reality (AR), where contextual graphics provided by AI are rendered on top of the real world, is poised to allow new spheres of human activity to benefit from the information age. A few examples include fixing mechanical systems, medicine, fieldwork, piloting aircraft, etc. However, the “motion-to-photon” (sensor to display) processing speeds of state-of-the-art AR systems is currently at least an order of magnitude too slow for a real-time overlay to appear seamless to a mobile human operator, which can in some instances cause “cybersickness.” This slow response is often referred to as latency—a delay in a system output with respect to a given input. Furthermore, the form factor and energy consumption of these systems should be kept small. A lack of real-time processing also limits other purely AI applications such as autonomous vehicles and live recognition. Despite the inadequate technology, the global AR market is expected to grow from $5.19B in 2016 to $63.95B in 2021, and even more beyond.

One way to overcome this issue is to enable the AR sensors and displays themselves to perform AI processing. By way of example the eye and brain process information differently from typical computer systems. There, networks of independent units-neurons-exchange spike signals to distill information in a highly parallel fashion. Analogous non-spiking platforms in the form of interweaved differential equations have been considered. Dubbed “neural networks,” these systems can be configured to perform computing tasks extremely quickly, simply through their dynamical evolution. The network structure determines the task that can be completed, for example classification with feedforward networks, model-predictive control with recurrent neural networks, image processing with convolutional neural networks or cellular neural network, associative memory with Hopfield networks, etc.

How strongly neurons are connected to each other in a neural network is determined by synaptic weights. In regular neural networks, the only connections are between the output of a neuron and the input of another. Before being fed as an input, the output of the first neuron is multiplied by some value—the weight. These weights between all neuron pairs can be tabulated, and in this setup are unambiguous.

Cellular neural networks (or retina-like networks, retinomorphic networks) are a restricted set of neural network topologies, whereby (a) each neuron is only allowed to communicate to other neurons that are their physical or virtual neighbors, and (b) in addition to communicating its (nonlinearly activated) internal state as for regular artificial neural networks (via an “A” template), a neuron can also communicate other properties such as its input (through a “B” template), its non-activated state (through a “C” template), and even nonlinear combinations of the above (through a “D” template). For example, if a cellular network is visualized as a two-dimensional grid containing pixels, a neighborhood of size N consists of a square containing N×N pixels. While this conceptual organization of neurons is convenient for physical artificial neurons that would be organized in a 2D matrix, is not less general than the definition of a general neural network in any dimension, since N can be arbitrarily large, allowing for an arbitrary number of connections and dimensions.

In some specific neural networks, for instance cellular neural networks, it is possible for neurons to receive as inputs more than the outputs of other neurons. In that case, it becomes important to differentiate between different types of weights. Because cellular neural networks typically exhibit only nearest-neighbor connections and are translationally invariant, these different sets of weights are termed “templates”. Because traditional cellular neural networks are mainly 2D, the templates are furthermore written as matrices. For example, for first nearest-neighbour connections only, the matrix is 3×3, with the connection of any given neuron to itself being the central entry, and connections to neighbours in the corresponding entries (north on top, east on right, etc.). There is one template per type of connection. For example, the output of one neuron into the input of another (the regular weight), is often called the “A” (or feedback) template. Another popular type of connection is when some external input of one neuron is communicated to another. The corresponding weight is written in a “B” (or feedforward) template. Other, more niche, templates exist: the “C” template is the set of weights that handles communication of the internal (not nonlinearly transformed) state of a neuron; the “D” template is the weight that characterizes communication of some other nonlinear mixed function of input, output, and internal state. In the most general case, A, B, C, and D can also be nonlinear operators acting on their relevant variable instead of a simple scalar multiplication.

Although similar processes have been replicated in computing by way of computational neural networks, application of such networks to AR contexts still suffers from the same motion to photon delay phenomenon as conventional computing, albeit to a slightly lesser degree because of the increased computing efficiency of neural networks.

There have been attempts to build neural network elements using only electronics. These require a large number of electronic elements to implement the required dynamics, and when networked suffer interconnectivity problems.

An integrated neuromorphic architecture composed of LEDs and detectors was described in Y. Nitta, J. Ohta, S. Tai & K. Kyuma, “Optical neurochip for image processing,” Electronics and Communications in Japan, Part 2 (Electronics), Vol. 78, No. 1, pp. 10-20, January 1995 and related articles. At the time, all-electrical analog neural networks were very popular. Optical neural networks also existed, but these were based on free-space interconnections. In such schemes, an array of light sources is illuminated on a 2D (often reconfigurable) plate that modifies its transmission in space, and the output rays are focused onto an array of photodetectors to perform summing. The referenced system, termed “optical neurochip”, was basically a 1-1 integration of such spatial optical neural networks. A gallium arsenide platform was used, and reconfigurable weights were implemented via photodetectors with tunable responsivity. However, inputs were effectively one-dimensional and outputs one-dimensional. The LED in the referenced system exists only to encode (one-dimensional) inputs, each detector performs the function of multiplying an input with a weight, and summing occurs by routing all the photocurrents in each column together. The nonlinearity in the referenced system is performed in the peripheral circuitry on the summed signals in each column.

The architecture disclosed below contrasts with, and includes several advantages over, the referenced architecture. First, the disclosed architecture is implemented in a thin-film platform. Second, the disclosed architecture does not explicitly multiplex neurons row or column-wise, allowing the disclosed architecture to implement more modern neuromorphic photonic systems where neurons are integrated and localized. Embodiments of the disclosed system integrate the nonlinearity within each pixel, and in some embodiments exploit LED physics to supply streamlined nonlinearity, which was not contemplated in the referenced system. Interconnections of the disclosed system can be optical and may use various degrees of freedom of light to distinguish signals, whereas in the referenced approach, different neurons needed to be connected electrically via peripheral electronics.

The physics of a neuron impose some changes to typical neural network theory when implemented in a thin film architecture. Additionally, a lone neuron cannot do much by itself: useful processing tasks are unlocked when networking large numbers of neurons together with tunable connections. Such tunable interconnections may be electrical or optical or a combination of both, but in some embodiments, independent and/or dynamic weighting of individual inputs to neurons in a network is essential to the proper functioning of a neural network. For neurons who communicate optically, optical weights are desirable since they result in high bandwidth/low latency, increased density, and reduced complexity.

Thus, there is a need in the art for improved neuromorphic opto-electronic devices.

### SUMMARY OF THE INVENTION

Some embodiments of the invention disclosed herein are set forth below, and any combination of these embodiments (or portions thereof) may be made to define another embodiment.

In one aspect, a thin film neuromorphic opto-electronic device comprises at least one thin film photoresponsive element, and at least one deposited mirror or optical filtering device, comprising at least two reflective thin film stacks with an interstitial medium therebetween forming at least one optical cavity.

In one embodiment, the at least one mirror or optical filtering device selectively reflects a range of frequencies and is more translucent to frequencies outside the range. In one embodiment, the device further comprises a waveguide positioned above the at least one mirror or optical filtering device. In one embodiment, the waveguide is planar or out-of-plane. In one embodiment, the waveguide comprises 3D printed microoptics. In one embodiment, the device further comprises at least one OLED. In one embodiment, the at least one mirror or optical filtering device is positioned above and/or in optical communication with the photoresponsive element. In one embodiment, the size of the cavity can be controlled via a microelectromechanical system (MEMS) device. In one embodiment, the at least one photoresponsive element is positioned in the cavity. In one embodiment, the device further comprises at least one tunable complex index of refraction thin film positioned in the cavity. In one embodiment, the cavity is configured to modify the signal being received by the photoresponsive element. In one embodiment, the device further comprises a plurality of spacers positioned above and below the at least one tunable complex index of refraction thin film positioned in the cavity. In one embodiment, the spacers are index matched. In one embodiment, the at least one tunable complex index of refraction thin film comprises an electrochromic material, a thermochromic material, a photochromic material, a phase-change material, a pn junction, an epsilon zero-change system, a liquid crystal, or an electro-optic film. In one embodiment, the index of refraction of the at least one tunable complex index of refraction thin film is used to selectively tune at least one of spectral reflectance or transmission. In one embodiment, the device is configured as an optical memristor. In one embodiment, the at least one mirror or optical filtering device comprises a Bragg mirror. In one embodiment, the cavity comprises a Fabry-Perot cavity. In one embodiment, the at least one mirror or optical filtering device is configured as a bandstop filter. In one embodiment, the device is configured to provide multiple weighting regions for a source. In one embodiment, wherein the at least one mirror or optical filtering device comprises an asymmetric mirror. In one embodiment, the at least one cavity comprises a multi-cavity. In one embodiment, a plurality of the at least one deposited mirrors or optical filtering devices are positioned over a common photoresponsive element. In one embodiment, the common photoresponsive element is configured to sum different same color signals.

In another aspect, a neuromorphic opto-electronic device comprises a backplane, a thin film photoresponsive element positioned above the backplane, at least one deposited mirror or optical filtering device positioned above the film photoresponsive element, comprising at least two reflective thin film stacks with an interstitial medium therebetween forming at least one optical cavity, wherein the at least one mirror or optical filtering device selectively reflects a range of frequencies and is translucent to frequencies outside the range, an OLED positioned above the backplane and adjacent to the photoresponsive element, and a waveguide positioned above the at least one mirror or optical filtering device and the OLED, optically connecting the at least one mirror or optical filtering device and the OLED. In one embodiment, the waveguide comprises a plurality of 3D printed microoptics.

In another aspect, a product comprising the thin film neuromorphic opto-electronic device as describe above, the product selected from the group consisting of a flat panel display, a curved display, a computer monitor, a computer, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro-display, a 3-D display, a virtual reality or augmented reality display or device, a vehicle, a video wall comprising multiple displays tiled together, a theater or stadium screen, a light therapy device, and a sign.

In another aspect, neuromorphic opto-electronic device comprises a first metal or dielectric mirror, a sub-cavity tunable complex refractive index film positioned above the first mirror, a sub-cavity minimum size OLED stack positioned above the sub-cavity tunable absorber, and a second metal or dielectric mirror positioned above the sub-cavity minimum size OLED stack.

In one embodiment, the sub-cavity tunable complex refractive index film comprises a spacer layer, a first electrode layer, and an absorber layer. In one embodiment, the sub-cavity minimum size OLED stack comprises a second electrode layer, a hole transport layer, an emission layer, an electron transport layer, and a cathode layer.

In another aspect, a method of manufacturing a neuromorphic opto-electronic system comprises providing a first die or a substrate, depositing a thin film photoresponsive element on the first die or substrate, depositing a weight stack in optical communication with the photoresponsive element, depositing an anode adjacent to the weight stack on the first die or substrate, and depositing an OLED on the anode.

In one embodiment, the method further comprises forming a waveguide connecting the weight stack and the OLED. In one embodiment, the first die or substrate comprises thin film transistors or silicon based CMOS devices. In one embodiment, the waveguide is printed onto the weight stack and the OLED. In one embodiment, the waveguide is printed on a second die or a second substrate. In one embodiment, the waveguide printed on the second die or second substrate is heterogeneously integrated onto the weight stack and the OLED.

In another aspect, a neuromorphic opto-electronic system comprises a plurality of interconnected artificial optical neurons, each including at least one thin film neuromorphic opto-electronic device comprising at least one thin film photoresponsive element, and at least one deposited mirror or optical filtering device, comprising at least two reflective thin film stacks with an interstitial medium therebetween forming at least one optical cavity.

In one embodiment, the plurality of interconnected artificial optical neurons are arranged in an array or in a plurality of interconnected arrays. In one embodiment, the array has a width of greater than or equal to one neuron and a height of greater than or equal to one neuron, wherein each neuron defines a pixel. In one embodiment, a plurality of deposited mirror or optical filtering device, each comprising at least two reflective thin film stacks with an interstitial medium therebetween forming at least one optical cavity, are timed to the at least one photoresponsive element. In one embodiment, the system is configured to perform at least one of time-division multiplexing or wavelength-division multiplexing. In one embodiment, the system is configured to perform time-division multiplexing and wavelength-division multiplexing simultaneously. In one embodiment, the at least one mirror or optical filtering device selectively reflects a range of frequencies and is translucent to frequencies outside the range. In one embodiment, the system further comprises a waveguide positioned above the at least one mirror or optical filtering device, wherein the waveguide is planar or out-of-plane, and wherein the waveguide comprises 3D printed microoptics. In one embodiment, the system further comprises at least one OLED. In one embodiment, the at least one mirror or optical filtering device is positioned above and/or in optical communication with the photoresponsive element. In one embodiment, the size of the cavity can be controlled via a microelectromechanical system (MEMS) device. In one embodiment, the at least one photoresponsive element is positioned in the cavity. In one embodiment, the system further comprises at least one tunable complex index of refraction thin film positioned in the cavity. In one embodiment, the cavity is configured to modify the signal being received by the photoresponsive element. In one embodiment, the system further comprises a plurality of spacers positioned above and below the at least one tunable complex index of refraction thin film positioned in the cavity. In one embodiment, the spacers are index matched. In one embodiment, the at least one tunable complex index of refraction thin film comprises an electrochromic material, a thermochromic material, a photochromic material, a phase-change material, a pn junction, an epsilon zero-change system, or a liquid crystal. In one embodiment, the index of refraction of the at least one tunable complex index of refraction thin film is used to selectively tune at least one of spectral reflectance or transmission. In one embodiment, the device is configured as an optical memristor. In one embodiment, the at least one mirror or optical filtering device comprises a Bragg mirror. In one embodiment, the cavity comprises a Fabry-Perot cavity. In one embodiment, the at least one mirror or optical filtering device is configured as a bandstop filter. In one embodiment, the neuron is configured to provide multiple weighting regions for a source. In one embodiment, the at least one mirror or optical filtering device comprises an asymmetric mirror. In one embodiment, the at least one cavity comprises a multi-cavity.

In another aspect, a neuromorphic opto-electronic system comprises a plurality of interconnected artificial optical neurons, each including at least one thin film neuromorphic opto-electronic device comprising, a backplane, a thin film photoresponsive element positioned above the backplane, at least one deposited mirror or optical filtering device positioned above the film photoresponsive element, comprising at least two reflective thin film stacks with an interstitial medium therebetween forming at least one optical cavity, wherein the at least one mirror or optical filtering device selectively reflects a range of frequencies and is translucent to frequencies outside the range, an OLED positioned above the backplane and adjacent to the photoresponsive element, and a waveguide positioned above the at least one mirror or optical filtering device and the OLED, optically connecting the at least one mirror or optical filtering device and the OLED. In one embodiment, the waveguide comprises a plurality of 3D printed microoptics.

In another aspect, a product comprises the thin film neuromorphic opto-electronic system as described above, wherein the product is selected from the group consisting of a flat panel display, a curved display, a computer monitor, a computer, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro-display, a 3-D display, a virtual reality or augmented reality display or device, a vehicle, a video wall comprising multiple displays tiled together, a theater or stadium screen, a light therapy device, and a sign.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 shows an organic light emitting device in accordance with some embodiments.

FIG. 2 shows an inverted organic light emitting device that does not have a separate electron transport layer in accordance with some embodiments.

FIG. 3 is a diagram depicting a typical computing environment containing separate subunits in accordance with some embodiments.

FIG. 4A shows a diagram of a conventional computational neuron in accordance with some embodiments.

FIG. 4B shows a diagram of an exemplary LED neuron employing optical weights in accordance with some embodiments.

FIG. 4C shows a diagram of an exemplary LED neuron employing electronic weights in accordance with some embodiments.

FIG. 4D shows a diagram of an exemplary LED neuron employing opto-electronic weights in accordance with some embodiments.

FIG. 5 shows a diagram of an exemplary generalized device architecture in accordance with some embodiments.

FIG. 6 is a diagram depicting a conceptual example of optical weighting in accordance with some embodiments.

FIG. 7 is a diagram depicting a conceptual example of optical weighting in accordance with some embodiments.

FIG. 8 is a diagram comparing a conventional sensing pixel to a smart sensing pixel in accordance with some embodiments.

FIG. 9 shows an exemplary two-cavity stack transmission map in accordance with some embodiments.

FIG. 10 is a table of GST optical constants in accordance with some embodiments.

FIG. 11 shows plots showing an exemplary tunable transmission profile of a two-cavity weight stack in the infrared in accordance with some embodiments.

FIG. 12 shows plots showing excess computational density compared to 5 μm² imaging subpixels, for rugate filters defined in the O-band and a range of reflectivities in accordance with some embodiments.

FIG. 13 is a diagram showing an exemplary two-cavity weight stack in accordance with some embodiments.

FIG. 14 is a table showing calculated parameters and resulting specifications from specified specifications of filters used in accordance with some embodiments.

FIG. 15 is a diagram showing an exemplary neuromorphic opto-electronic device utilizing MEMS in accordance with some embodiments.

FIG. 16 shows a plot depicting exemplary effective transmission for an exemplary neuromorphic opto-electronic device in accordance with some embodiments.

FIG. 17 shows further details of an exemplary neuromorphic opto-electronic device in accordance with some embodiments.

FIG. 18 is a plot showing spectral profiles of different sources to be weighted in accordance with some embodiments.

FIG. 19 is a diagram showing example embodiments of exemplary neuromorphic opto-electronic devices in accordance with some embodiments.

FIG. 20 is a diagram showing an exemplary architecture of an exemplary neuromorphic opto-electronic device employing higher-order filters in accordance with some embodiments.

FIG. 21 is a diagram showing further details of an exemplary neuromorphic opto-electronic device in accordance with some embodiments.

FIG. 22 depicts an exemplary few-material mirror and associated simulated transmission in accordance with some embodiments.

FIG. 23 depicts an exemplary cavity and associated simulated results in accordance with some embodiments.

FIG. 24 is a plot depicting a spectrum change of an exemplary notch mirror cavity (narrowband) in accordance with some embodiments.

FIG. 25 is a plot depicting a weighting (5 nm source) of an exemplary notch mirror cavity (narrowband) in accordance with some embodiments.

FIG. 26 is a plot depicting a weighting (10 nm source) of an exemplary notch mirror cavity (narrowband) in accordance with some embodiments.

FIG. 27 is a plot depicting a weighting (full OLED source) of an exemplary notch mirror cavity (broadband) in accordance with some embodiments.

FIG. 28 shows plots relating to the higher-order filter device of FIG. 19 in accordance with some embodiments.

FIG. 29 is a plot depicting a spectrum change of an exemplary second-order notch mirror cavity (narrowband) in accordance with some embodiments.

FIG. 30 shows an enlarged section of the plot of FIG. 29 in accordance with some embodiments.

FIG. 31 is a plot depicting a weighting (5 nm source) of an exemplary second-order notch mirror cavity (narrowband) in accordance with some embodiments.

FIG. 32 is a plot depicting a weighting (10 nm source) of an exemplary second-order notch mirror cavity (narrowband) in accordance with some embodiments.

FIG. 33 is a plot depicting a weighting (full OLED source) of an exemplary higher-order notch mirror cavity (narrowband) in accordance with some embodiments.

FIG. 34 is a plot depicting a spectrum change of an exemplary higher-order notch mirror cavity (narrowband) in accordance with some embodiments.

FIG. 35 is a plot depicting a weighting (15 nm FWHM input) of an exemplary higher-order notch mirror cavity (narrowband) in accordance with some embodiments.

FIG. 36 shows plots summarizing the simulated results in accordance with some embodiments.

FIG. 37 depicts exemplary few-material mirrors and associated simulated results in accordance with some embodiments.

FIG. 38 shows exemplary simulation results when the mirrors of FIG. 37 are stacked in accordance with some embodiments.

FIG. 39 shows exemplary simulation results when the mirrors are stacked and the separation between the cavities is changed in accordance with some embodiments.

FIG. 40 shows enlarged exemplary simulation results of FIG. 39 in accordance with some embodiments.

FIG. 41 shows exemplary simulation results when the mirrors are stacked and the separation between the two green mirrors is changed in accordance with some embodiments.

FIG. 42 shows enlarged exemplary simulation results of FIG. 41 and corresponding transmission change when considering overlap of emitter and filter in accordance with some embodiments.

FIG. 43 shows enlarged exemplary simulation results of FIG. 41 and corresponding transmission change when considering overlap of emitter and filter in accordance with some embodiments.

FIG. 44 shows exemplary simulation results when the mirrors are stacked and the separation between the two green mirrors is changed in accordance with some embodiments.

FIG. 45 shows enlarged exemplary simulation results of FIG. 44 and corresponding transmission change when considering overlap of emitter and filter in accordance with some embodiments.

FIG. 46 shows enlarged exemplary simulation results of FIG. 44 and corresponding transmission change when considering overlap of emitter and filter in accordance with some embodiments.

FIG. 47 is a diagram showing details of an exemplary neuromorphic opto-electronic device in accordance with some embodiments.

FIG. 48 is a diagram showing details of an exemplary neuromorphic photoresponsive opto-electronic device in accordance with some embodiments.

FIG. 49 is a circuit diagram for an exemplary photodetector in accordance with some embodiments.

FIG. 50 is a diagram showing details of an exemplary neuromorphic opto-electronic device in accordance with some embodiments.

FIG. 51 is a diagram showing an exemplary thin-film resonant cavity-enhanced absorption modulator in accordance with some embodiments.

FIG. 52 is a plot showing a comparison the change in transmission of matched signals versus other signals in accordance with some embodiments.

FIG. 53 is a plot showing a comparison the change in transmission of matched signals versus other signals in accordance with some embodiments.

FIG. 54 is a chemical diagram for an electrochromic molecule in accordance with some embodiments.

FIG. 55 is a comparison image showing an exemplary electrochromic thin film in its colored and colorless forms in accordance with some embodiments.

FIG. 56 is a plot showing two photochromic isomers with different absorption profiles in accordance with some embodiments.

FIG. 57 is a chemical diagram for a photochromic molecule in accordance with some embodiments.

FIG. 58 depicts exemplary photochromic molecules in accordance with some embodiments.

FIG. 59 is a diagram depicting exemplary transmission through a photochromic film in accordance with some embodiments.

FIG. 60 is a diagram depicting exemplary transmission through a photochromic film embedded in an optical cavity in accordance with some embodiments.

FIG. 61 are plots showing coloring of a single photochromic-loaded cavity and fading of a single cavity in accordance with some embodiments.

FIG. 62 depicts a plot showing destructive actuation in accordance with some embodiments.

FIG. 63 is a diagram showing selective actuation in an exemplary photochromic stack in accordance with some embodiments.

FIG. 64 are plots showing simulated results for a photochromic stack in accordance with some embodiments.

FIG. 65 is a plot showing an input sawtooth wave in accordance with some embodiments

FIG. 66 are plots showing s a simulated response of a photochromic memristive system in accordance with some embodiments.

FIG. 67 are plots showing s a simulated response of a photochromic memristive system in accordance with some embodiments.

FIG. 68 is a diagram showing an exemplary emissive neuromorphic opto-electronic device in accordance with some embodiments.

FIG. 69 is a diagram showing an exemplary experimental device in accordance with some embodiments.

FIG. 70 are plots showing an exemplary experimental device's index profile in accordance with some embodiments.

FIG. 71 shows simulated spectra in accordance with some embodiments.

FIG. 72 are plots showing simulated results in accordance with some embodiments.

FIG. 73 are plots showing simulated results in accordance with some embodiments.

FIG. 74 are plots showing simulated results in accordance with some embodiments.

FIG. 75 is a diagram showing a free-space experimental approach in accordance with some embodiments.

FIG. 76 shows a planar integrated experimental approach in accordance with some embodiments.

FIG. 77 shows additional details of a free-space experimental approach in accordance with some embodiments.

FIG. 78 shows additional details of a free-space experimental approach in accordance with some embodiments.

FIG. 79 is a plot outlining Fabry-Perot resonance enhancement in accordance with some embodiments.

FIG. 80 is a diagram outlining Fabry-Perot resonance enhancement in accordance with some embodiments.

FIG. 81 is a plot showing exemplary free-spectral range in accordance with some embodiments.

FIG. 82 are plots showing calculated external versus internal resonance enhancement in accordance with some embodiments.

FIG. 83 is a diagram of an experimental free-space cavity in accordance with some embodiments.

FIG. 84 are tables outlining Bragg mirror options in accordance with some embodiments.

FIG. 85 are diagrams showing Bragg mirror options in accordance with some embodiments.

FIG. 86 is a plot showing calculated cavity decay constant in accordance with some embodiments.

FIG. 87 is a plot showing calculated resonance linewidth in accordance with some embodiments.

FIG. 88 is a diagram showing details of an integrated approach in accordance with some embodiments.

FIG. 89 is a diagram showing details of an integrated approach in accordance with some embodiments.

FIG. 90 shows a typical waveguide mode in accordance with some embodiments.

FIG. 91 shows a sub-wavelength waveguide mode in accordance with some embodiments.

FIG. 92 shows details of a slot-waveguide in accordance with some embodiments.

FIG. 93 shows details of a slot-waveguide mode in accordance with some embodiments.

FIG. 94 shows details of a photonic crystal cavity in accordance with some embodiments.

FIG. 95 a top view of exemplary slot microring configuration in accordance with some embodiments.

FIG. 96 is a plot showing a scale comparison between a microring resonator and a photonic crystal cavity.

FIG. 97 depicts a conceptual schematic of a system including imaging, processing, and display capabilities in accordance with some embodiments.

FIG. 98 shows a comparison between past and present device architectures in accordance with some embodiments.

FIGS. 99A-B shows a comparison between past and present system architectures in accordance with some embodiments.

FIGS. 100A-F depict an exemplary manufacturing process in accordance with some embodiments.

FIG. 101 depicts a general overview of an exemplary neuromorphic opto-electronic system in accordance with some embodiments.

FIG. 102 shows exemplary pixel assignment schemes in accordance with some embodiments.

FIG. 103 shows an exemplary connection neighborhood in accordance with some embodiments.

FIG. 104 shows an exemplary connection neighborhood in accordance with some embodiments.

FIG. 105A shows an example case for single time steps and unlimited wavelengths in accordance with some embodiments.

FIG. 105B shows an example non-optimal pixel neighborhood for the case of FIG. 105A.

FIG. 106A shows an example case opposite the case shown in FIGS. 105A-B for a single wavelength and unlimited time steps in accordance with some embodiments.

FIG. 106B shows an example non-optimal pixel neighborhood for the case of FIG. 106A.

FIG. 107 shows an example of simple time multiplexing in a row-by-row operation in accordance with some embodiments.

FIG. 108 illustrates the effects of weight redundancy in accordance with some embodiments.

FIG. 109 shows an experimental free-space emulation of the system of FIG. 101 in accordance with some embodiments.

FIG. 110 shows specifications of a Fraunhofer bi-directional microdisplay used for experimentation in accordance with some embodiments.

FIG. 111 shows details of a Fraunhofer bi-directional microdisplay used for experimentation in accordance with some embodiments.

FIG. 112 shows a side view of a self-imaging concept free-space scheme in accordance with some embodiments.

FIG. 113 shows a top view of a 2-mirror retroreflector in accordance with some embodiments.

FIG. 114 shows a top view of a mirror in accordance with some embodiments.

FIG. 115 shows experimental details for convolutional kernels via defocusing in accordance with some embodiments.

FIG. 116 shows a basic system-level experiment in accordance with some embodiments.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

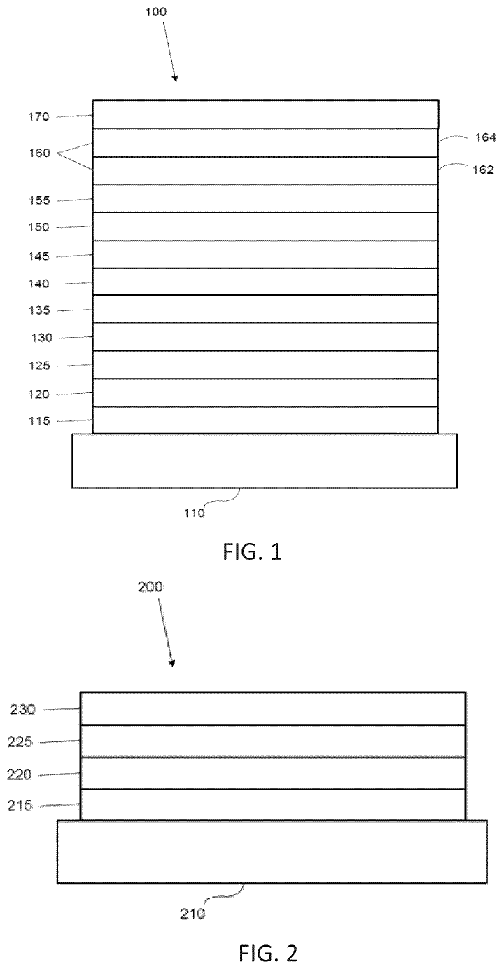

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as inkjet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers, and cameras or other devices including optical or other sensors. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, other imaging devices, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

Although exemplary embodiments described herein may be presented as methods for producing particular circuits or devices, for example OLEDs, it is understood that the materials and structures described herein may have applications in devices other than OLEDs. For example, other optoelectronic devices such as organic solar cells and organic photodetectors may employ the materials and structures. More generally, organic devices, such as organic transistors, or other organic electronic circuits or components, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a fluorescent emitter, a delayed fluorescent emitter, a phosphorescent emitter, a thermally assisted delayed fluorescent emitter (TADF) or a phosphorescent sensitized fluorescent emitter. In some embodiments, the OLED comprises a RGB pixel arrangement or white plus color filter pixel arrangement. In some embodiments, the OLED is a mobile device, a handheld device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host. In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes.

The OLED disclosed herein can be incorporated into one or more of a consumer product, an electronic component module, and a lighting panel or an imaging device. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

One aspect of the disclosure improves upon one or more techniques based on a re-entrant shadow mask disclosed in U.S. Pat. No. 6,013,538 issued on Jan. 11, 2000 to Burrows et al., the contents of which is incorporated herein by reference in its entirety.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, optically active metamaterials are defined as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

The terms “photosensitive element” and “photoresponsive element” as used in this disclosure refer to any electronic device whose electrical properties change in response to light. Examples of photosensitive elements include, but are not limited to, photodetectors, photodiodes, phototransistors, or photogates. Various exemplary embodiments of devices or systems may be presented herein including one or more particular photosensitive elements, for example photodetectors. These exemplary embodiments are not limiting, and that, as would be understood by one skilled in the art, any photosensitive element in an exemplary device may be substituted, sometimes with the addition or subtraction of additional circuitry, with another photosensitive element.

In some aspects of the present invention, a mirror and/or optical filtering device can include one or multiple layers of thin-films whose concerted action reflects some incident light, transmits some incident light, and (potentially) absorbs some incident some light. The amount of transmission, reflection, and absorption depends on the wavelength of light in general and is dictated by the filter design. Examples include but are not limited to metals, dielectric interfaces, quarter-wave stacks, rugate filters, graded-index filters, irregular discrete thin-film dielectric, optical resonators, multi-cavity optical resonators.

In some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

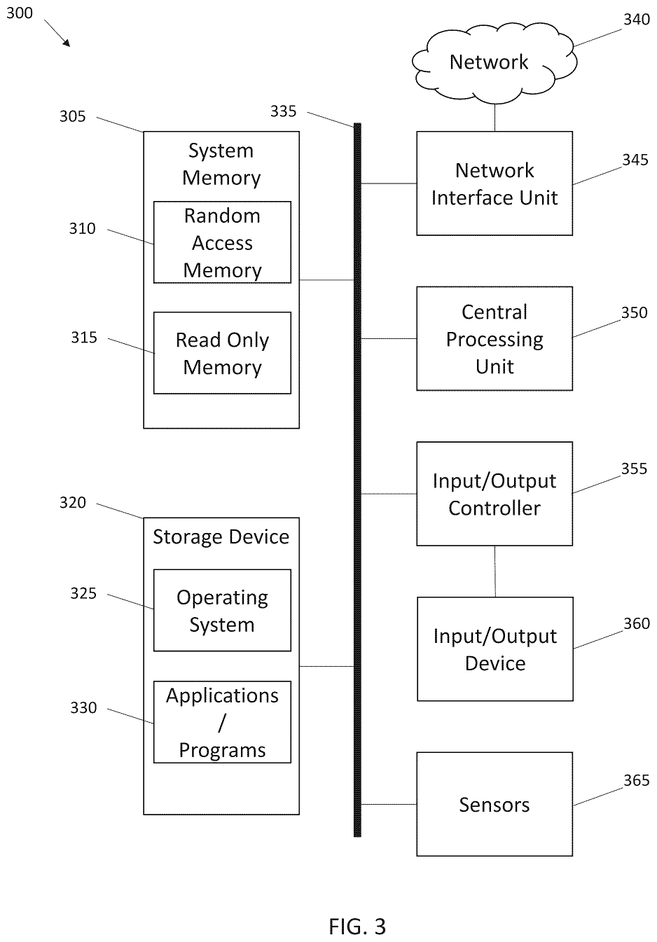

FIG. 3 and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 3 depicts an illustrative computer architecture for a computer 300 for practicing the various embodiments of the invention. The computer architecture shown in FIG. 3 illustrates a conventional personal computer, including a central processing unit 350 (“CPU”), a system memory 305, including a random-access memory 310 (“RAM”) and a read-only memory (“ROM”) 315, and a system bus 335 that couples the system memory 305 to the CPU 350. A basic input/output system containing the basic routines that help to transfer information between elements within the computer, such as during startup, is stored in the ROM 315. The computer 300 further includes a storage device 320 for storing an operating system 325, application/program 330, and data.

The storage device 320 is connected to the CPU 350 through a storage controller (not shown) connected to the bus 335. The storage device 320 and its associated computer-readable media, provide non-volatile storage for the computer 300. Although the description of computer-readable media contained herein refers to a storage device, such as a hard disk or CD-ROM drive, it should be appreciated by those skilled in the art that computer-readable media can be any available media that can be accessed by the computer 300.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 300 may operate in a networked environment using logical connections to remote computers through a network 340, such as TCP/IP network such as the Internet or an intranet. The computer 300 may connect to the network 340 through a network interface unit 345 connected to the bus 335. It should be appreciated that the network interface unit 345 may also be utilized to connect to other types of networks and remote computer systems.

The computer 300 may also include an input/output controller 355 for receiving and processing input from a number of input/output devices 360, including a keyboard, a mouse, a touchscreen, a camera, a microphone, a controller, a joystick, or other type of input device. Similarly, the input/output controller 355 may provide output to a display screen, a printer, a speaker, or other type of output device. The computer 300 can connect to the input/output device 360 via a wired connection including, but not limited to, fiber optic, ethernet, or copper wire or wireless means including, but not limited to, Bluetooth, Near-Field Communication (NFC), infrared, or other suitable wired or wireless connections.

As mentioned briefly above, a number of program modules and data files may be stored in the storage device 320 and RAM 310 of the computer 300, including an operating system 325 suitable for controlling the operation of a networked computer. The storage device 320 and RAM 310 may also store one or more applications/programs 330. In particular, the storage device 320 and RAM 310 may store an application/program 330 for providing a variety of functionalities to a user. For instance, the application/program 330 may comprise many types of programs such as a word processing application, a spreadsheet application, a desktop publishing application, a database application, a gaming application, internet browsing application, electronic mail application, messaging application, and the like. According to an embodiment of the present invention, the application/program 330 comprises a multiple functionality software application for providing word processing functionality, slide presentation functionality, spreadsheet functionality, database functionality and the like.

The computer 300 in some embodiments can include a variety of sensors 365 for monitoring the environment surrounding and the environment internal to the computer 300. These sensors 365 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

### Neural Networks

In one embodiment, the dynamics of a neuron i in a cellular neural network are given by:

$$\frac{{dx}_{i}}{dt} = - \frac{{x}_{i}}{{τ}_{i}} + {\sum }_{j} {A}_{ij} \cdot f ( {x}_{j} ) + {\sum }_{j} {B}_{ij} \cdot {u}_{j} + {I}_{i} \qquad ( 1 )$$

where j represents the group of other neurons neuron i is networked with (typically a local neighborhood in the case of cellular neural networks). By extending the neighborhood to cover all other neurons in the network and allowing only diagonal feedforward template terms (Bᵢⱼ=Bᵢᵢδᵢⱼ), “regular”, non-cellular neural networks are obtained. As such, hardware that can emulate a cellular neural network can also emulate regular artificial neural networks. Note that variations of this equation exist and can also be implemented in hardware.

Throughout this disclosure, examples may be presented in the context of one or more particular types of neural network, including but not limited to a cellular neural network, a retinomorphic neural network, a recurrent neural network, a feedforward neural network, a convolutional neural network, a generative neural network, a discriminative neural network, or a Hopfield neural network. It is understood that exemplary embodiments presented in one context are not meant to be limiting on the disclosure, and that the systems and methods disclosed herein may in some embodiments be advantageously adapted to any kind of neural network. In particular, Cellular neural networks (or retinomorphic networks) are a restricted subset of general artificial neural networks that are usually implemented via software. While these restrictions make some of the embodiments more convenient to be implemented, the examples in no way limit the proposed hardware here described. Many features described in the embodiments can be extended to general neural networks topologies by anyone skilled in the art.

This equation explains how a cell state x; evolves in time. Four effects drive the evolution: 1) a decay in time, 2) the current state of the neighbors (and itself) xⱼ through “feedback weights” Aⱼ and a nonlinear transformation f, 3) the input state (this is the input “image”) of the neighbors (and itself) uₖ through “input weights” Bₖ, and 4) some pumping (bias) Iᵢ. In some alternate models, the last three terms are nonlinearly transformed together. In one embodiment of a cellular neural network, the decay, pumping, action of the neighbors, and nonlinearity ensure that the cells evolve to one of a maximum or minimum state. As used herein, the term “neighbor” refers to any other cell the current cell can influence, including but not limited to physical neighbors. The weights are set according to what long term behavior is desired. One example is identification of closed curves by erasing open ones.

As disclosed herein, a link has been identified between the mathematics governing neural networks, including but not limited to cellular neural networks, and the dynamics of electro-optic circuits comprising organic light-emitting diodes (OLEDs), the fundamental building block of many displays today. In some embodiments, methods of the disclosed approach may be used with semiconductor light emitting diodes rather than OLEDs. By doing all or part of the computation at the sensor or display level, the motion-to-photon time could be greatly improved as compared to traditional architectures.

The disclosed approach is based on mapping form to function. Standard neuromorphic photonics exploits the natural operation of lasers, linear optical elements, photodetectors, and modulators to physically emulate brain-like signal processing. Similarly, the high density and planar nature of OLED arrays make them suited to neurophotonic processing in highly parallel ways. By doing all or part of the computation at the sensor or display level, the motion-to-photon time can be greatly improved as compared to a traditional architecture. To realize this, two approaches will be considered: general neuromorphic computing with active-matrix OLEDs, and analog “retinomorphic” image processing or display with smart pixels. In some embodiments, the neuromorphic opto-electronic device disclosed herein enables new processes, both on its own and even more so if networked.

In one embodiment, the disclosed approach forms a key building block of scalable photonic cellular neural networks. These networks may be implemented as fast massively parallel computing units. Such networks can be especially good at image processing tasks. Because embodiments of the disclosed photonic neuron are made of components already present in display units, this would be highly useful, for example in augmented reality applications.

For example, a general-purpose neuromorphic processor can be engineered using active-matrix OLEDs, organic photodetectors, and thin-film transistors. In one exemplary embodiment, a 5×5 mm, 1 million pixel display could be reconfigured as a single layer of 1,000 neurons where each neuron is connected to every other neuron in the array. This has advantages over purely electronic neuromorphic computing in that 1) the matrix architecture allows for extremely high interconnect capabilities, 2) summations may be performed optically in parallel, and 3) electronic components can implement weighting factors. In other embodiments, weighting factors may also be implemented in the optical layer. Also, while slower than state-of-the-art silicon photonic neuromorphic computing, the active-matrix OLED approach does not require advanced optics, filters, and lasers to be developed and integrated onto expensive substrates. Systems based on this approach can readily be prototyped with existing technology, largely off-the-shelf, and such systems rely on established manufactured components. All of this greatly reduces the time to commercialization. Further examples of hybrid neuromorphic computing systems and methods may be found in U.S. patent application Ser. No. 16/376,744, filed Apr. 5, 2019, and incorporated herein by reference in its entirety.

More specialized architectures are also disclosed. Inspired by the human eye, one embodiment of a system forgoes the active matrix and make each pixel independently “smart.” With photodetectors as inputs, such OLED pixel arrays could natively implement “retina-like” nearest-neighbor image processing at the source of the image. Since this forms a short time-constant dynamical system that is effectively agnostic to refresh rate, many layers could be stacked before latency becomes an issue, allowing complex computations such as convolutions to be performed quickly. In deep learning image recognition, for example, over 98% of the operations occur in the first few layers of the network. The converse problem—ultrafast reactive displays—could also be tackled, for instance by considering coherent imaging schemes within a silicon photonic backplane and the OLED as a pure display.

Embodiments of the disclosed device are made using the same fabrication procedure as for bidirectional OLED microdisplays on silicon. However, extra components—photodetectors and transistors, mainly—are assembled to give individual display elements the described functionality. The simplest specific extra electronic circuits to be added are well-known: one or more RC circuits, transimpedance amplifiers, current sources, and voltage limiters. The necessity of these components is directly mappable to the dynamics of the device.

In some embodiments, neurons disclosed herein could appear in a full-fledged network. A neural network in a display/sensor would be a natural fit for augmented reality tasks. Such a network could for instance perform real-time massively parallel image processing tasks at the image capture level. This could allow processing below the speed that causes “cybersickness” in humans, enabling augmented reality, and therefore enable the fabrication of a low latency neuromorphic processing system.

The input layer of neurons receives signals from outside instead of or in addition to other neurons. “Input neuron” as used herein means those neurons which also receive inputs from a source that is not a bias or other neurons. Anything that can be converted to an electrical or optical signal compatible with the input or next layer of neurons can work.

Specialized sensors can therefore be added to some or all of the neurons in a network as inputs. These can be from different devices (e.g. electronic sensor feeding electronic data) or can be co-integrated if made out of the same materials as the display. The latter is a feature of thin-film optically-connected neurons. For example, photodiodes of the same type as those in optically-connected neurons that take in visual information can be thin film organic or inorganic. Organic upconverters can take non-visual near-infrared light and output visible light for neural processing. Organic spectrometers can convert chemical information to localized optical signals.

In some embodiments, being able to store values for neuron elements (nonlinear units, weights, short-term memory, long-term memory, gain circuits) may be used in reconfigurable networks. Beyond local RAM, this memory can be co-integrated at the physical level at any of the levels disclosed herein. For example, an active-matrix architecture allows analog voltage values to be stored on capacitor plates. This can be used to set the responsivity of a phototransistor or the transmission of a liquid crystal filter. Analog values can also be stored in the fraction of coexisting phases of matter whose optical and electrical properties vary continuously based on the fraction.

In some embodiments, one or more neurons may comprise one or more reconfigurable elements, for example the nonlinear units, weights, short-term memory, long-term memory, gain circuits. Each reconfigurable unit may be changed either in real time or during an offline training session. The elements may be reconfigured either via local learning rules, global learning rules, or via external inputs. In such embodiments, a network may include a way to transmit information either in electronic form or optical form to each reconfigurable element in each neuron.

Neurons may be connected to one another via electrical connections, optical connections, or a combination of the two. In some embodiments, the primary output of an artificial neuron as disclosed herein may be an LED, which may be connected via an optical connection (for example a light pipe or waveguide) to one or more inputs of one or more other artificial neurons. In some embodiments, two neurons may be connected to one another via an electrical connection between an electrical output of a first neuron and an electrical input of a second neuron. Such electrical connections may be direct electrical connections, for example a simple wire or trace. However, the term “electrical connection” as contemplated herein also encompasses indirect electrical connections, for example an electrical connection through one or more intermediary devices. An indirect electrical connection is defined as any connection between two nodes where a change in potential at the first node results in a change in potential at the second node.

In order to be reconfigurable, each neuron may contain an electronic or photonic memory circuit and an electronic biasing circuit, composed of e.g. RAMs coupled to LUTs, much like in the hardware typified by in-memory computing. Reconfiguration information is stored and transmitted in digital form to other neurons or to the outside world. In order to simplify the memory circuits, neurons may be limited to volatile memory units that are loaded upon boot time from an external non-volatile memory unit.

In some embodiments, an array of neurons may be organized in a 2D substrate (or in “2.5D” if arranged in a stacked configuration), each with their corresponding memory units. However, it is understood that artificial neural networks need a level of plasticity (i.e. change of internal neural states or synaptic weights) in order to function properly. The plasticity rate, i.e. the rate of change in the configuration of each neuron, is often much slower than the data processing rate performed by the neural network.

The present disclosure contemplates three kinds of plasticity rules: local, nearest-neighbor, and global. The rules offer different neural-network functionalities at different speeds.

In the local plasticity rule, a circuit in a neuron will reconfigure, or “update”, itself based on the real-time data it receives as input or sends as output to other neurons. This update rule may be implemented by an electronic circuit present in a neuron, which may be fixed by fabrication or field-programmable, as in a Field Programmable Gate Array (FPGA). It is expected that a local plasticity rule would operate as fast as possible, on the order of the data rate. An example of such a rule is spike-timing-dependent plasticity (STDP), which allows the network to have unsupervised learning capabilities.

A nearest-neighbor plasticity rule is a generalization of a local plasticity rule. Here, the update rule affects not only the neuron itself, but also the neighboring neurons. Such a strategy is conducive to direct wired connections between neurons. This enables a “small-world network” topology that mimics many networks studied in both engineering and neuroscience. Systems with small-world connections display enhanced signal-propagation speed, computational power, and synchronizability. These are all desired features of a distributed reconfigurable network. Nearest-neighbor plasticity rules do not need to operate as fast as local ones. An example of a nearest-neighbor rule is rewiring a cluster of neurons to produce the same overall outputs in the event that one of them ceases to function properly.

A global plasticity rule generalizes the nearest-neighbor rules. One example of a global rule is based on the inputs and outputs of a subset of neurons in the neural network, and has the reach to affect every neuron in the network. Because such a rule is global and general, it is also the slowest. An example of such a rule in action is supervised learning, wherein the weights of hidden layers of neural networks are changed based on whether the output layer is close or not to a predetermined target.

In some embodiments, a network of neurons may comprise an addressing scheme for effective transmission of messages, parameters, or inputs to individual neurons. Generally speaking, there are two possible addressing schemes to implement reconfiguration methods with the lowest latency possible: random access or sequential access.

In a random-access connectivity pattern, a reconfiguration signal may be transmitted to any neuron in the 2D or 2.5D substrate within a deterministic amount of time. This can be implemented with well-known protocols such as Address-Event Representation (AER), used extensively in the IBM TrueNorth chip, for example. The AER is itself a simplified version of the networking protocol in the world wide web, where messages are encapsulated in packets and redirected within a network via dedicated “router” circuits. This allows low-latency messages to be transmitted from one neuron to another in the network, or from the outside world to one neuron, but it imposes significant overhead because of the encapsulation and routing. Therefore, it is fast if the rate of messages transmitted in the network is small and sparse. Otherwise, there can be congestion points in each router. A random-access communication scheme is well-suited for small networks, where most communication happens between neighboring neurons, and which very rarely require message transmission to the edges of the network.

Sequential access is an alternative to random access that offers better performance in the case where all neurons need reconfiguration at a single step. With the prior knowledge that all neurons need updating with as high a refresh rate as possible, a more appropriate addressing scheme is to not use any routing at all, which avoids encapsulation and header overhead. Instead, all the data may be packaged into a sequence of bits to be streamed to the neural network in bulk, and serialization and deserialization circuits may be used to unpack the stream and update one fraction of the neurons in a single step. As an example, this can be implemented like a scanline driving scheme commonly employed in flat panel displays, where a scan line selects a row to be updated, and data lines feed the required data in parallel to an entire row of neurons. A full neural network refresh can be performed by sequencing the updates row by row until the entire network has been reconfigured, much like a full frame refresh in a flat panel display.

Neurons in a network can be subdivided into two non-disjoint categories based on their input-output capability. They can take signal inputs from the world via optical or electronic sensors and detectors. They can also output signals to the world via light emitters, direct wires, or radio antennas.

Evidence from both the neuroscience and machine learning fields suggests that useful networks have an “input” layer, which is dedicated to taking inputs from the world, followed by one or more hidden layers, which do not have access to the world and cannot be probed directly, finally connected to an “output” layer, which displays the results of the computation or cognition to the world. Based on that, three methods are used for slicing the neural network into input and output layers. For simplicity, the input and output layers are referred to as I/O neurons, and the strategy can be applied to either input or output.

In a first method, I/O neurons can be organized at the perimeter of the network, forming a one-dimensional I/O. This is amenable to signals that are a one-dimensional time series, or a scalar time series that was deserialized for this purpose. An example of a one-dimensional time series is data coming from a set of sensors in parallel. An example of a scalar time series is an audio stream.

Another possible organization method is to arrange a 2D array of neurons in the network as potentially I/Os. This can be a subset of the entire neural network or its entirety. In this scheme, the neural network will be able to process 2D data arrays, e.g. images or video frames. It can also process a one-dimensional time series that was deserialized, allowing for finite impulse response filters or Fourier and other transforms to be performed in real-time.

A third method is to abandon the one-to-one neuromorphic mapping between the hardware neurons and the artificial neurons. In this case, a much larger artificial neural network is segmented into smaller chunks that fit the network implemented in hardware. At each processing step, each neuron is reconfigured to implement the chunk. Then, inputs are fed electronically or optically to the network and outputs are collected after the required processing time. The collected output is stored in memory either within the network (fast), or in a central processor outside (slow). The outputs are recorded because they may become inputs in subsequent steps. The process is repeated until all of the artificial network has been emulated. The final output is then displayed to the outside world via the central processor coordinating this operation. This scheme has a high latency in comparison with the others, as it requires breaking up a neural network into chunks, and reconfiguring the entire network for each processing step. But it offers the most flexibility in what kinds of network it can simulate.

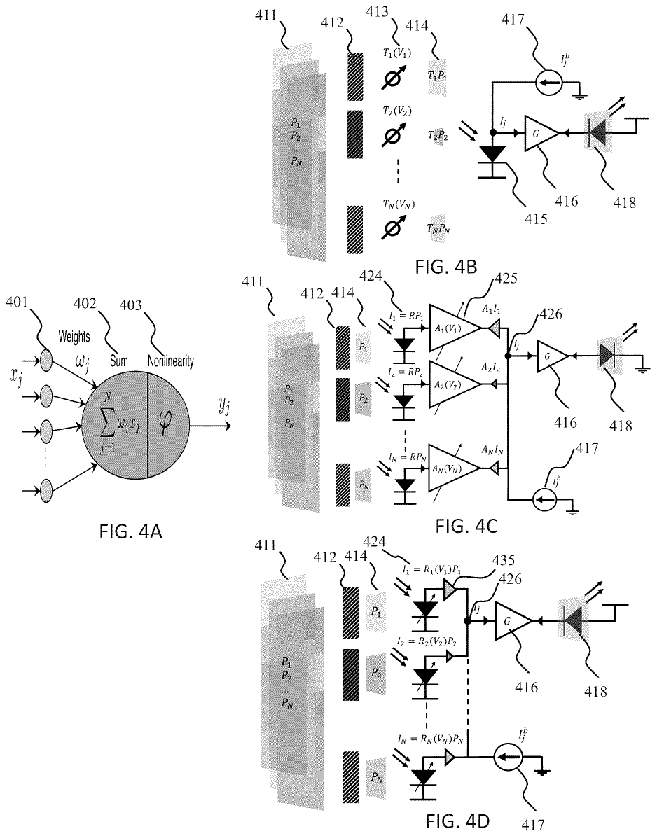

An embodiment of a thin-film optoelectronic neuron using an optical weighting scheme is shown in FIG. 4B, with FIG. 4A for reference. As shown in FIG. 4A, a conventional neuron includes a set of weighted inputs 401 which feed into a summation element 402, and then a nonlinear element 403 which determines whether to “fire” the neuron based on the summed weighted inputs. In some embodiments, the “firing” determination may be a result of diode physics (P(I), P(V)) as discussed above.

As understood herein, a summation element is an electrical, optical, or other element that takes in a plurality of inputs and provides a sum or combination of the inputs as an output. One example of a summation element is a summing amplifier or voltage adder. In other embodiments, a photodetector may act as a summation element, for example by accepting light having first and second intensities at first and second wavelengths to which the photodetector is sensitive, resulting in an electrical output roughly proportional to the sum of the intensities.

As understood herein, a nonlinear element is an electrical, optical, or other element having at least one input and at least one output, wherein the relationship between a magnitude of at least one output is not directly proportional to a magnitude of at least one input. One example of a nonlinear element is a single-input, single-output thresholding element where the output transitions from a low state to a high state, or vice versa, when the input rises above or falls below a predetermined threshold. In one embodiment, an inverter, for example a thin-film transistor inverter, may be used as a nonlinear element. In one embodiment, any other circuit having a nonlinear transfer function or electrical gain may be used as a nonlinear element. In a nonlinear element the output cannot be simply described as the sum of the weighted inputs, but includes some non-linear function that determines the output based on any given set of inputs. In various embodiments, a nonlinear element may be internal to a neuron or external to a neuron.

An optoelectronic implementation of this principle is shown in FIG. 4B, wherein the plurality of inputs 411 may for example be multiple wavelengths of light. These inputs 411 may be demultiplexed using color filters 412 and then may be individually weighted using variable attenuators 413, in which case |Tₖ(λ)|<1, selectively, for instance through some control voltage Vik. A single photodetector may be used to sum all the optical powers into a single photocurrent:

$${I}_{j} = {I}_{j}^{b} + {\sum }_{k}^{N} ( \int d λ {R}_{jk} ( λ ) {T}_{jk} ( λ , {V}_{jk} ) ) {P}_{k} \qquad ( 2 )$$

and hence the weighting factor wⱼₖ(Vⱼₖ)=∫dλRⱼₖ(λ)Tⱼₖ(λ, Vⱼₖ) in this scheme.

Here, optical power Pₖ and the detector Rⱼₖ are written as scalars. In practice these scalars result from emission and detection profiles (in free space), or mode overlap (with waveguides).

In one embodiment, the variable attenuators 413 may comprise liquid crystals like the ones currently used to attenuate light emitted from individual pixels or subpixels of an LCD display. Other display technologies whose operating mechanisms involve modulating light transmission can also be used, including but not limited to interferometric modulation, micro-electromechanical devices, etc. Electrochromic elements can also be used for this purpose. In some embodiments, waveguides and/or microlenses, for example 3D-printed microlenses, may be used to help route light.

The weighted, demultiplexed inputs 414 may then be fed into one or more photodetectors 415, with the resulting signal passed through optional electronics 416 (for example a continuous-time amplifier, buffer, digital controller, fire-and-reset transistors for “spiking” amplifiers, etc.). Whether or not electronics are used, LED 418 can serve the function of the nonlinear element 403 in the conventional neuron, because LED 418 will emit no light up until the input voltage (sum of weighted inputs) crosses the threshold to move the LED from zero emission into an increasing emissive mode, increasing until the underlying electronics, should they be present, reach a saturation point.

With reference to FIG. 4C, another exemplary embodiment is shown using electrical weighting for the inputs. Here, each filter 412 has an independently wired photodetector 424 for collecting the filtered light 414. The photodetector outputs are electrically connected to tunable current gain elements 425, which may be actuated by a control voltage. The outputs are then routed to a common node 426 for summing yield:

$${I}_{j} = {I}_{j}^{b} + {\sum }_{k}^{N} ( {A}_{k} ( {V}_{jk} ) \int d λ {R}_{jk} ( λ ) {T}_{jk} ( λ ) ) {P}_{k} \qquad ( 3 )$$

and so wⱼₖ(Vⱼₖ)=Aₖ(Vⱼₖ)∫dλRⱼₖ(λ)Tⱼₖ(λ) in this scheme. The tunable current gain elements may in some embodiments comprise a thin-film amplifier or transimpedance amplifier.

With reference to FIG. 4D, another exemplary embodiment is shown using in-detector weighting for the inputs. In this embodiment, the responsivity of each individually filtered linear imager 424 can be tuned externally, allowing weighting to be performed in the individual photodetector for compactness. The summing at the common node 426 in this embodiment is defined as:

$${I}_{j} = {I}_{j}^{b} + {\sum }_{k}^{N} ( \int d λ {R}_{jk} ( λ , {V}_{jk} ) {T}_{jk} ( λ ) ) {P}_{k} \qquad ( 4 )$$

and so wⱼₖ(Vⱼₖ)=∫dλRⱼₖ(λ, Vⱼₖ)Tⱼₖ(λ) in this scheme. The detector responsivity may be adjusted for example by changing the detector bias, or by changing the gate voltage of an individual phototransistor.

In some embodiments, a bias may be applied to the neuron. A bias as understood herein is a fixed input to a neuron. Such an input may be applied optically, for example as a fixed light input, or electrically, for example as a fixed current or voltage input. In some embodiments, the recovered current can be further processed locally using for example analog electronics or local digital lookup tables.

Summing may be performed in the optical or electrical domain or both depending on the weighting scheme. If optical weighting is used, then a single photodiode can effectively sum a portion or all of the weighted signals. If electrical weighting or in-detector weighting is used, all the resulting synaptic currents can be summed by wiring the weighted outputs together. Switches can be used at this level to direct currents from individual detectors to positive and negative lines which are then subtracted before thresholding. Summing may also be accomplished with dedicated active electronics such as summing amplifiers or adders.

Excitatory and inhibitory synapses can be defined at any of the above levels. In an optical weighting configuration, dedicated optical channels can be used. In some embodiments, within the same optical channel, spectrally similar detectors with different responsivity magnitudes can be used to produce a net current with a certain polarity akin to balanced photodetectors (except with the same amount of light impinging on both detectors, differentiation must happen at the responsivity level). In one embodiment, identical detectors can sum their currents only after experimenting different amplification. In one embodiment, a single photodetector can be used in conjunction with an electrical switch to control if the current adds or subtracts with other synapses. In some embodiments, the sign of the weight can be defined in a local analog or digital processing unit.

Light routing action in networks implemented using the devices and methods disclosed herein may be implemented in various different ways. In one embodiment, the waveguiding action of the display itself (or lack thereof if patterned appropriately) is used to route light from the output of one neuron to an input of another. This can be accomplished by vertical stacking of elements and/or horizontal dielectric waveguides. In another embodiment, modulable filters, such as liquid crystal elements, may be positioned between the neurons to modulate transmission between different neurons. In some embodiments, wavelength-division multiplexing, i.e. using different colors and chromatic filters to transmit multiple signals across the same physical medium at once, can be used. For example, a given LED can transmit primarily or exclusively blue light, and blue filters can be positioned only over those detectors meant to receive the light emitted from the given LED, for example desired weight cells, neurons, or +/− photodetectors. In various embodiments, two, three, four, five, six, seven, eight, nine, ten, fifteen, twenty, or more distinct colors of light may be used, and all the different color channels can be configured to share the same physical path (e.g. waveguide). In some embodiments, visible light may be used, but in other embodiments, infrared light, ultraviolet light, or any wavelength or set of wavelengths generatable, filterable, and or detectable may be used, alone or in combination with visible light.

In some embodiments, multiple polarizations of light may be used, alternatively or in combination with wavelength-division multiplexing, to convey multiple channels along the same medium. These can be obtained by filtering light after emission and before detection, as well as by using emitters and detectors of different spectral profiles. This can be achieved with distinct materials or different device geometries (e.g. cavity effects, material thicknesses, etc.). Wavelength and polarization filtering can be achieved with chemical (e.g. thin-film molecular filters) or physical (e.g. nanophotonic or plasmonic structures) means. Multiple of the above methods can be combined to further diversify the available spectral responses, and hence the number of logical channels.

In addition, multiple LEDs or OLEDs could be used having different output spectra. Arrays of photodetectors could be made to detect only specific wavelengths or the light from specific OLEDs—this could be accomplished by use of color filters applied to the photodetectors or the use of different spectral sensitivity materials in different photodetectors. As discussed elsewhere in this disclosure, having neurons process different wavelengths of light in parallel increases the processing power of the network.

In some embodiments, one or more neurons as disclosed herein may be integrated into an OLED display, which may for example be driven by thin-film transistors or otherwise, for example in microdisplay form. Many physical layers of this scheme can be implemented in the growth direction (i.e., the axis normal to the display surface) to yield a multilayer neural network. This can also be used to simply exploit the third dimension for more connectivity options in a network with effectively fewer layers. In general, many states can be associated with the same neuron (for example by subpixel subdivision) to achieve an effective multilayer network.

The disclosed systems have significant advantages over purely electronic approaches. For example, it is much easier to broadcast to many distant neurons using light, because there are fewer interconnect problems, especially when using color multiplexing. Summation may be implemented passively, simply by collecting light with photodetectors. In AR applications, some or all of the computing can be done at the display level itself. In some embodiments, a global switch can be configured to reset the neurons to some predefined state. Finally, typical display electronics can be used to adjust some or all pumping and weight values, as well as to read output voltages electronically if necessary. This allows the sequential use of different weight configurations conditional on the previous ones on the refresh rate timescale, which permits a wider variety of algorithms to be implemented. Spatially variant topologies are also easy to create this way by generating different weight templates at different areas of the LED display.

Artificial neural networks are currently experiencing a renaissance under the appellation of deep learning. A key enabler for this is hardware that implements efficient linear multiply-accumulate (MAC) operations co-located with memory, which more closely emulates neural computing models than Von Neumann processors. In datacenters, where throughput is key and other metrics such as Size, Weight, and Power (SWaP) are not critical, digital solutions such as Google's TPU have been deployed to great success. At the edge, however, inputs from the environment (e.g., video from cameras) often have a much higher throughput than current mobile electronic hardware can process. In order to deal with this, data is typically digitized and sent to the cloud for processing, leading to unwanted latency and bandwidth bottlenecks in networked systems. For many environmental inputs, particularly for analog time series from sensors, signals of interest are often low-bandwidth compared to total throughput. Accordingly, a more attractive solution for this problem is to employ low-power, low-latency neural pre-processing of sensor readouts by analog neural networks. Data is then highly reduced and efficient digital processing becomes possible for edge devices. This approach can be especially effective for image sensors, where full digitization implies row/column-wise serial readout. Neural processing directly on the image acquisition plane has been pursued in order to reduce overall system latency and power consumption. Application-specific integrated circuits (ASICs) based on the cellular neural network paradigm, specialized chips such as eye trackers, and spike-based event sensors have been developed to this end.

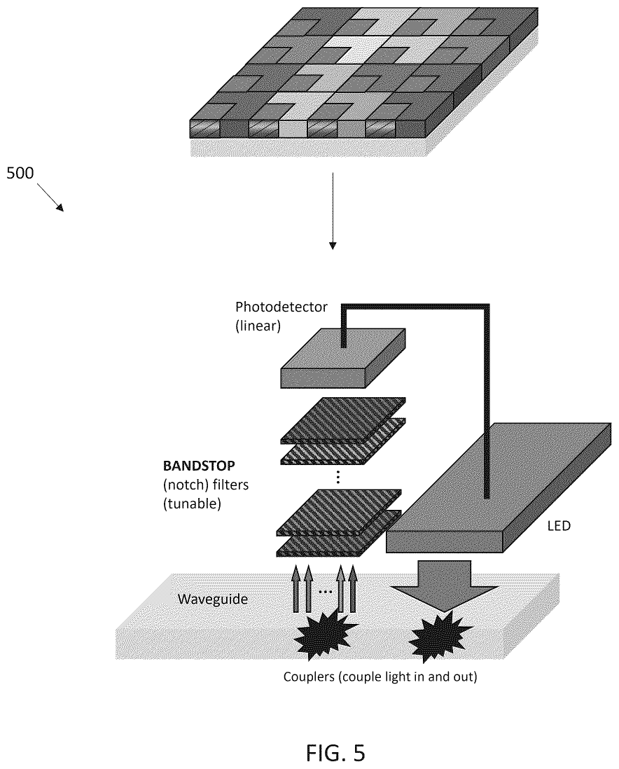

A key operation in any AI pre-processing is a weighted sum of several inputs. In the context of a 2D pixel array in an image sensor, one example is a convolutional operation, where the result at each pixel is a weighted sum of the values of the pixel and its neighbors. There are many scaling advantages in doing such an operation in the analog domain, because the processing complexity increases with O(N²) for an N×N square neighborhood. Wavelength-division multiplexed (WDM) photonics can leverage the spectral dimension of light to accommodate the equivalent of O(N) electrical wires into a single optical waveguide. An added benefit of moving from wires to waveguides is the elimination of interchannel electromagnetic cross-talk and intercomponent output impedance loading. WDM tunable interconnections still require a resonant element calibrated to each wavelength of interest within one pixel area. Thin-film technology enables the possibility to integrate these resonant elements in the vertical dimension, allowing spectral selectivity within the footprint of a single photodetector. An analogous idea has been proposed in the field of neuromorphic silicon photonics with a single bus waveguide, but here it is demonstrated that it carries the same advantages in ‘smart pixel sensors’. This concept and its contrast to conventional sensing methods is illustrated in FIGS. 5-8.

Below is described a weighted addition model and its optoelectronic implementation. The model is generalized to sources of arbitrary spectral profiles. This allows the analysis to extend to sensors.

### Multiply-Accumulate (MAC) Operations in Multiwavelength Photonics

Weighted addition is mathematically defined as:

$$y ( t ) = 〈 ω , x ( t ) 〉 = {\sum }_{i}^{N} {ω}_{i} {x}_{i} ( t ) \qquad ( 5 )$$

“Signal” vectors x(t) are dotted with “weight” vectors w, which are typically updated on considerably slower timescales than signals. In multiwavelength photonics, photodetectors can perform summation, producing a current/pp proportional to total impinging optical power P(v) via responsivity R_{PD}(v):

$${I}_{PD} ( t ) = {\int }_{- ∞}^{∞} d υ {R}_{PD} ( υ ) P ( υ , t ) \qquad ( 6 )$$

where the amplitude modulation of the power occurs on a much slower timescale than the carrier frequencies v (slowly varying envelope approximation) and thus allows it to have unambiguous time dependence. The first step to map Equation 6 to Equation 5 is to define separate signals. The spectral dimension was used to do so:

$$P ( v , t ) = {\sum }_{i}^{N} {P}_{i} ( t ) {ρ}_{i} ( v ) \qquad ( 7 )$$

Here, ρᵢ(v) is the normalized spectral profile of the source whose power amplitude Pᵢ(t) is modulated. For incoherent sources, the expression above holds for arbitrary ρᵢ(v) since powers from different sources add linearly. For coherent, narrowband sources where ρᵢ(v)→δ(v−vᵢ), but where the different carriers are incoherent respective to each other, Equation 7 holds only in so far has the separation between the vᵢ's is large enough compared to the bandwidth of Pᵢ(t) to avoid coherent interchannel beating.

A structure can be inserted between the sources and the detector to exhibit some transmission profile T(v). Then, the photocurrent becomes:

$${I}_{PD} ( t ) = {\sum }_{i}^{N} ( {\int }_{- ∞}^{∞} d υ T ( υ ) {ρ}_{i} ( υ ) {R}_{PD} ( υ ) ) {P}_{i} ( t ) \qquad ( 8 )$$

and hence an effective weight:

$${ω}_{i} ≡ {\int }_{- ∞}^{∞} d υ T ( υ ) {ρ}_{i} ( υ ) {R}_{PD} ( υ ) \qquad ( 9 )$$

performs the optoelectronic MAC operation for optical power Pᵢ. A further condition to make the signals distinct (mutually distinguishable at the detector) is that:

$${\int }_{- ∞}^{∞} d υ T ( υ ) {ρ}_{i} ( υ ) {ρ}_{j} ( υ ) {R}_{PD} ( υ ) ∝ {δ}_{ij} \qquad ( 10 )$$

To implement reconfigurable MACs, then, the task is to find a structure where T(v)=T(v,Δ) can be actuated under a set of control signals Δ. The metric of interest is contrast between weights corresponding to different signal bands, i.e. the maximum difference between wᵢ and w_{j≠i}. Equation 9 treats weighting as an absolute change in optical power that can be detected. For weighted addition, this can be normalized to actuatable detected power to account for fixed insertion losses. With a fixed maximum weight w_{i,max}, the weighting range is simply normalized to (0,1) by letting wᵢ→wᵢ/w_{i,max}. The case of nonzero minimum weight can be handled through a balanced detection scheme.

### Stackable Resonator Weights

The building block for controlling T (v) was chosen as the optical resonator, in particular the Fabry-Perot resonator. Optical cavities defined out-of-plane have long been investigated for wavelength-selective optical devices. The high sensitivity of a cavity's reflection or transmission profile on its optical path length is well-known in interferometry. Wavelength-selective field enhancement is key in enhancing absorption in resonant cavity-enhanced detectors or emission in resonant cavity-enhanced light-emitting diodes. Solid-state actuation is interesting for stacked architectures, and cavity optical lengths have successfully been tuned through e.g. morphological changes in phase-change materials, forming the basis of displays and tunable passband sensors.

Fabry-Perot cavities are most often modelled as a pair of mirrors with an interstitial propagation medium. Symmetric mirrors maximize transmission at resonance, and are in this case characterized by both a power reflectance R(v) and a phase shift φᵣ(v). A uniform cavity medium is described by length/, real refractive index n, and absorption coefficient α. The normal incidence transmission of such an arrangement is:

$${T}_{FP} ( υ , R ) = \frac{{( 1 - R ( υ ) )}^{2} {e}^{- α l}}{{( 1 - R ( υ ) {e}^{- α l} )}^{2} + 4 R ( υ ) {e}^{- α l} {sin}^{2} [ ϕ ( v ) ]} \qquad ( 11 )$$

with round-trip phase accumulation

$$ϕ ( υ ) = \frac{4 π vnl}{c} + 2 {ϕ}_{r} ( υ ) .$$

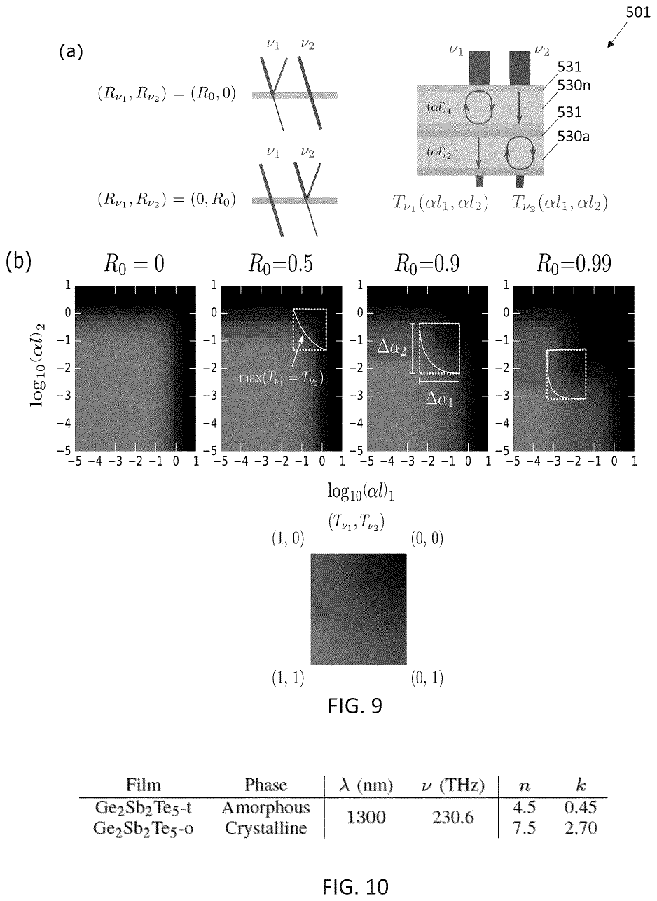

The observation here is that if the reflectances R(v) have stopband characteristic, i.e. they have reflectivity value R₀ on some finite range of the spectrum and zero elsewhere as displayed in FIG. 9, the structure behaves as a cavity only for signals in the stopband. This has implications for weighting of spectrally-separated channels, and considering stacked cavities with mirrors having specific forms of R (v) to allow for nominally independent cavities is the main thrust of this work.

Trivially, for lossless cavities, T_{FP}(v,0)=1 while T_{FP}(v,R₀) depends on n and l. This is especially effective for the coherent case ρᵢ→δ(v−vᵢ), since then wᵢ→T(vᵢ,R₀). Since the main effect of n and/on the transmission profile is to simply translate it in frequency space, this may not be as effective a weighting mechanism if the linewidth of the source is commensurate or larger than the cavity linewidth, or if the pixel is operated as a sensor. In general, however, a change in index also leads to a change in absorption (Kramers-Kronig). A changing absorption α(Δ) principally impacts the magnitude of the cavity transmission, and can therefore have a larger impact on the integral of Eq. 5 regardless of the profile of ρᵢ. However, unlike changes in n and/, changing a also adds unintentional weighting e^{-α(Δ)/} to out-of-band signals experiencing R(v)=0.

FIG. 5 shows a diagram of an exemplary generalized device architecture of a neuromorphic opto-electronic device 500. Unlike previous devices, only a single detector per neuron is required if tunable optical interconnections are defined. This has important effects on footprint, with the footprint fixed instead of growing with every added connection, and also directly translates into higher speeds through reduced capacitance. In this scheme, since all optical signals share the same spatial path and generate photocurrent in the same location, they must be differentiated by, for example, color (wavelength-division multiplexing). Hence, they must only interact with one of a plurality of filters and be unaffected by the remaining filters. In some embodiments bandstop filters are utilized. The general architecture of the device 500 includes stacked components between a photodetector and waveguide, and adjacent to an LED.

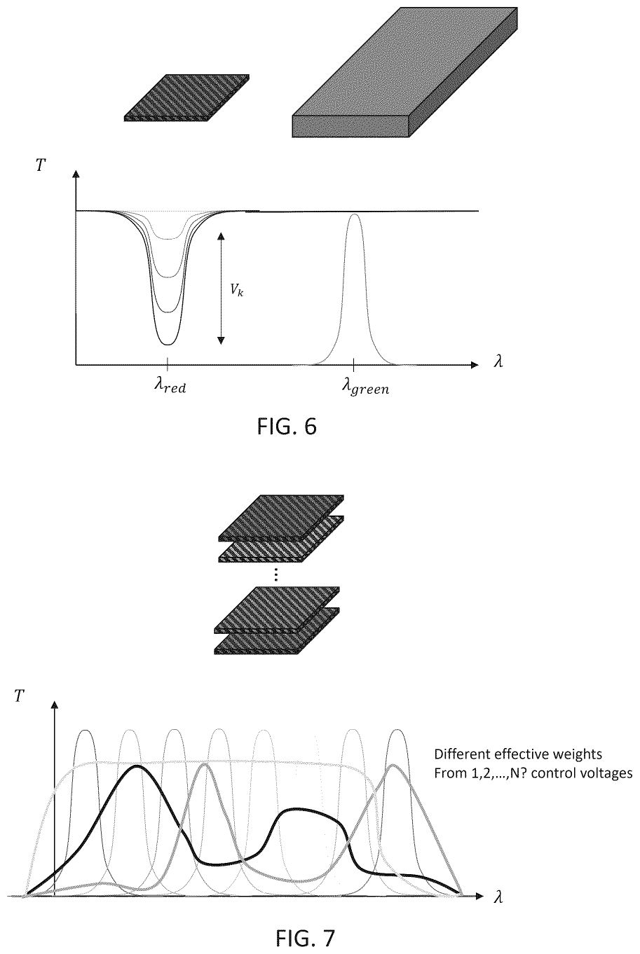

FIG. 6 and FIG. 7 show conceptual examples of optical weighting. Each neuron emits on its own color (wavelength range), and a thin-film structure can modify transmission over the entire spectrum. This implements independent weighting for signals coming from different neurons in a compact way. In the ideal case, this transmission can be changed in-situ through various means such as, for example, applied voltages. By stacking filters different effective weights can be achieved.

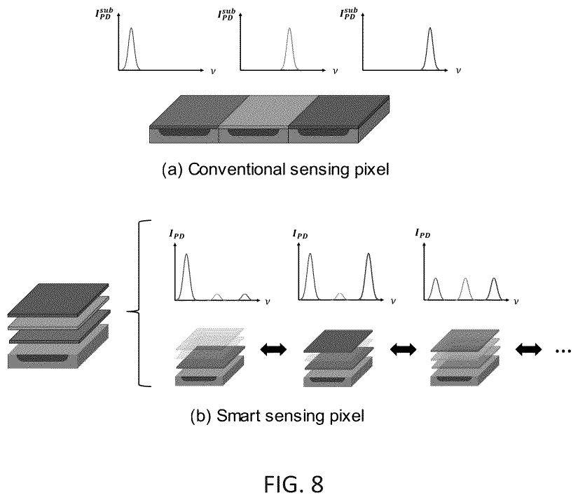

FIG. 8 shows a diagram comparing a conventional sensing pixel to a smart sensing pixel. Section (a) of FIG. 8 shows a conventional imaging/hyperspectral pixel uses one subpixel per color or frequency v to image. Each subpixel generates its own electrical signal I_{PD}^{sub}. In some embodiments, the spectral response is fixed at fabrication. Section (b) of FIG. 8 shows how a smart pixel can reconfigure the spectral response of a single photodetector with a single output I_{PD}.

FIG. 9 shows an exemplary two-cavity stack transmission map. Section (a) of FIG. 9 shows the system considered for a neuromorphic opto-electronic device 501 in some embodiment. In some embodiments, a plurality of cavities 530a-n (generally 530) lie in the same optical path. In some embodiments, the cavities 530 are comprised of frequency-selective mirrors and interstitial media of (tunable) absorption α. Section (b) of FIG. 9 shows the Transmission map as a function of absorption-length product αl of either cavity (x-y axes) and selective mirror reflectivity R₀. As the cavity mirror reflectance is increased, better transmission contrast is recovered. Given some control range Δα over α, by choosing l and R₀ appropriately, a reconfigurable detector spectral response can be engineered (white square control region). Within the regime of operation, there further exists a contour where both individual transmissions can take on some upper extremal value (white contour line).

FIG. 9 explores the effect on the transmission of two spectrally distinct signals of absorption level change in optical cavities. Each cavity 530 only has nonzero reflectance R₀ for one of the signals. If the cavities 530 were not stacked, the transmission of each signal could be independently modulated from 0 to 1 by only actuating their cavity absorption. When the cavities 530 are stacked as displayed, each signal experiences the transmission of its own cavity and regular propagation loss through the other cavity. Hence, actuating one of the cavities 530 introduces a transmission change to both signals. However, as the mirror reflectivities are increased, near-independent weighting of the signals can recover as is seen in FIG. 9 section (b). Hence, l and R₀ should be chosen so that by spanning the full range of available α's, transmissions ranging from low to high in either channel can be independently commanded (white square in FIG. 9 section (b)). The effective weighting range is further constrained by the base insertion loss when the channel in the cavity is transparent, but the other is opaque. This is represented by the contour line max (Tᵥ₁=Tᵥ₂). The actual range of transmission for which Tᵥ₁ and Tᵥ₂ can be independently set lies northeast of this contour on the plot, and this region becomes proportionally larger as the cavities reach higher unloaded Q-factors where smaller al regimes offer comparable effective weighting.

Intuitively speaking, the cavity causes signals matched to it to experience multiple round trips, and hence be more sensitive to its absorption state compared to the other cavities. For instance, exactly at resonance, the change in transmission due to a change in the absorption state of the cavity medium is:

$${\partial }_{Δ} {T}_{FP} ( {υ}_{0} , {R}_{0} ) = \frac{{l ( 1 - {R}_{0} )}^{2} ( {R}_{0} + {e}^{α ( Δ ) l} ) {e}^{α ( Δ ) l}}{{( {R}_{0} - {e}^{α ( Δ ) l} )}^{3}} {\partial }_{Δ} α \qquad ( 12 )$$

whereas out-of-band signals seeing only a single pass through the cavity experience:

$${\partial }_{Δ} {T}_{FP} ( υ , 0 ) = - l {e}^{- α ( Δ ) l} {\partial }_{Δ} α \qquad ( 13 )$$

Hence, an increased factor of sensitivity of:

$$\vert \frac{{\partial }_{Δ} {T}_{FP} ( {υ}_{0} , {R}_{0} )}{{\partial }_{Δ} {T}_{FP} ( υ , 0 )} \vert = \frac{{( 1 - {R}_{0} )}^{2} ( {R}_{0} + {e}^{α ( Δ ) l} ) {e}^{2 α ( Δ ) l}}{{( {e}^{α ( Δ ) l} - {R}_{0} )}^{3}} \qquad ( 14 )$$

can be observed. This ratio saturates to

$$\frac{1 + {R}_{0}}{1 - {R}_{0}} > 1$$

in regimes where mirror losses dominate over the propagation loss α(Δ)l. This monotonically increases with R₀, so the practical limit is defined by fabrication limitations, the physical thickness acceptable for a filter (which scales with reflectance), or detector sensitivity/integration time as detected light levels are reduced by smaller cavity linewidths. Smaller R₀ might be desirable if the cavity medium operates in a loss-dominated regime (non-unity transmission at resonance), since in this case increasing R₀ increases baseline absorption in the low absorption state.

### Stack Simulation

Numerical simulations of the transmission of a concrete resonator stack were performed to explore inline photonic weighting. The example considers signals on infrared O-band carriers, where apodized rugate filters of porous silicon can create narrowband rejection filters and tunable optical materials such as Ge₂Sb₂Te₅ are well characterized. The concept is straightforwardly extended to other wavelength bands, filter types, and materials. A minimal two-channel microcavity weight stack is investigated, but more cavities can be cascaded to weight multidimensional signals. Assuming index-matching from/to incoming and outgoing media, the structure considered here is of form: (1) Filter A, with a single rejection band about v_{0,A}=225.4 THz (1330 nm), (2) Tunable film, (3) Filter B, with dual rejection bands about v_{0,A} and v_{0,B}, (4) Tunable film, and (5) Filter C, with a single rejection band about V_{0,B}=232.4 THz (1290 nm).

Narrowband rejection filter synthesis is described in below, and is based on apodized sinusoidal index profiles. The tunable films were Ge₂Sb₂Te₅, which can be switched from a more transparent (t), amorphous phase to a more opaque (o), crystalline phase under appropriate stimulus. The optical constants of the two states are reported in the table of FIG. 10. They were considered dispersionless and of value at the quoted wavelength/frequency. Thin 5 nm layers were considered. This makes the absorption length product in this regime span 0.02 to 0.13. From FIG. 9, mirror reflectivities were constrained below ˜0.9 to ensure transmission magnitudes above ˜50% in the transparent state. To compute transmission, the standard approach of discretizing the index profiles and applying transfer matrix methods was used.

### Two-Microcavity Weight Stack Analysis

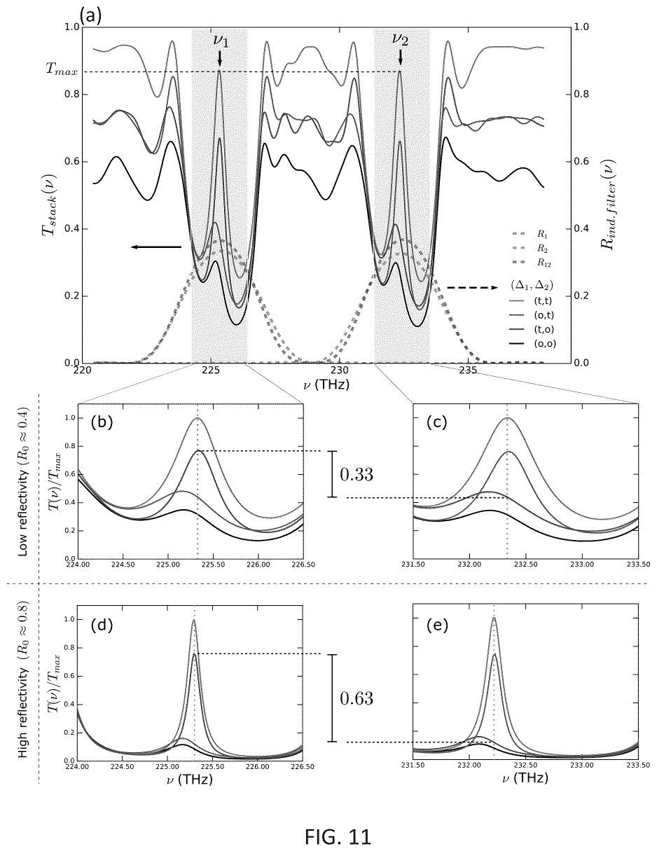

FIG. 11 shows plots showing an exemplary tunable transmission profile of a two-cavity weight stack in the infrared. Section (a) of FIG. 11 shows full transmission profiles of a stack as a function of the “extrema” of tunable PCM states (full lines): [t,t] (magenta) for both films in the amorphous, “transparent” form; [o,t] (red) and [t,o] (blue) for one of the films amorphous and the other fully “opaque”, crystallized; and [o,o] (black) for both films crystallized. The reflectivities of the filters forming the stack cavities are overlaid (dashed lines). Sections (b-c) of FIG. 11 shows transmission near cavity resonances for R₀˜0.4. Sections (d-e) of FIG. 11 shows comparisons to transmission near cavity resonances for R₀˜0.8.

FIG. 11 displays the full transmission of the weight stack in the O-band as a function of the extrema of the two tunable film states (different line colors). The filter reflectance profiles are also displayed. Large dips in transmission down to (1−R)² are observed within the stopbands of the rejection filters, with transmission being otherwise high. Inside the stopbands, transmission peaks corresponding to cavity resonances can be observed. Multiple equally-frequency-spaced resonances are present in each stopband. If the cavity length was limited to the actuatable film thickness of 5 nm, the free spectral range

$$Δ f \approx \frac{c}{2 {n}_{0} L}$$

would be in the 100's of THz, and only a single peak should be observable (if the resonance fell in the stopband at all). The ˜2 THz spacing observed here is more consistent with an effective cavity length of ˜20 μm. This matches the apodization length of the filters, which are expected to allow concomitant light penetration.

The transmission response to the tunable film states is different for both channels. The two channel regions are highlighted and presented in FIG. 11 sections (b-c). The cases (t,t) and (o,o) are simple, leading to high or low transmission in both regions. The main prediction, namely that transmission on different portions of the spectrum can be independently modulated, is confirmed by considering the cases (t,o) and (o,t). For instance, for (o,t), weight 1 matched to the v₁≈225 THz-centered cavity is made absorbing and index shifted with respect to the default high transmission state. This has a strong effect, as pictured in FIG. 11 section (b) (red curve is suppressed). Meanwhile, in FIG. 11 section (c), which focuses on the other channel at ≈232 THz, high transmission remains (red curve is high). There is nonetheless a drop from the (t,t) case in magenta due to crosstalk from the single-pass absorption. This corresponds to the curved white contour in FIG. 9 and sets the maximum independent weight (w=1).

The reciprocal (blue curve) is true when the tunable film matched to the v₂≈232 THz-centered cavity is moved away from transparency. Outside of cavity stopbands, for example around 230 THz, the red and blue curves collapse onto each other, indicating that independent weighting is not possible, highlighting the importance of the “independent” cavities.

Even for a small GST thickness of 5 nm the cavities are operating in an absorption-loss-dominated regime, as evidenced by the resonance transmission peaks being lower than unity. Increasing R₀ changes Tₘₐₓ from ≈0.9 to ≈0.65. The base crosstalk due to a single propagation into the other cavity, however, remains proportionally the same as plotted in FIG. 11 sections (d-e). What does change is the achievable contrast in transmission given a constant change in absorption. Here, nearly 2-fold increase is observed in contrast between (t,o) and (o,t) transmission at resonance. Essentially, the suppressed signal is more suppressed through its interaction with the cavity, while the unsuppressed signal always experiences the same nonenhanced propagation loss. This highlights the improvement of differential weighting with an increase in mirror reflectivity.

### Scaling Analysis

Analysis of the footprint advantages of the stacked architecture over lateral subpixels was then performed. While intuitively the light waves sharing the same propagation path should only increase density of pixels, the finite thickness of realistic filters leads to increased beam divergence going from input beam to detector backplane as compared to lateral subpixels with thin single-color filters. In the case of single-mode guiding where there is no such divergence, fundamental limits relating to interwaveguide coupling or practical fabrication considerations will limit density.

The specific metric considered is excess computational density:

$${N}_{A} = \frac{\# speactral channels {N}_{s}}{area} \qquad ( 15 )$$

This must be contrasted to the default situation with laterally defined cavities of conventional sensing pixels. This benchmark is:

$${N}_{A}^{lateral} = \frac{{N}_{s}}{{N}_{s} {P}^{2}} = \frac{1}{{P}^{2}} \qquad ( 16 )$$

since the Nₛ sensors performing the Nₛ operations occupy an overall area of NₛP², with P the pitch between the square pixels. A realistic pitch for commercial sensors is P≈5 μm², leading to a density≈0.04 channels/μm². Hence, for a stacked architecture to be more advantageous, from the point of view of footprint the condition is

$$\frac{{N}_{A}^{stack}}{{N}_{A}^{lateral}} > 1 .$$

Filter equations as described below were used to estimate thicknesses of stacked filters and extend the example from the last section (porous silicon filter in the infrared) when considering realistic values.

### Fundamental Limits

If the light routed down the weight stack can be waveguided in a single-mode fashion, for instance if the stacks also exhibit lateral index confinement, then the number of multiply-accumulate operations per area is fundamentally only limited by (1) the pitch between stacks to avoid cross-stack coupling, and (2) how spectrally narrow the cavity mirrors can be made. As an example, silicon, which is nonadsorbing for infrared light, has demonstrated porous rugate filters with n₁=0.014, which in the O-band between 1260 and 1360 nm can translate to Δλ≈10 nm. Hence, about ten cascaded spectral channels in the O-band alone are conceivable if such structures can be etched laterally into single-mode nanopillars, and potentially more if filters are made to overlap somewhat and coherent crosstalk is managed. In this case, the tightest confinement occurs for an average index close to pure silicon (≈3.5) and an interface with air. Coupling crossover lengths above ˜ mm occur with waveguide separations above 1 μm, and hence 1 stack per μm² is conceivable, leading to 10 channels per μm². This is 250× more dense than the equivalent subpixel arrangement.

### Realistic Guided Modes

In practice, if waveguides are vertically-etched, constraints on etching aspect ratio will limit pillar density. The number of MACs per area is then:

$${N}_{A}^{stack} \approx \frac{{N}_{s}}{{( {L}_{s} / {A}_{R} )}^{2}} \qquad ( 17 )$$

where Nₛ is the number of spectral channels per stack, and (Lₛ/A_{R})₂ the (approximate) effective area of a stack, which is set by its height Lₛ and the achievable etch aspect ratio A_{R}. For instance, an aspect ratio of 30:1 (achievable in deep reactive ion etching) means that for every 30 units of depth etched to form the stack, the lateral dimensions of the corresponding hole are 1 unit of depth, which determines the pitch between stacks (equivalently, one stack per etch area). Assuming a stack of Nₛ roughly identical cavities (one per spectral channel) with dual-band mirrors of length L, a stack height of:

$${L}_{s} = ( 1 + {N}_{s} ) L \approx ( 1 + {N}_{s} ) \frac{2}{{n}_{0} Δυ} \frac{c}{π} arctanh \sqrt{{R}_{0}} \qquad ( 18 )$$

is required. The rightmost relation is obtained by considering the scaling of L with n₁, which is proportional to Δv from rugate filter equations, neglecting penalties from apodization and the cavity size itself. The required filter spectral width Av can further be tied to the number of channels via Δv≈B/Nₛ for a spectral band B in which the channels are defined. For the O-band, B≈18 THz.

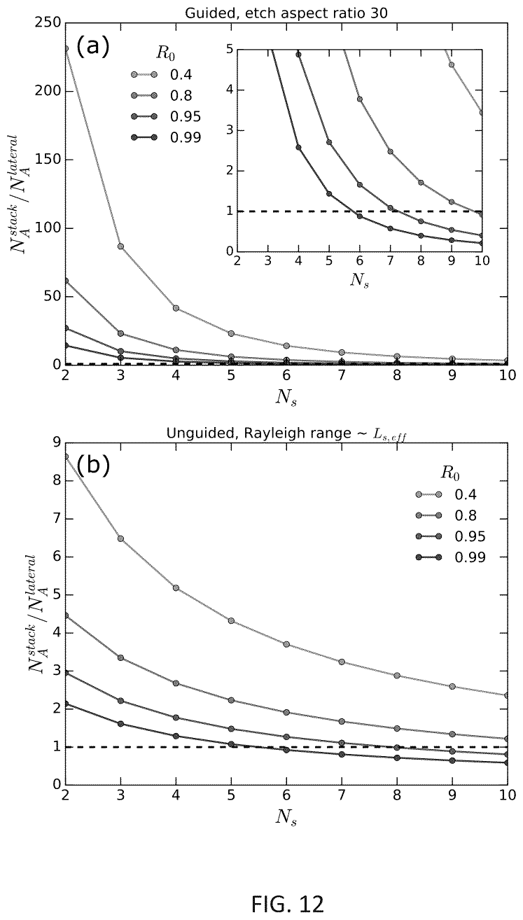

FIG. 12 shows plots showing excess computational density compared to 5 μm² imaging subpixels, for rugate filters defined in the O-band and a range of reflectivities. Section (a) of FIG. 12 shows density excess for guided modes assuming a thickness:area etch aspect ratio of 30. Section (b) of FIG. 12 shows density excess for unguided modes assuming an incoming beam waist corresponding to Rayleigh range or order stack thickness. In both cases, there are combinations of reflectivities and number of channels that yield higher spectral channel areal densities.

FIG. 12 section (a) shows the excess computational density for this B, A_{R}=30 (achievable in deep reactive ion etching, from which porous silicon filter have also been defined), n₀=3.4 (silicon in the O-band).

### Unguided Modes

Fabrication of such tight lateral confinement structures may be difficult, or undesired in order to allow for fabrication with no patterning. In this case, beam divergence must be considered in discussions of channel density. The main consideration here is ensuring the wavefronts maintain sufficient coherence for the cavities to operate as expected, a rule of thumb being that the Rayleigh range of the input beam is of order ˜L_{s,eff}, the distance the beam must travel. This effective travel distance in this case is a version of Equation 17 where travelling through the cavity is relevant as the unguided cavity round-trips cause beam divergence:

$${L}_{s , eff} = ( 1 + {N}_{s} ) L + ( \frac{1}{2} \frac{\sqrt{{R}_{0}}}{1 - {R}_{0}} - 1 ) {L}_{c} \qquad ( 19 )$$

Here, L_{c} is the effective cavity length including mirror penetration depth. Apodization of only a few cycles has been shown to effectively suppress sidebands in rugate filters, which means effective cavity lengths can be close to physical tunable medium thickness. Unless reflectivities are very large (>0.99), this term is small compared to the other if the tunable film material is thin (μm-size filters L vs nm-size tunable films L_{c}). The input beam waist w₀ that will satisfy the interference condition set above leads to a corresponding computational density of:

$${N}_{A}^{s t a c k} ∼ \frac{{N}_{s}}{{ω}_{0}^{2}} \approx {N}_{s} \frac{{υ}_{0} π}{c {L}_{s , eff}} \qquad ( 20 )$$

The result in the O-band is presented in FIG. 12 section (b).

For both etched pillars and unguided light, there is a range of reflectivities for which the unpatterned stack is more computationally dense than the equivalent subpixels i.e. for stacks containing less than the Nₛ value yielding

$$\frac{{N}_{A}^{stuck}}{{N}_{A}^{lateral} = 1}$$

(dashed line), tiling the plane with stacks allows one to perform more MAC operations than what would be possible by using laterally-separated detectors. This analysis is limits. For instance, in the unguided case the exact threshold above which interference fails is unknown. At the same time, there exist other degrees of freedom, such as angle-selective photodetectors that mitigate spatial crosstalk and can potentially allow spot sizes tighter than the Gaussian beam limit would predict.

### Manufacturability

Optical filters today are usually designed using sophisticated computer-driven algorithms. Depending on the materials and techniques available, different options are available to generate optical stopband filters. Fourier techniques generate smooth index profiles given a target reflectance. Smooth index profiles can be implemented, for instance, through co-deposition of different materials and glancing angle deposition. They can also be approximated with discrete layers, whether by using multiple layers stepping the index or through frequency-modulated digitization. Different ways of generating notch filters from limited sets of materials have also been considered, such as thickness modulation. General-purpose methods such as the needle method and more recently reinforcement learning have also been applied to the problem of finding the optimal constrained profile to generate a reflection response. Beyond deposition, some stopband filters such as porous silicon have been manufactured through electrochemical or reactive ion etching.

When manufacturing a weight stack, an important consideration will be how to alternate the addition of a filter component and a tunable index component. PCMs, for instance, can be sputtered, making them compatible with deposition-based filter manufacturing technologies. Graded index techniques that rely on microstructure voids in the material may be susceptible to pore infiltration from the tunable film material, although this is also a way to incorporate materials in cavities after fabrication as is done in sensing applications.

Tunable Films and their Actuation:

In some embodiments, integrated microelectromechanical devices can affect large changes in l (and effective n). This is exploited in traditional PICs and in display applications. Phase change materials as considered above have been heavily studied for applications in non-volatile photonics. These materials crystallize when annealed above a crystallization temperature Tc, and amorphize if quickly quenched from a melting temperature Tm. There are large changes in real and imaginary index of refraction between the two forms. The heat can be delivered via Joule heating by a current through the film, from a nearby heater, or from absorbed optical energy. Configurational changes at the molecular level are also known to be able to affect optical properties, a phenomenon known as “chromism”. Photochromism in particular occurs when the change in color is caused by photons. Some photochromic molecules, such as diarylethenes and furylfulgides, are thermally stable at room temperature. Hence, they retain their state in the absence of radiation, making them of interest for photoswitching and optical memory applications. They exist as thin films suspended in polymers or even in crystalline form, suggesting that integration is feasible. Other films have been incorporated into thin-film stacks to modify optical properties. The electronic analogue of photochromism, electrochromism, has been investigated for displays and smart lighting applications. Recently, changing carrier concentrations at thin-film interfaces, leading to changes in complex index from plasma dispersion, has also been considered for light modulation applications.

For reconfigurability, the cavities also need to be actuated in some way. Regular planar structures easily interface with electrical traces for actuation. Introducing independent electrical leads to multiple vertically-stacked cavities, while not impossible, introduces more fabrication complexity. Light controlled films are therefore of interest. The “threshold” behavior of GSTs-amorphization and crystallization being only triggered if an energy above some threshold is dissipated-simplifies the synthesis of “set”, “reset”, and “probe” pulses. Their wavelength-selective optical actuation inside optical cavities has been demonstrated, which is of interest for differential addressing without electrical contacts. Similar to what is proposed here, PCMs have been used to define neuromorphic photonic synapses, and have also been successfully integrated into stacks for display applications.

### Coherent Crosstalk

Residual reflectance outside a given stopband due to insufficient apodization, unmatched interfaces, or other filter imperfections will cause “super-cavities” to form between the resonators. When this occurs, the stack cannot be decomposed as a series of independent cavities and free propagation as was assumed throughout this manuscript. The result is spurious shifts in the transmission curves as the cavity states are actuated. This coherent crosstalk has been extensively studied in the context of microring weight banks. The consequence is another cross-weight penalty that reduces the effective weighting range. This can nonetheless be characterized and effective weighting can be achieved similarly to what was done in this manuscript for absorptive crosstalk.

### Weight Range

In deep learning and neuromorphic engineering, neural excitation and inhibition are usually captured by, respectively, positive and negative weights. Add-drop microring resonators, being 4-port devices, can efficiently route “transmitted” and “dropped” light spatially separated from the input onto two arms of a balanced photodetector to determine the sign of generated photocurrent. There is a two-fold reason why this cannot be replicated in the proposed stacked resonators: (1) a microcavity only has two spatially separated ports, and hence it is difficult to collect reflected light without disturbing the input, and (2) absorption tuning, which is present to some degree in all solid-state approaches through the Kramers-Kronig relations, does not conserve photon number. It is, however, always possible to implement negative weights by splitting the input onto two weight stacks, each of which sits on top of one arm of a balanced photodetector. The cost to do this is a 2× power penalty over the regular arrangement from the complete attenuation of a given signal in one of the stacks that is required. The components density is also lessened by 2×, and if optical weight tuning is employed, it now requires spatial resolution. A balanced detection scheme also allows weight 0 to be represented even if low transmission states have nonzero transmission.

### Stopband Filters Modelling

Consider a simple structure exhibiting a pure stopband, the apodized rugate filter. The optical properties of rugate filters are intuitively understood by solving the wave equation in a medium of index:

$$n ( z ) = {n}_{0} + {n}_{1} sin ( \frac{2 π}{Λ} z ) \qquad ( 21 )$$

with average index no and modulation index n₁<<n₀ of period Λ. The result is a complex normal incidence reflection coefficient:

$$r = \frac{- i κ sinh ( sL )}{s cosh ( s L ) + i ( Δ k / 2 ) sinh ( s L )} \qquad ( 22 )$$

with coupling constant κ=(πv/c)n₁, a wave/grating momentum mismatch Δk=2k₀−2π/Λ (with k₀=2πn₀/λ=(4πv/c)n₀), and s²=κ²−√(Δk/2)². From this, the peak reflectance amplitude |r₀|=R₀ and center frequency v₀ (when Δk=0), as well as half-max width of the stopband Δv (range for which s is real, which occurs for |Δk|<2κ) can be related to the stack design parameters n₀, n₁, Λ, and L as:

$${n}_{0} Λ = \frac{c}{4 {πυ}_{0}} \qquad ( 23 )$$

$$\frac{{n}_{1}}{{n}_{0}} = \frac{1}{2} \frac{Δυ}{{υ}_{0}} \qquad ( 24 )$$

$${n}_{1} L = arc tanh ( \vert {r}_{0} \vert ) \frac{c}{{πυ}_{0}} \qquad ( 25 )$$

where L is the thickness of the filter.

The narrowband filters above can be deposited sequentially to achieve the separated cavities. However, it is also possible to synthesize dual band rejection filters to improve compactness. Now, the profiles above are superposed as:

$$n ( z ) = {n}_{0} + {n}_{1} sin ( \frac{2 π}{{Λ}_{1}} z ) + {n}_{2} sin ( \frac{2 π}{{Λ}_{2}} z ) \qquad ( 26 )$$

where the same nᵢ and Λᵢ as for the single filter were used. Using different modulation depths is known to help with equalization of the optical densities.

An issue with the structures above is that non-negligible reflectance occurs away from this main stopband due to higher harmonics, truncation of the stack, and interfaces at the boundaries. Harmonics and truncation artefacts can be handled through multiplication of the index profile with a windowing function. A popular apodization function in optics is the following quintic, which exhibits null first and second derivatives:

$$f ( z , d ) = 10 {( \frac{z}{d} )}^{3} - 15 {( \frac{z}{d} )}^{4} + 6 {( \frac{z}{d} )}^{5} \qquad ( 27 )$$

where d is the distance over which apodization is performed and z∈[0,d]. Many other apodization functions (sine, exponential sine, Gaussian, etc.) have also been proposed. Apodization of the profile has the side effect of reducing the filter's optical density and increasing light penetration depth. For this demonstration, consider the simplest apodization scheme: the windowing of Equation 26 is applied over across the entire filter, and the filter length is doubled to compensate for the peak reflectance degradation. This function could also be used to index match at boundaries, which is not considered here.

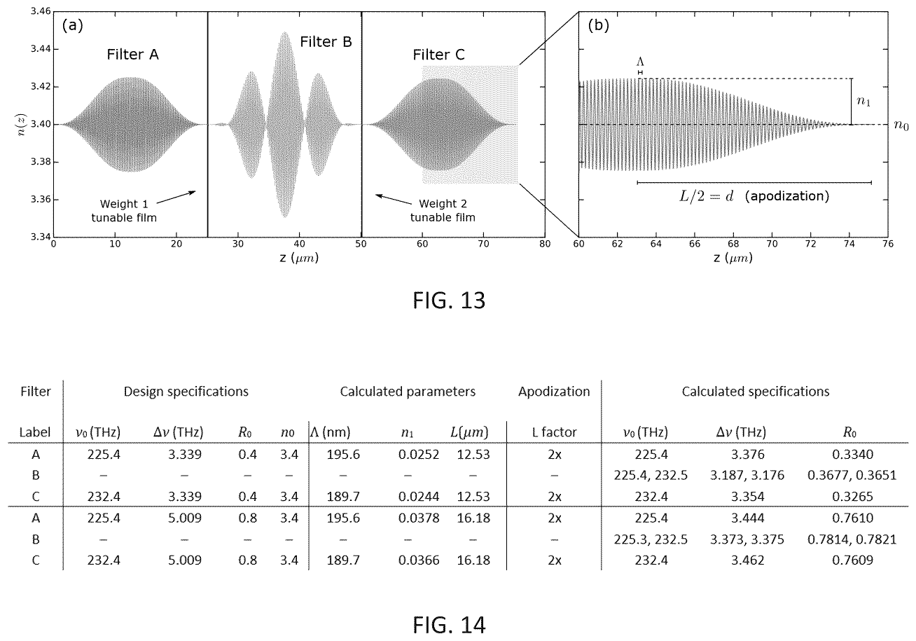

FIG. 13 is a diagram showing an exemplary two-cavity weight stack under consideration. Section (a) of FIG. 13 shows the index profile of the weight stack. The vertical black lines represent the tunable films, in this case 5 nm-thick GST films. Section (b) of FIG. 13 shows a blowup on filter with variables of interest highlighted.

FIG. 14 is a table showing calculated parameters and resulting specifications from specified specifications of filters used. The table of FIG. 14 tabulates the design parameters used to construct the filters. The corresponding physical filter structure they correspond to according to Equations 22-24 are reported under calculated parameters. As explained above, the design length is doubled and the structure fully apodized to suppress sidelobes. Filters B are dual band rejection filters matched to filters A and B, and as such use the same calculated parameters as A and B, but employ a profile generated from Eq. 25.

The reflectance profiles of the constituent filters is overlaid in FIG. 11. The resulting specifications are extracted from the reflection profiles. The design specifications are well matched to the intended specifications and out-of-band reflectance is kept below a few percent for all filters.

In some embodiments various thin-film stacks such as bandpass optical filters, broadband pass optical filters, long wave pass optical filters, short wave pass optical filters, dichroic optical filters, rejection optical filters, edge pass optical filters, and neutral density optical filters can be combined to create multiple different behaviors corresponding to different weighting matrices in a photonic neural network.

Since the optical transmission of a thin-film stack depends on the thicknesses of the layers or their indices of refraction, the ability to change the thickness of a thin-film or its index of refraction allows this functionality. MEMS devices such as Qualcomm's IMOD can move two thin film stacks relative to each other, changing thickness. On the other hand, some thin films such as blue phase liquid crystals can change the index of refraction of the film under, for example, applied voltage.

The physics of IMOD MEMS devices are such that under applied voltage, the electrostatic attraction between two mirrors separated by a small gap can be increased, and the equilibrium distance between them reduced. There is a range under which this deformation is continuous (the “released” curves, analog operation), and a critical voltage above which the two mirrors collapse onto each other (the “unstable/actuated” curves, for bistable/digital operation). Such a structure can be changed depending on the reflective behavior of both mirrors, where the transmission can be modified only on a small slice of the spectrum, leaving the rest unaffected. This occurs when the mirrors are both narrowband, i.e they only behave as mirrors on a small slice of the spectrum. Note that the transmission peak does not actually vanish, but rather is moved laterally outside of the range of interest.

In general, for a narrowband mirror, if only a discrete set of materials are available there is no intuitive structure that will only reflect wavelengths on a narrow part of the spectrum, leaving others unaffected. Optimization techniques have been developed to solve this problem.

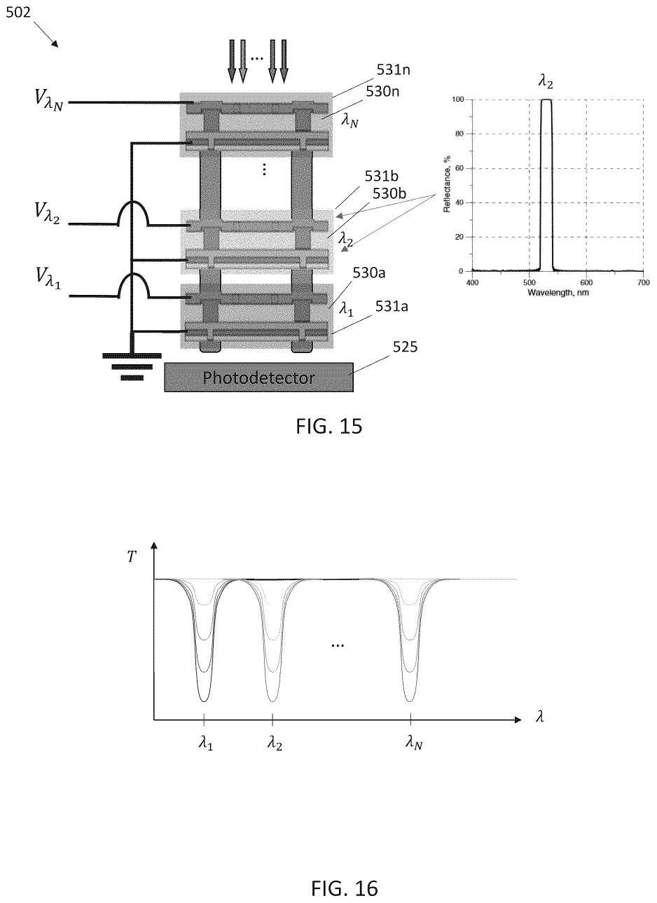

FIG. 15 is a diagram showing an example embodiment of a neuromorphic opto-electronic device 502. The device 502 includes a plurality of stacked selective mirrors (531A-N, generally 531) comprising MEMS devices, each of which includes a pair of identical narrowband mirrors, but different pairs reflect different parts of the spectrum. Under an actuation voltage, the effective transmission of different devices can be modified as displayed in FIG. 16, implementing the compact photonic synaptic device when all signals are photodetected. For effective transmission to be modified, either analog operation of the MEMS moving the filter transmission peak from or away from the emitter can be used, or the large digital transmission swing from full transmission to null transmission can be used with dithering implementing grayscale levels. If there is residual reflectance between mirrors of different MEMS devices, then a plurality of inter cavities 530a-n are formed. This is analogous to microring resonator weight banks where such coherent feedback effect has been successfully engineered away.

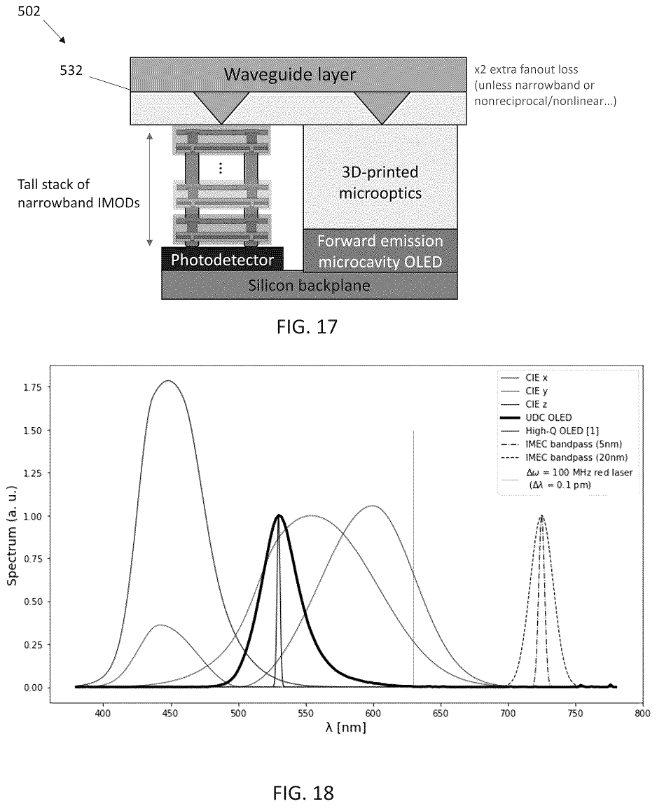

FIG. 17 shows further details of device 502. In some embodiments, light can be guided between emitters and the device 502 via a waveguide 532. The waveguide 532 can be planar or out-of-plane. In some embodiments, light emitted out of plane is guided using 3D optical structures and is taken from the OLED and focused back down onto the weighting stack.

FIG. 18 is a plot showing the spectral profiles of different sources to be weighted since in photonic multiply-accumulate operations, the detected signal depends on the overlap between the emitter profile and the cavity spectral profile. The CIE color coordinates (full color lines) are the most spectrally wide. OLEDs have varying linewidths (full black lines), with a sharp one for a metal-free microcavity structure. Filters can be placed over emitters to narrow their linewidths at the cost of efficiency (dashed lines). Finally, lasers have very sharp linewidths (thin red line).

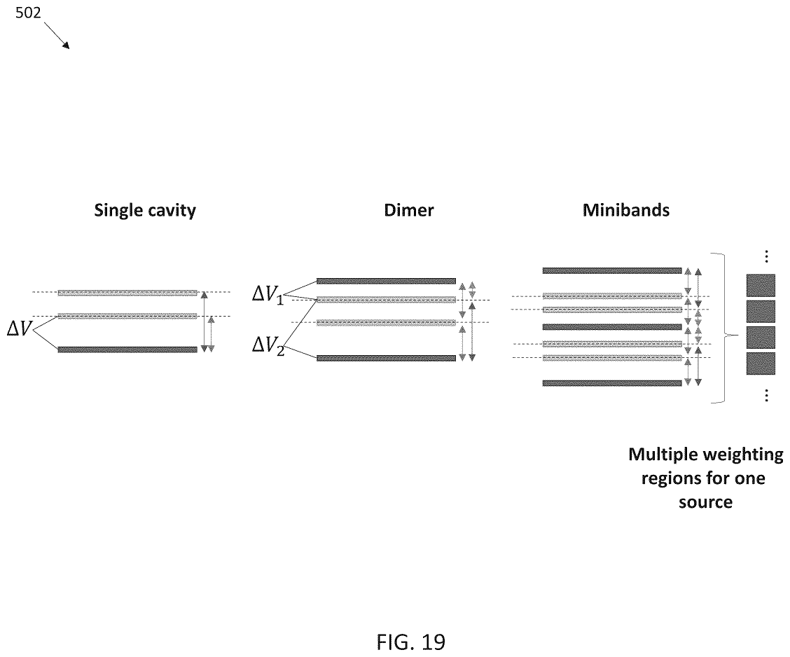

FIG. 19 shows a comparison between single cavity, dimer and miniband embodiments of device 502. Using multiple cavities instead of a single one can increase the spectral range of the cavity that performs the weighting. This allows weighting of sources with larger linewidths than the cavity.

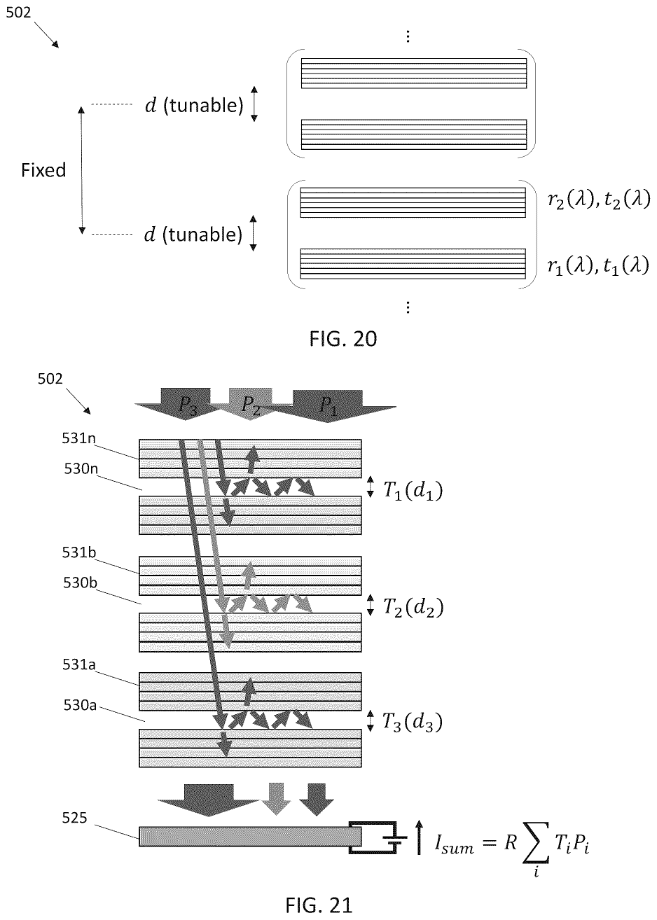

FIG. 20 is a diagram showing an exemplary architecture of an exemplary neuromorphic opto-electronic device 502. The transmission of a stack of thin-film filters can be computed using transfer matrix methods, which are implemented in many available software. These thin film stacks, in turn, can form the mirrors of optical cavities used for weighting.

Fabry-Pérot transmission is defined by:

$${T}_{IMOD} ( λ , d ) = {\vert t \vert}^{2} = \frac{{\vert {t}_{1} ( λ ) {t}_{2} ( λ ) \vert}^{2}}{{\vert 1 - {r}_{1} ( λ ) {r}_{2} ( λ ) exp ( - i 2 \frac{2 π}{λ} d ) \vert}^{2}} \qquad ( 28 )$$

and the general dielectric partially reflective mirror is defined by:

$$[ \begin{matrix}\frac{1}{{t ( λ )}^{*}} & \frac{r ( λ )}{t ( λ )} \\ \frac{{r ( λ )}^{*}}{{t ( λ )}^{*}} & \frac{1}{t ( λ )}\end{matrix} ] = \frac{1}{2 {n}_{1}} [ \begin{matrix}{n}_{1} + {n}_{0} & {n}_{1} - {n}_{0} \\ {n}_{1} - {n}_{0} & {n}_{1} + {n}_{0}\end{matrix} ] \times ( {{\prod }_{ι = 1}}^{N - 1} \dot{[ \begin{matrix}{e}^{- J \frac{2 π}{λ} {n}_{ι} {d}_{ι}} & 0 \\ 0 & {e}^{J \frac{2 π}{λ} {n}_{ι} {d}_{ι}}\end{matrix} ]} \times \frac{1}{2 {n}_{i + 1}} [ \begin{matrix}{n}_{i + 1} + {n}_{i} & {n}_{i + 1} - {n}_{i} \\ {n}_{i + 1} - {n}_{i} & {n}_{i + 1} + {n}_{i}\end{matrix} ] ) \times [ \begin{matrix}{e}^{- i \frac{2 π}{λ} {n}_{N} {d}_{N}} & 0 \\ 0 & {e}^{i \frac{2 π}{λ} {n}_{N} {d}_{N}}\end{matrix} ] \times \frac{1}{2 {n}_{∞}} [ \begin{matrix}{n}_{∞} + {n}_{N} & {n}_{∞} - {n}_{N} \\ {n}_{∞} - {n}_{N} & {n}_{∞} + {n}_{N}\end{matrix} ] \qquad ( 29 )$$

including the air-first layer interface, propagation in a given layer and next interface (repeated), and propagation in the last layer and last layer-air interface.

A large suit of materials can be used to construct the thin film filters including AlF₃, MgF₂, NdF₃, LaF₃, YF₃, GdF₃, Al₂O₃, L5, SiO₂, Substance M2, YbF₃, Substance M3, Substance M5, HfO₂, PbF₂, Na₃AlF₆, Na₅Al₃F₁₄, Y₂O₃, Substance M1, Substance L5/L5HD, CeF₃, ZrO₂, Ta₂O₅, NB₂O₅, Substances H1/H4/H4HD, Substance H8, ZnS, TiO₂, Substance H2, ITO, ZnSe, SiO, and Cr₂O₃. The same materials deposited in different ways can also exhibit different optical constants, thus offering a larger design space

Furthermore, Bragg mirrors and/or Rugate filters can also be utilized. Bragg mirrors are comprised of thin-film stacks made of alternating high and low index materials. The structure strongly reflects in the vicinity of one wavelength, with some reflection harmonics outside of this range. In one example, a thin-film filter made from a continuous index variation can be utilize where the reflection can be made strong only in one region of the spectrum.

FIG. 21 is a diagram showing further details of an exemplary neuromorphic opto-electronic device 502 utilizing stacked transmission mode interferometric modulator filter banks. The device includes a plurality of cavities 530a-n apportioned between a plurality of stacked selective mirrors 531a-n stacked above a photodetector 525. In some embodiments, the cavities 530 comprise multi-cavities. In some embodiments, optical filtering devices are utilized in place of the selective mirrors 531. The selective mirrors 531 are each configured to interact with light of separate specific wavelengths. This is facilitated by cavities 530 matched to different emitters, which is made easier with mirror pairs that do not overlap spectrally with each other. Optical weighting is preferable because a single photodetector 525 is required, thus simplifying the design, and the detector receives aggregate optical power thus increasing signal-to-noise. Furthermore, no weighting electronics are in the signal path. Materials with low optical loss in the wavelength range of interest are preferable, and relevant thicknesses will be on the order of the wavelength of the light.

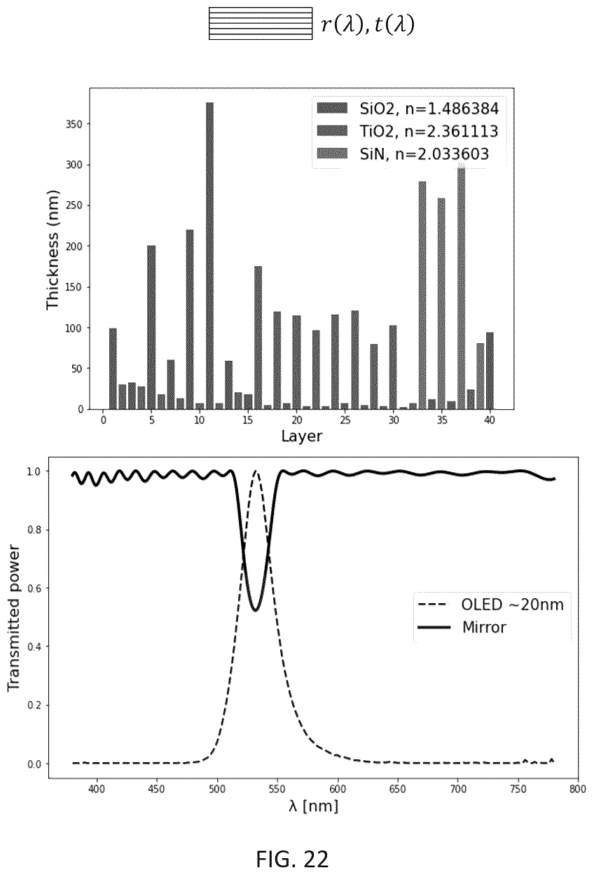

FIG. 22 depicts an exemplary notch half mirror optimized for about 532 nm and associated simulated results. Thin film mirrors rejecting more strongly on a small slice of the spectrum and being very transparent away from it (more so than Bragg mirror) can also be constructed from a discrete set of materials using optimization techniques. The central plot represents a thin film structure. Its transmission profile is shown in the lower plot, with about 50% reflection in a part of the spectrum overlapping with a hypothetical OLED emitter.

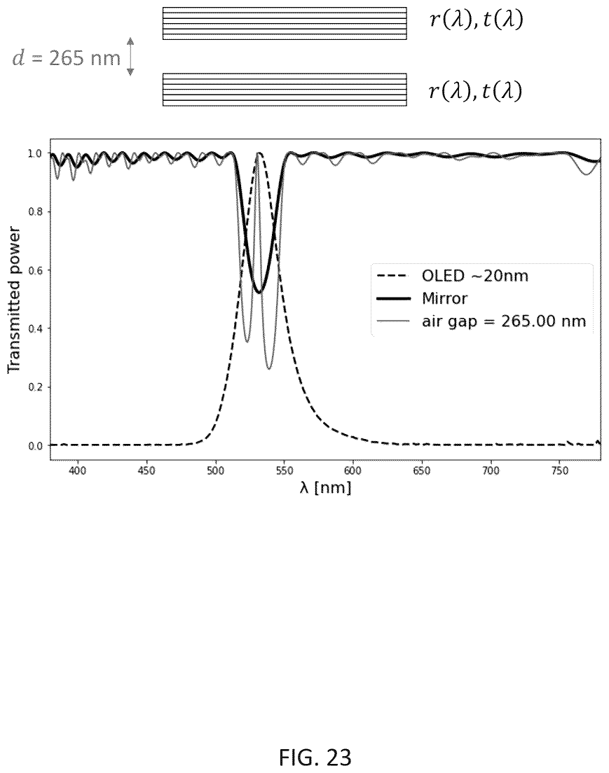

FIG. 23 depicts an exemplary cavity and associated simulated results. By using the mirror structure from FIG. 22 and repeating it after a small air gap (top), an optical cavity can be formed. Its transmission is plotted (blue curve), overlaid over the single mirror transmission (black) and a hypothetical emitter. It has similar but stronger reflection to the single mirror, except where incident light is resonant with the structure. In this case, a high transmission peak is observed.

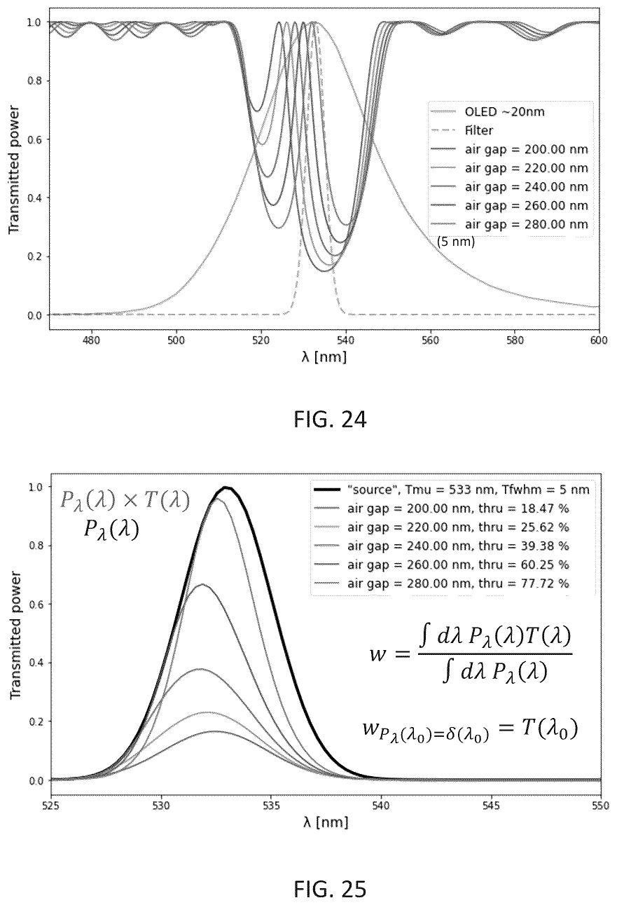

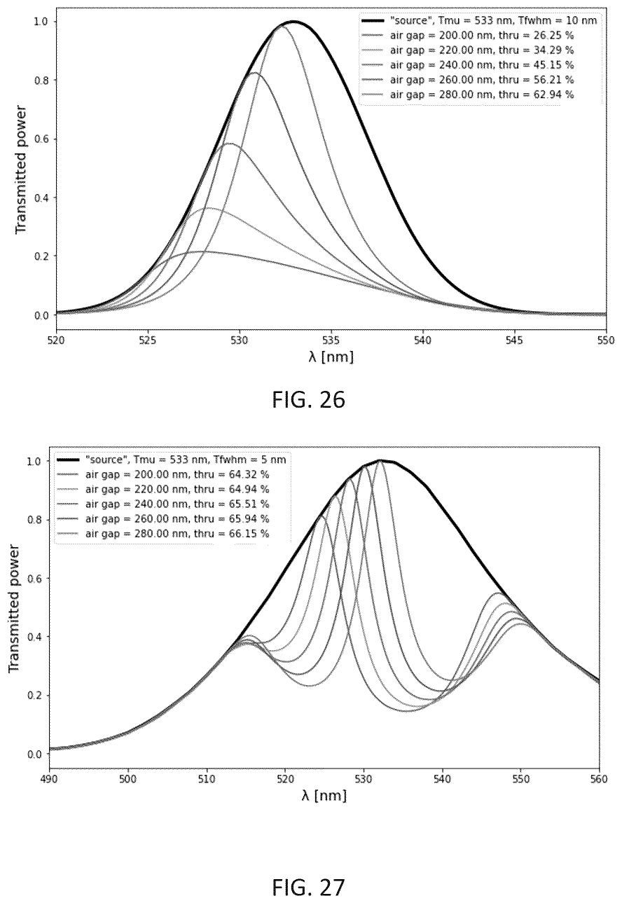

Referring now to FIGS. 24-27, plots of a simulated notch mirror cavity are shown. The weighting was evaluated as the air gap between the two mirrors made of the optimized structure in the last figures was changed. The transmission peak in FIG. 24 in the stopband of the filter is shifted in wavelength as the air gap was changed. The resulting change in overlap with a filtered source shown in FIG. 25 leads to less optical power making it through the structure, leading to weighting of the optical signal. For example, about 75% to 20% (55%) transmission contrast is shown for 80 nm motion. Repeating the last calculation, with a source effectively twice as large, is shown in FIG. 26. Weighting still occurs but is less effective. For example, about 63% to 26% (37%) transmission contrast is shown for 80 nm motion. When the emitter linewidth is much larger than the cavity, as shown in FIG. 27, the effect becomes small. For example, about 66% to 64% (2%) transmission contrast is shown for 80 nm motion.

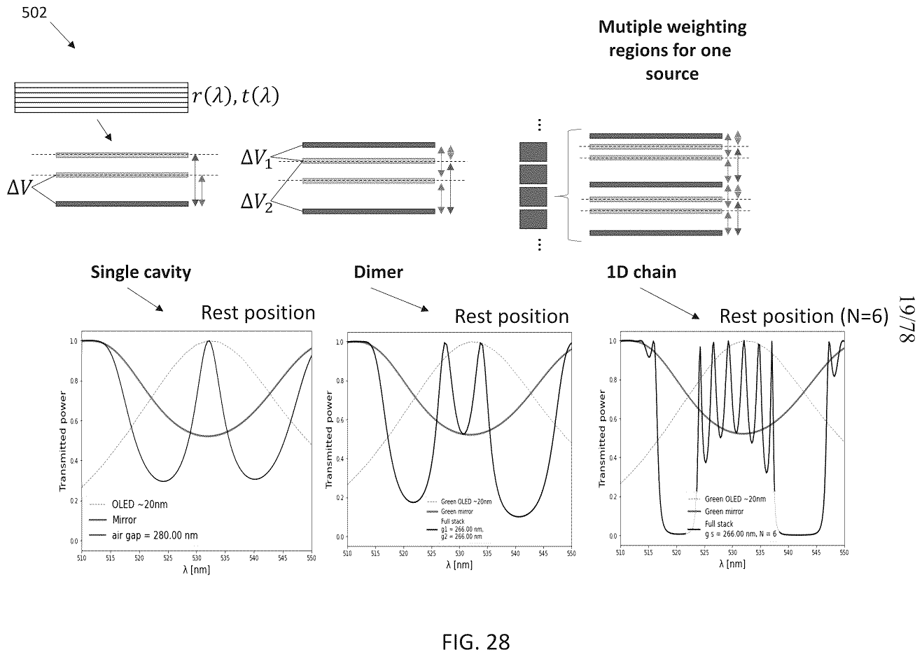

FIG. 28 shows plots relating to the device 502 of FIG. 19 showing a comparison of the configurations. The left plot shows simulated results for a single cavity, the center plot shows simulated results for two cavities with a single movable membrane, and the right plot shows simulated results for six cavities, with push-pull motion of membranes between neighboring cavities. By adopting the multicavity structure, the effective width of the cavity can be artificially increased.

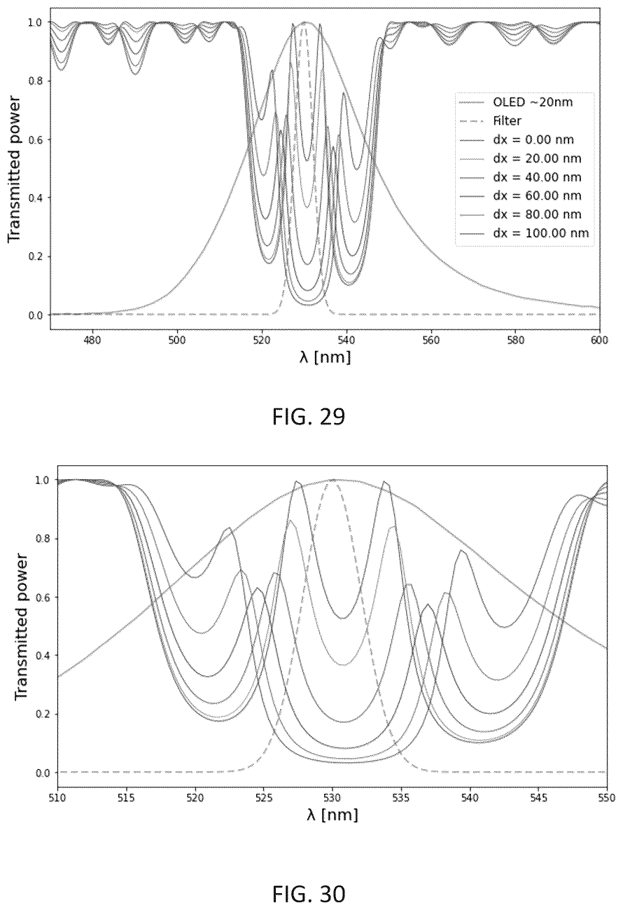

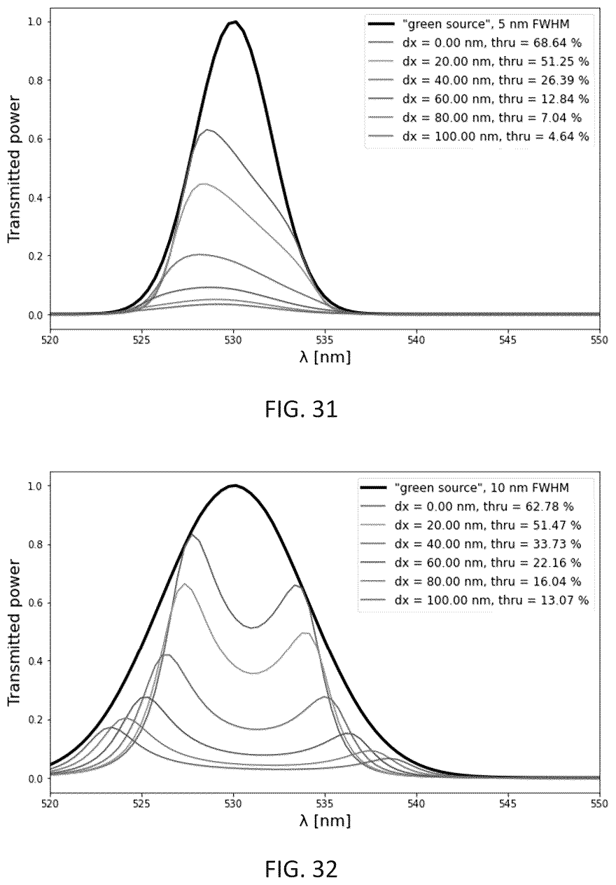

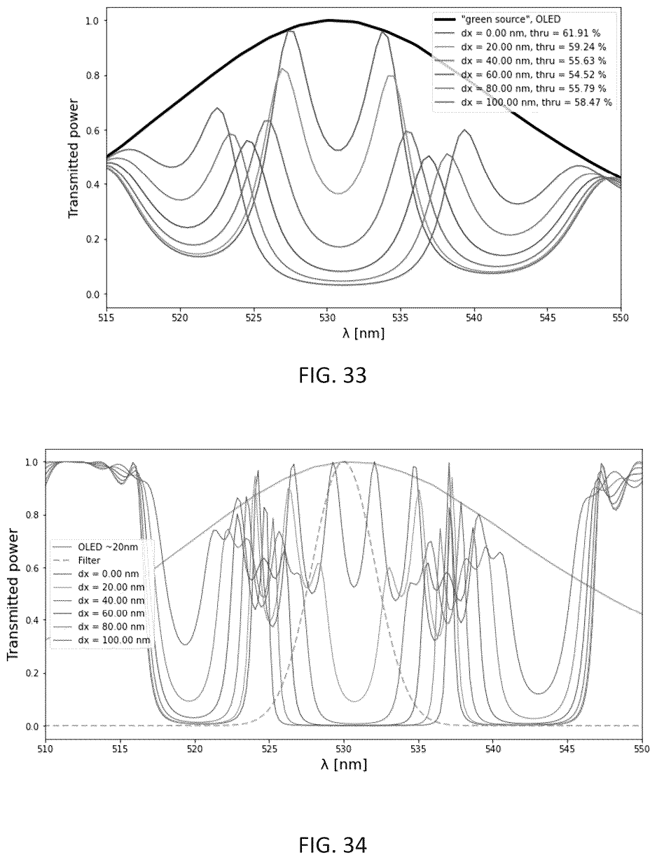

Referring now to FIGS. 29-33, plots of a simulated notch mirror cavity are shown for the dimer (2-cavity) filter. The transmission peak shown in FIG. 29 and shown enlarged in FIG. 30. The resulting change in overlap with a filtered source shown in FIG. 31 leads to less optical power making it through the structure, leading to weighting of the optical signal. Larger transmission shifts as compared to the single cavity can be observed. For example, about 69% to 7% (62%) transmission contrast is shown for 80 nm motion. Repeating the last calculation, with a source effectively twice as large, is shown in FIG. 32. Weighting still occurs but is less effective. Larger transmission shifts as compared to the single cavity can be observed. For example, about 62% to 16% (46%) transmission contrast is shown for 80 nm motion. When the emitter linewidth is much larger than the cavity, as shown in FIG. 33, the effect becomes small. Larger transmission shifts as compared to the single cavity can be observed. For example, about 62% to 54% (8%) transmission contrast is shown for 60 nm motion.

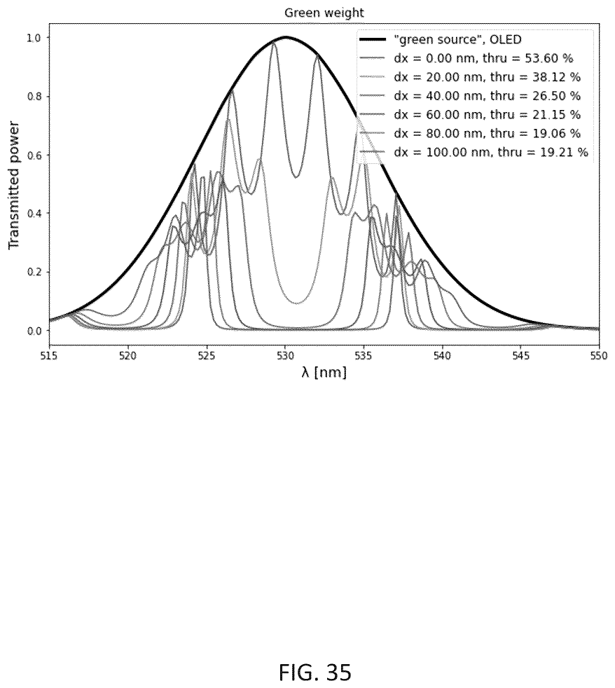

Referring now to FIGS. 34-35, plots of a simulated notch mirror N=6 cavity are shown. The transmission peak is shown in FIG. 34. The resulting change in overlap with a filtered source shown in FIG. 25 leads to less optical power making it through the structure, leading to weighting of the optical signal. For example, about 62% to 54% (8%) transmission contrast is shown for 60 nm motion. The same effect can be observed with larger number of cavities.

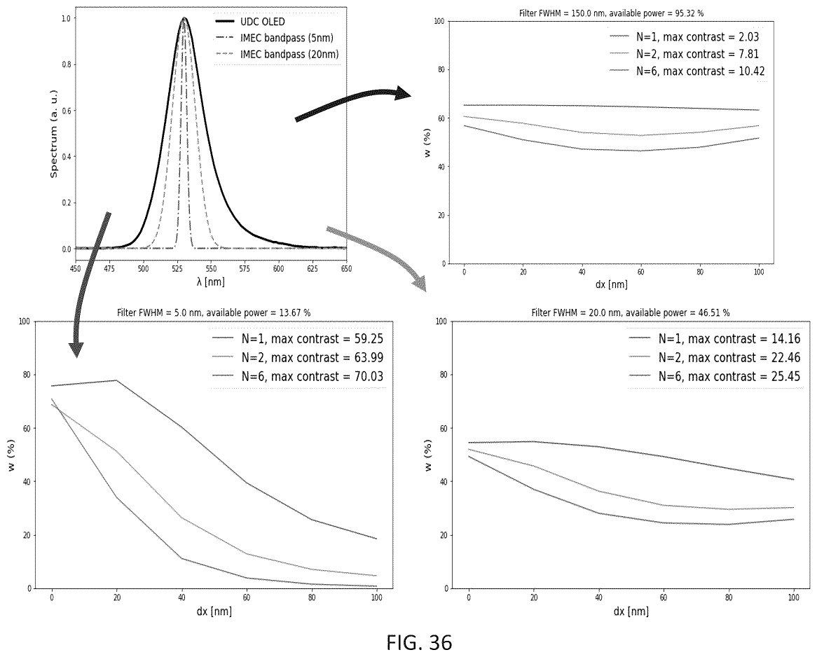

The calculations from FIGS. 24-35 are summarized in FIG. 36. For three different sources (full: black, filtered to 20 nm: green, filtered to 5 nm: red), the filtered optical power acting as a weight is plotted as a function of displacement of the mirror. The contrast is better for smaller source linewidths and can also be improved by considered multicavity schemes.

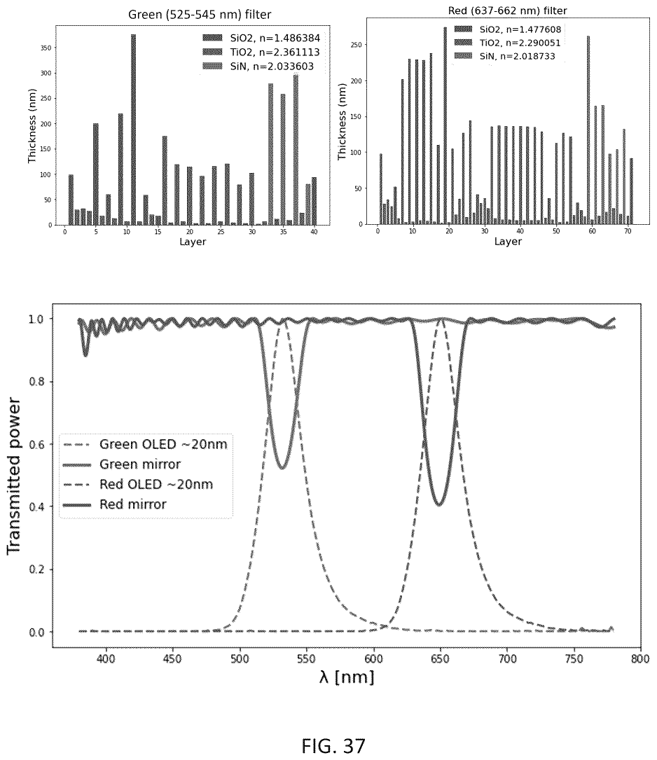

FIG. 37 shows an exemplary two IMOD mirror and associated simulated results. Independent weighting of signals on different parts of the optical spectrum was considered. To achieve this, two optimized mirrors were considered as presented in the top two plots. Their transmission profiles are presented in the bottom plot, with one filter centered at 532 nm (green), and the other one centered at 650 nm (red).

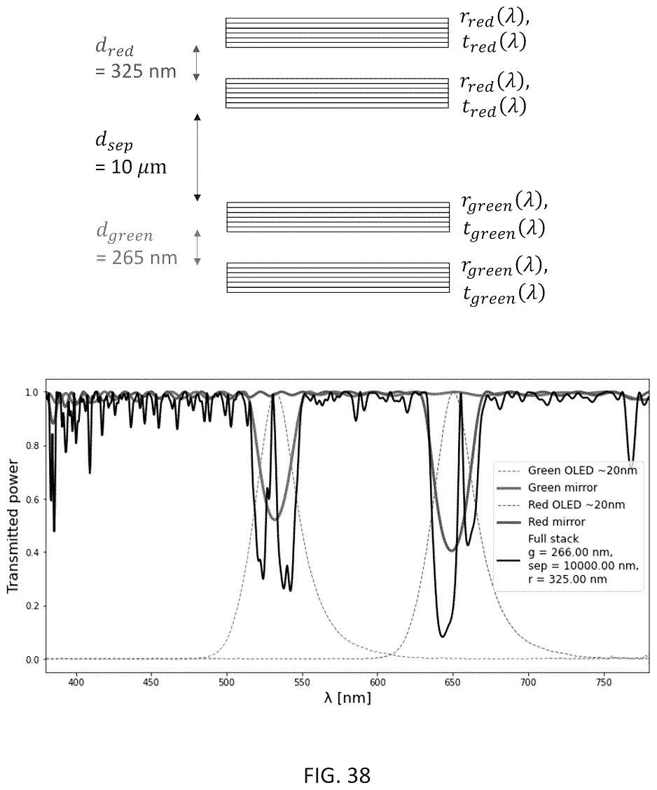

FIG. 38 shows exemplary simulation results when the mirrors of FIG. 37 are stacked. The mirrors are stacked in the configuration as shown to form two cavities. Three gaps are present: separation between “red” mirrors, separation between the two cavities, and separation between the “green” mirrors. The resulting transmission profile of the entire assembly (black) is overlaid on the individual components' transmissions (colors).

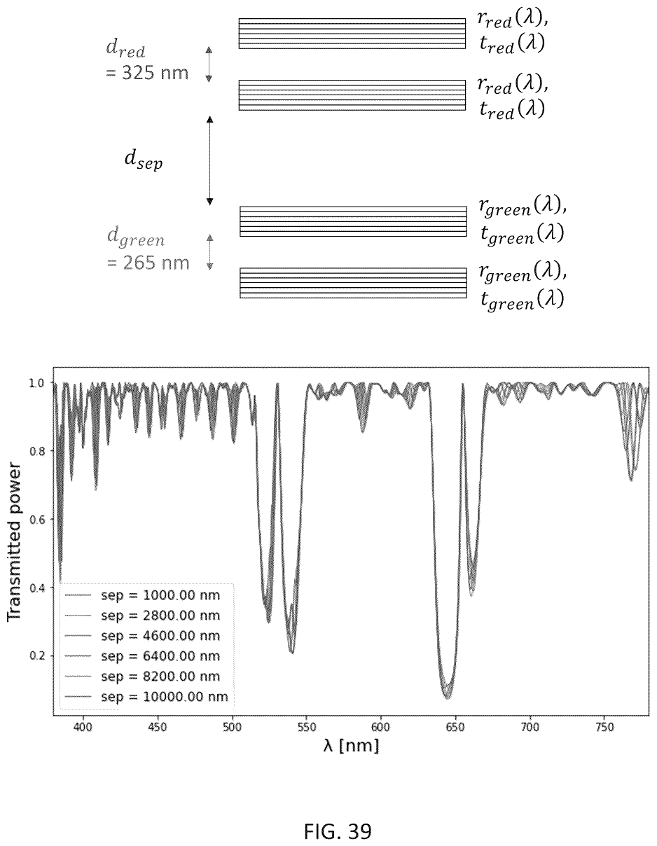

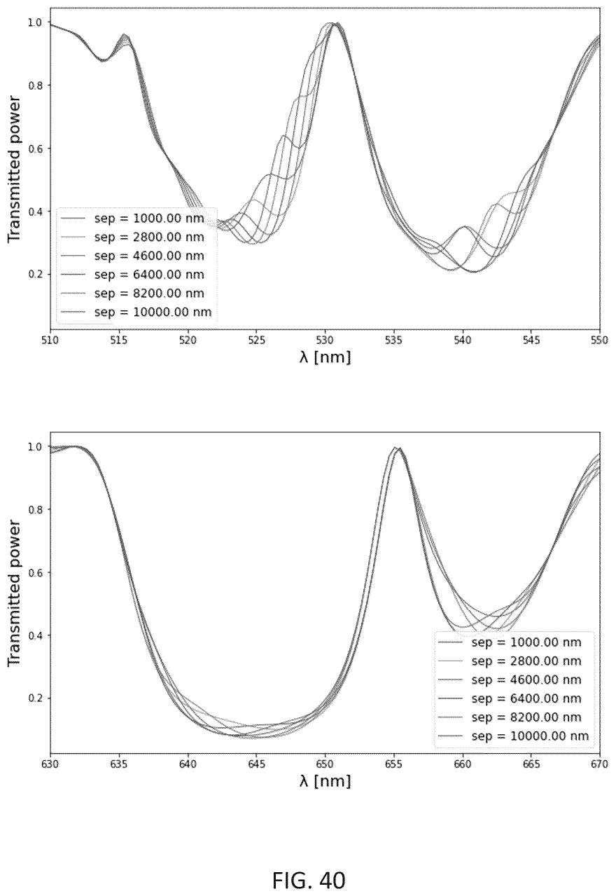

With reference now to FIG. 39 and FIG. 40, combined transmission versus inter-IMOD separation is described. Transmission curves of the entire assembly as the separation between the two cavities is changed is shown. The overall spectrum shifts but does not shift noticeably in the regions of interest where the mirrors operate.

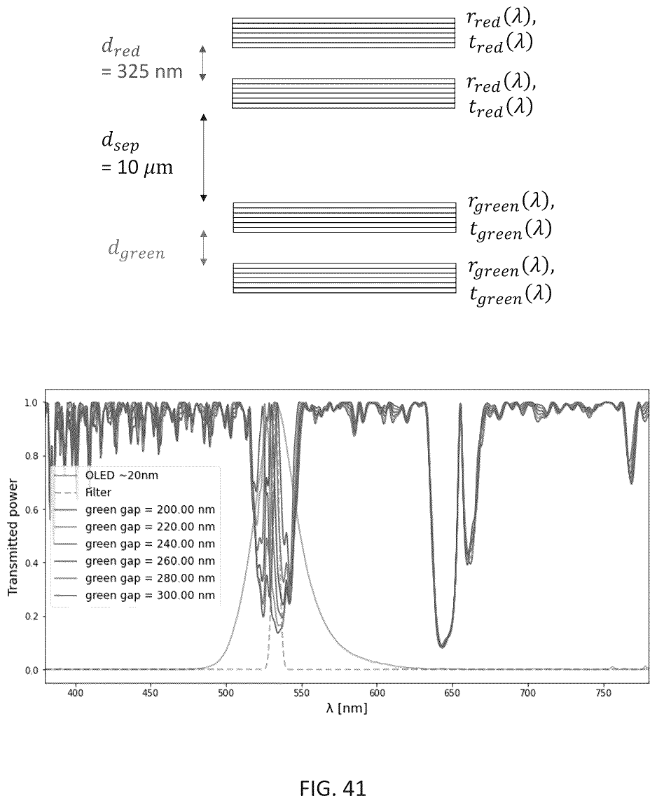

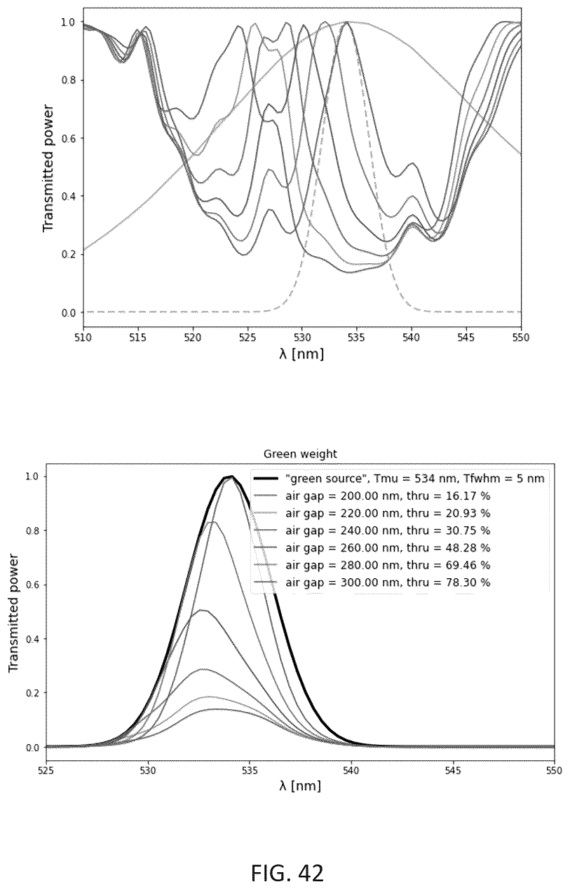

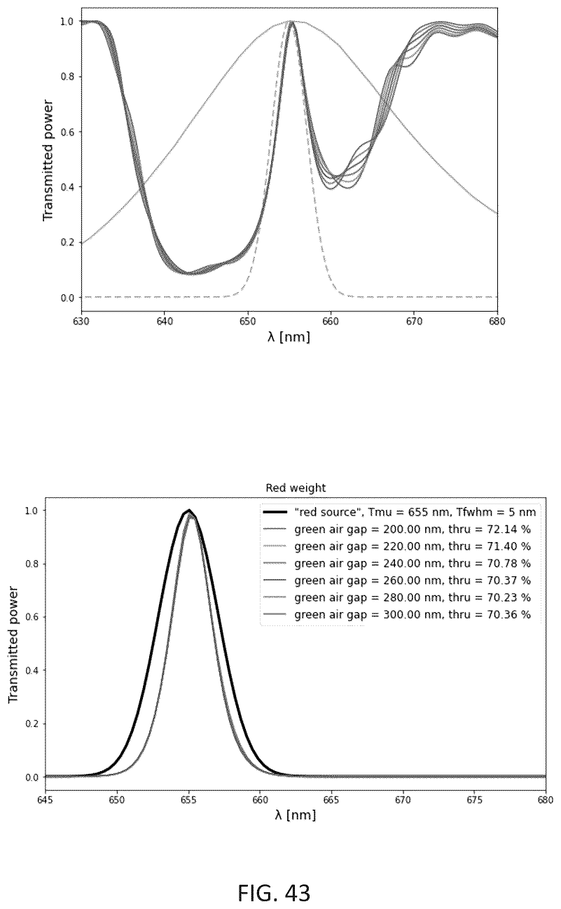

With reference now to FIGS. 41-43, combined transmission versus green IMOD tuning is described. Transmission curves of the entire assembly as the separation between the two green mirrors is changed is shown. The spectrum exhibits large shifts in the vicinity of the green filters, and hardly moves anywhere else. The plots of FIG. 42 and FIG. 43 show a zoomed in view on the regions of interest about the two cavities (top), with corresponding transmission change when considering overlap of emitter and filter (bottom). There is a large shift about the green filter, and barely any shifts about the red filter.

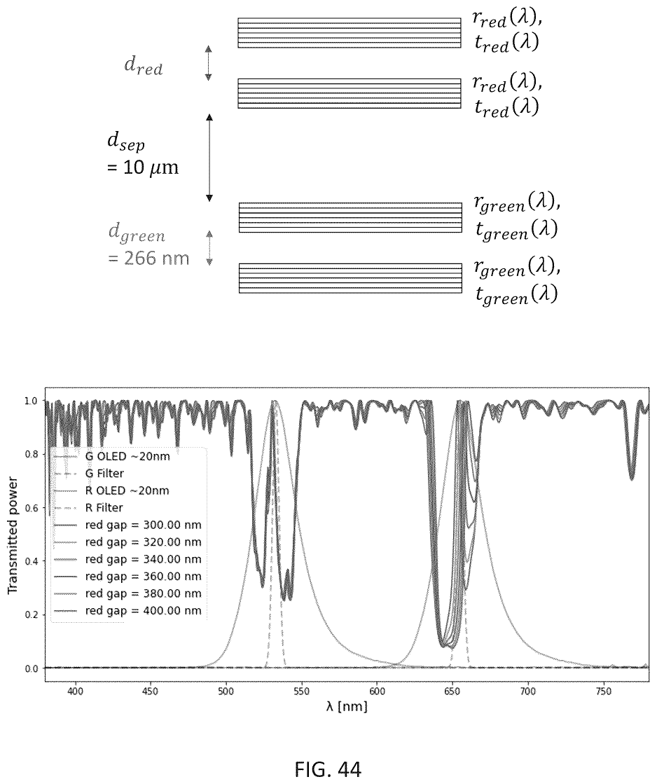

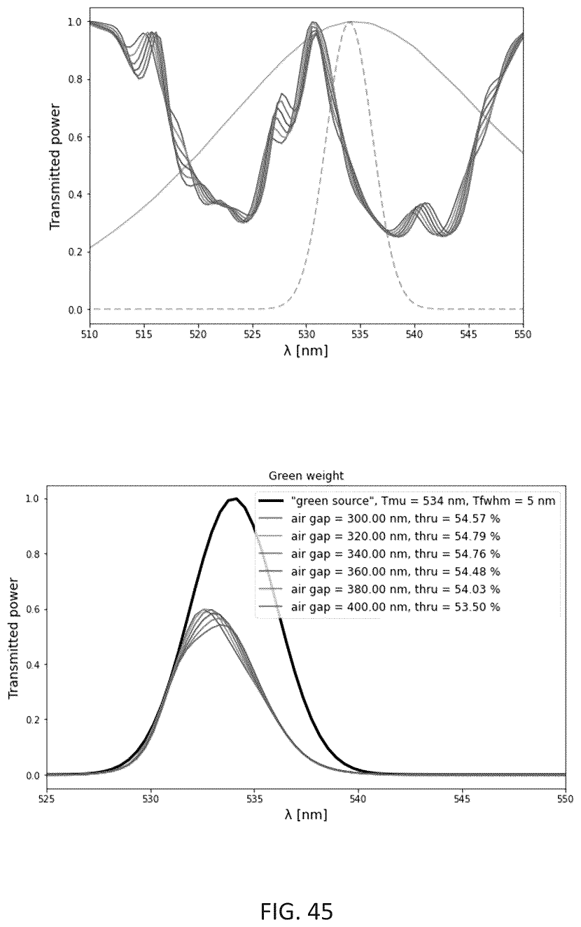

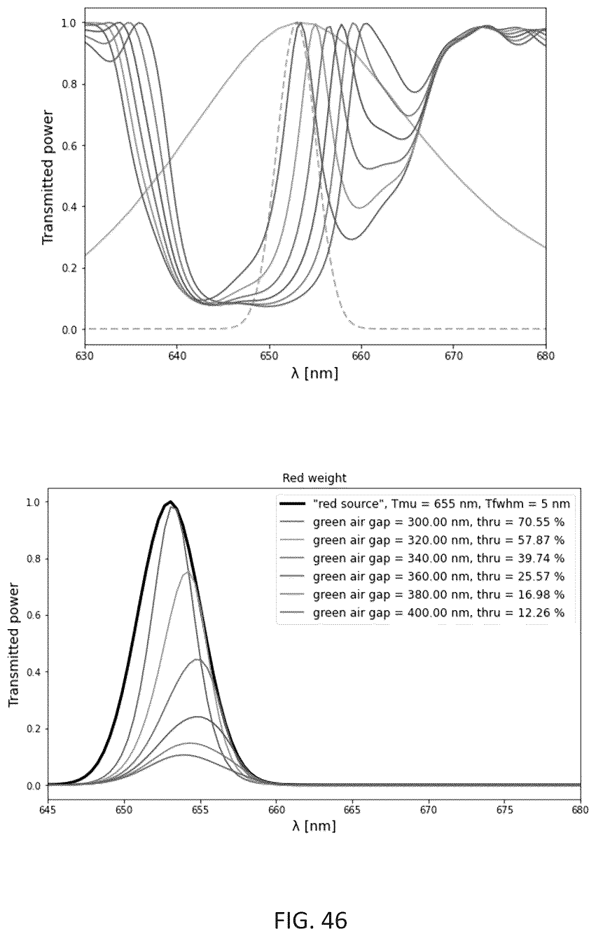

With reference now to FIGS. 44-46, combined transmission versus red IMOD tuning is described. Transmission curves of the entire assembly as the separation between the two red mirrors is changed is shown. The spectrum exhibits large shifts in the vicinity of the red filters, and hardly moves anywhere else. The plots of FIG. 45 and FIG. 46 show a zoomed in view on the regions of interest about the two cavities (top), with corresponding transmission change when considering overlap of emitter and filter (bottom). There is a large shift about the red filter, and barely any shifts about the green filter.

The maximum number of channels is directly related to the spectral narrowness of the mirror, and thus the smallest manufacturable layer. The maximum analog tuning range sets how sharp of a resonance is needed, and the optics and mechanics can be decoupled. The resonance sharpness is set by mirror reflectivities and also bounded by manufacturability. How sharp a resonance can be is equal to how much light is available for processing.

Applications include both analog and digital applications such as OLEDs, WDM neural network synapses, grayscaling, color/hyperspectral mixing at input, reconfigurable routing, and time-multiplexed high spatial resolution hyperspectral filters, for example. Furthermore, the stacked IMODs can be engineered as to minimally interfere with each other.

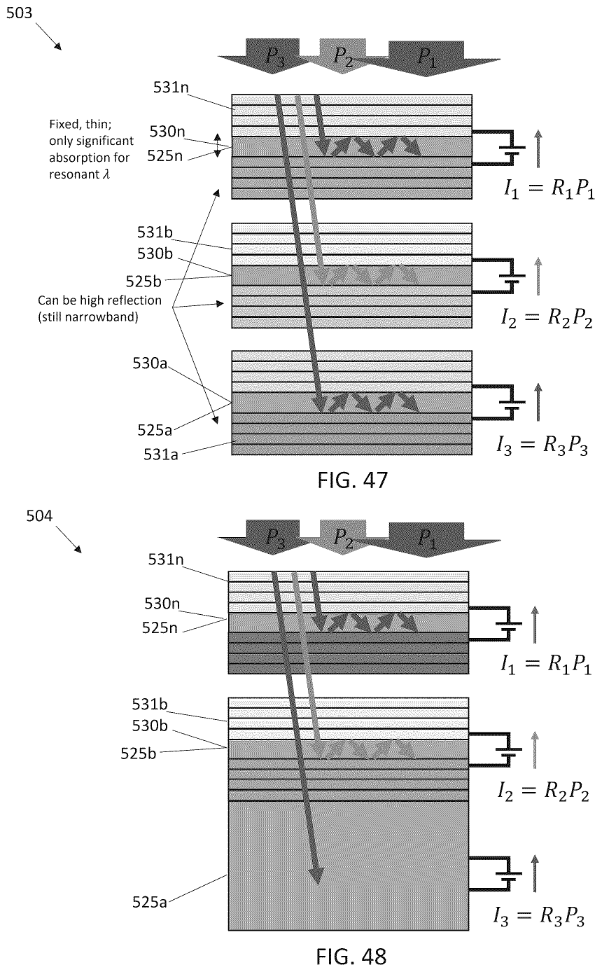

Additional embodiments of neuromorphic opto-electronic devices (503, 504) are shown in FIG. 47 and FIG. 48 utilizing thin film resonant cavity enhanced photodetector banks. Devices 503 and 504 are all solid-state devices configured to provide for easier manufacturing and fixed resonator behavior. The designs are also versatile where the weighting can be done during photodetection by tuning responsivity, or after photodetection via once circuit per synapse.

Device 503 includes a plurality of cavities 530a-n apportioned between a plurality of stacked selective mirrors 531a-n. In some embodiments, the cavities 530 comprise multi-cavities. In some embodiments, optical filtering devices are utilized in place of the selective mirror 531. Each selective mirrors 531 includes one of a plurality of photodetectors 525a-n (collectively 525) positioned within the cavities 530. In some embodiments the photodetectors 525 comprise resonant-cavity-enhanced photodetectors. The selective mirrors 531 are each configured to interact with light of separate specific wavelengths. Since the light does not need to propagate down to below the stack, the mirrors in this case can be asymmetric, where the lower mirrors can reach up to 100% reflection.

Device 504 includes a plurality of cavities 530b-n apportioned between a plurality of stacked selective mirrors 531b-n. In some embodiments, the cavities 530 comprise multi-cavities. In some embodiments, optical filtering devices are utilized in place of the selective mirrors 531. Each selective mirror 531 includes one of a plurality of photodetectors 525b-n positioned within the cavities 530 to detect light in each cavity. The selective mirrors 531 are each configured to interact with light of separate specific wavelengths. The device can further include a bulk photodetector 525a positioned below the stacked selective mirrors 531 for the last channel, assuming all other channels have been absorbed at this depth.

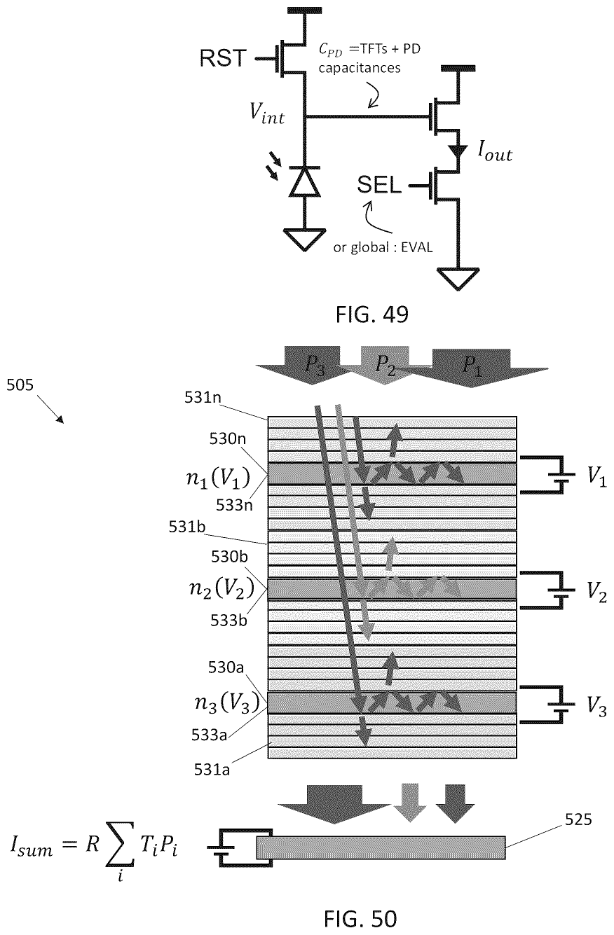

The photodetectors 525 can be any suitable photosensitive element, including phototransistors, photogates, and avalanche photodetectors with intrinsic gain. Additionally, electronics can be utilized after to photodetector 525 to provide gain either directly, such as for a transimpedance amplifier, or in an integrating scheme, such as shown in FIG. 49. Typically, individual films will require thicknesses of order wavelength to filter. Mirror film materials should have low absorption in the wavelength ranges of interest, and dielectrics are typically used. The detector thickness will depend on its absorption and the reflectivity of the mirrors 531, the goal being that most light matched to a given cavity gets absorbed in that photodetector 525 while other light suffers minimal absorption. Since the cavities 530 ensure wavelength selectivity, the detector materials can absorb broadband light, although further choosing different materials with wavelength-dependent responsivity (e.g. organics) can further improve performance.

FIG. 50 shows an additional embodiment of a neuromorphic opto-electronic device 505 utilizing transmission mode absorption modulator filter banks. Device 505 includes a plurality of cavities 530a-n apportioned between a plurality at least one tunable complex index of refraction thin film of stacked selective mirrors 531a-n. In some embodiments, the cavities 530 comprise multi-cavities. In some embodiments, optical filtering devices are utilized in place of the selective mirrors 531. Each selective mirrors 531 includes one of a plurality of tunable complex index of refraction thin films 533a-n (collectively 533) positioned within the cavities 530. The selective mirrors 531 are each configured to interact with light of separate specific wavelengths. Device 505 further includes a photodetector 525 positioned below the stacked selective mirrors 531. Device 505 combines the advantages of devices 502 and 503 including detecting the sum of signals instead of individual ones thus leading to higher signal-to-noise, no electronics for weighting in the signal path, easier manufacturing and fixed resonator behavior. The index of the cavities is tuned as opposed to the gap of the cavities. Candidates for the complex index of refraction thin films 533 include, for example, blue phase liquid crystals, PLZT Thin Films (quadratic electro-optic Kerr), BaTiO3 (Pockels), organic chromophore, and any other suitable material. For absorption-based modulators, other materials such as phase-change materials, chromic molecules (e.g. electrochromic, photochromic, thermochromic), III-V modulator or detector materials, and carrier-based films (e.g. pn junctions, epsilon-near zero stacks, etc.), or any other suitable material can be utilized.

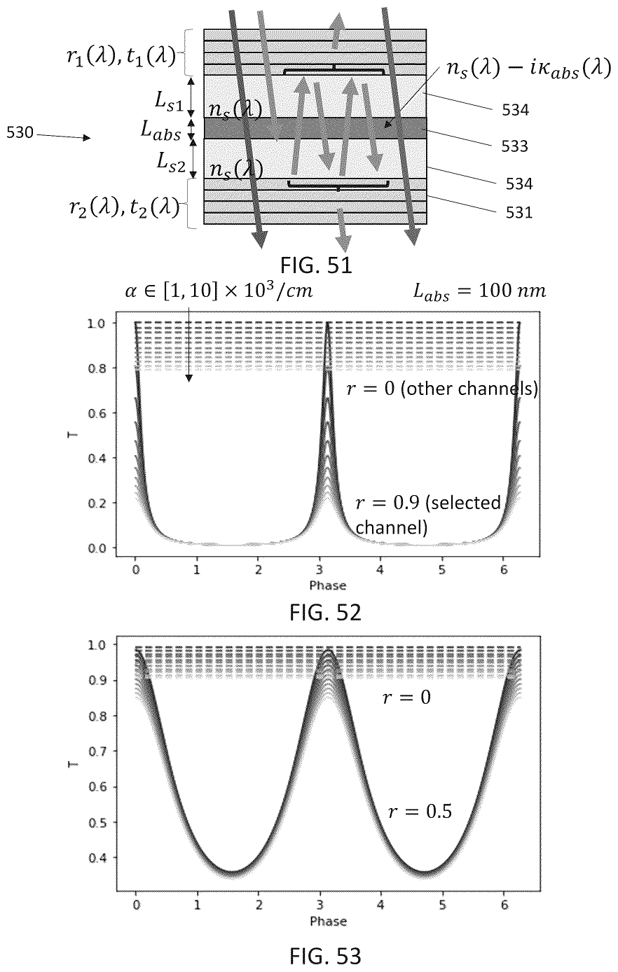

FIG. 51 is a diagram showing an exemplary thin-film resonant cavity-enhanced absorption modulator of device 505. It includes two selective mirrors that form a cavity for one of the impinging signals (here, green), with free propagation for other signals. Between the mirrors, a film of tunable complex index of refraction 533 is placed. Depending on the optical constant of the tunable film 533, the transmission for the matched signal can be tuned with minimal impact on the other signals. In some embodiments, the cavity 530 includes a tunable complex index of refraction thin film 533 positioned between spacers 534. In some embodiments, the spacers 534 are used to decouple resonance and absorption. In some embodiments, the spacers 534 are index matched. Typically, individual films will require thicknesses of order wavelength to filter. Mirror film materials should have low absorption in the wavelength ranges of interest, and dielectrics are typically used. For absorption-based modulators, other materials such as phase-change materials, chromic molecules (e.g. electrochromic, photochromic, thermochromic), III-V modulator or detector materials, and carrier-based films (e.g. pn junctions, epsilon-near zero stacks, etc.), or any other suitable material can be utilized.

Consider transmission through the absorptive stack as a function of the absorption coefficient. Loss from the mirrors can be defined by:

$${\vert r ( λ ) \vert}^{2} + {\vert t ( λ ) \vert}^{2} = IL ( λ ) < 1 \qquad ( 30 )$$

single-pass phase can be defined by:

$$φ = \frac{2 π}{λ} [ {n}_{s} ( {L}_{s 1} + {L}_{s 2} ) + ( {n}_{s} - i {κ}_{a b s} ) {L}_{a b s} ] \qquad ( 31 )$$

$$T ( λ ) = {\vert \frac{{t}_{1} {t}_{2} {e}^{- i φ}}{1 - {r}_{1} {r}_{2} {e}^{- i 2 φ}} \vert}^{2} = \frac{{( 1 - IL ( λ ) - {\vert r ( λ ) \vert}^{2} )}^{2} {e}^{- \frac{4 π}{λ} \cdot {κ}_{a b s} ( λ ) {L}_{a b s}}}{{\vert 1 - {r ( λ )}^{2} {e}^{- i \cdot 2 R e ( φ ( λ ) )} {e}^{- \frac{4 π}{λ} {κ}_{a b s} ( λ ) {L}_{abs}} \vert}^{2}} \qquad ( 32 )$$

which can be written as:

$$T ( λ ) = \frac{{( 1 - IL ( λ ) - {\vert r ( λ ) \vert}^{2} )}^{2} {e}^{- α {L}_{a b s}}}{{\vert 1 - {r ( λ )}^{2} {e}^{- i \cdot 2 Re ( φ )} {e}^{- α {L}_{abs}} \vert}^{2}} \qquad ( 33 )$$

where α=4πκ(λ)/λ and r(λ)² equals 0 if λ is far from λ₀.

FIG. 52 and FIG. 53 are plots showing a comparison the change in transmission of matched signals (solid) versus other signals (dashed). There is a much larger change in transmission for signals on resonance (nonzero reflection and proper phase) as compared to other signals (non-matched mirrors) as the absorption of the film is changed (different colored lines). The effect is increased with increased mirror reflectivity. This indicates that the device can act as a selective weighting element for photonic signals. The effect can be further engineered through A-dependence of absorption. In a typical polymer α˜10³ cm⁻¹, and so this was used as the baseline absorption for illustration. For actual weight integration of source and filter both the spectral width and height change matter.

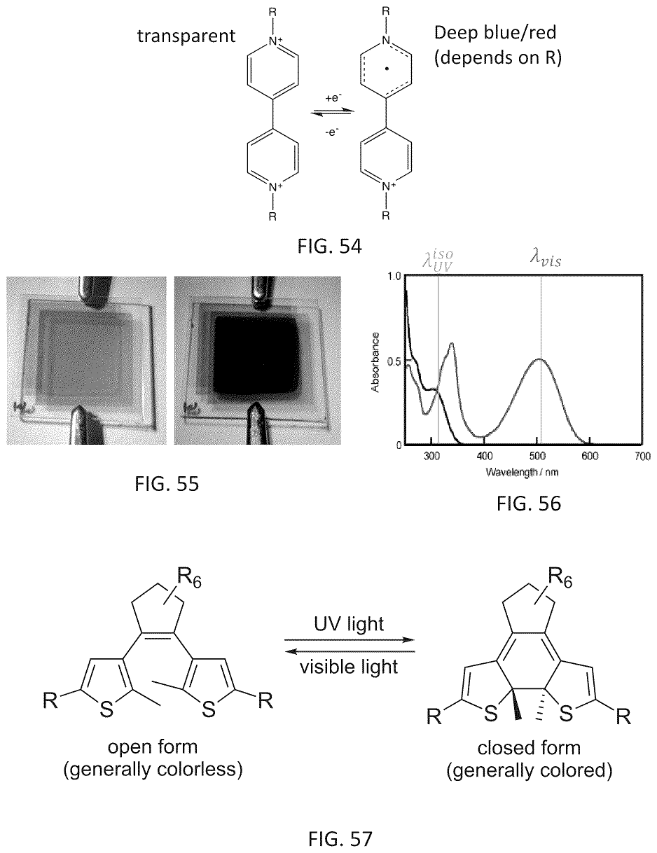

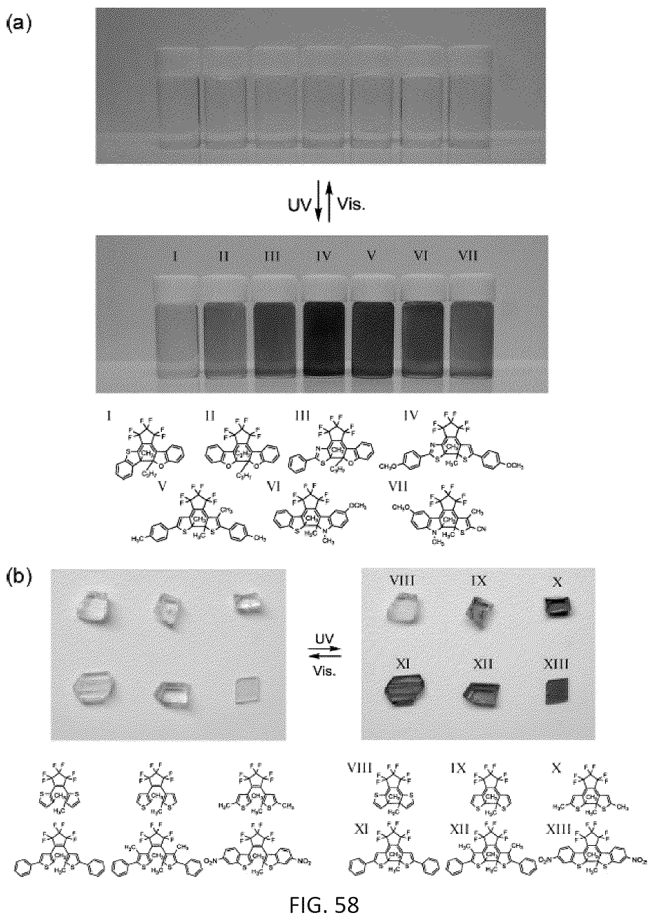

For nonvolatile control of absorption electrochromic devices or photochromic thin films can be used. FIG. 54, FIG. 57 and FIG. 58 show chemical diagrams for exemplary electrochromic and photochromic molecules. The complex index of refraction and absorption of these materials can be tuned under an external electrical or optical signal. FIG. 55 and FIG. 58 show example photochromic substances in colored and colorless forms. An example of photochromics are diarylethenes, which have been studied for optical data storage and optical switching. These properties are desirable for photonic synapses. The main desirable behavior is two isomers with different absorption profiles as shown in FIG. 56. Different functionalizations result in different behaviors. Advantages of utilizing photochromic thin films in a device include that the device resonance is environmentally stable, the device is all solid-state for ease of manufacturing, and a single large optical signal provides for simple electronics.

In some embodiments, the absorption-modulated stack device 505 of FIG. 50 can utilize photochromic films whose absorption can be tuned using light. This is useful since elements in the stack can be addressed using signals that are of the same form as the ones used for processing. This makes fabrication much easier, as electrical contacting of elements in the stack is not required. Processing and reconfiguration signals being in the same form also allows for in-situ learning for photonic neural networks.

By using photochromic weight actuation electrical contacting of each element in the stack is not necessary. Furthermore, processing signals are in the same form as the actuation signals, thus the device can display optical memristive behavior and optical learning rules (plasticity) can be implemented.

A mathematical model of the dynamics of photochromic molecules is presented below. The transition between the two states follows a linear rate equation, with the rate constant proportional to the optical intensity, absorption coefficients, and quantum yield of the two forms, all of which depend on the photon wavelength.

The photokinetics can be defined by:

$$\frac{d {x}_{O} ( z , t )}{d t} = - {\sum }_{λ} {I}^{λ} ( z , t ) \cdot [ {ϵ}_{O}^{λ} {Φ}_{O \to C}^{λ} \cdot {x}_{O} ( z , t ) - {ϵ}_{C}^{λ} {Φ}_{C \to O}^{λ} \cdot {x}_{C} ( z , t ) ] \qquad ( 34 )$$

with x_{0/C}(z,t)=N_{0/C}(z,t)/N and molecule conservation x₀+x_{C}=1.

The net absorption coefficient is defined by:

$${α}^{λ} ( z , t ) = {ϵ}_{O}^{λ} {x}_{O} ( z , t ) C + {ϵ}_{C}^{λ} ( 1 - {x}_{O} ( z , t ) ) C + {α}_{m a t r i x}^{λ} \qquad ( 35 )$$

$$where C = \frac{{w}_{\%} ρ {N}_{A}}{{M}_{p h}} .$$

The net refractive index is defined by:

$${n}^{λ} ( z , t ) = {n}_{O}^{λ} {x}_{O} ( z , t ) \frac{C}{{C}_{tot}} + {n}_{C}^{λ} ( 1 - {x}_{O} ( z , t ) ) \frac{C}{{C}_{tot}} + {n}_{matrix}^{λ} \frac{{C}_{tot} - C}{{C}_{tot}} \qquad ( 36 )$$

Absorption is well-characterized in molar extinction coefficient ϵ. The index change is small (˜0.01) with respect to interface mismatch, but large enough for cavity actuation.

The photon flux (photons per unit time) is defined as:

$$[ I ] = \frac{photons}{{m}^{2} s} = \frac{1}{hv} \frac{J}{s \cdot {m}^{2}} = \frac{1}{hv} \frac{W}{{m}^{2}} \qquad ( 37 )$$

the absorption cross section (how many photons absorbed) as:

$$[ {ϵ}_{X}^{λ} ] = \frac{{m}^{2}}{mole c u l e} = {N}_{A} \frac{{m}^{2}}{mol} \qquad ( 38 )$$

with the quantum yield (how many absorbed photons yield photoreaction) as

$$[ {Φ}_{X \to \overline{X}}^{λ} ] = ( unitless ) ,$$

concentration

$$[ C ] = \frac{mole c u l e s}{{m}^{3}} ,$$

mol amount or active units [w_{%}]=(unitless), density of active film

$$[ ρ ] = \frac{ℊ}{{m}^{3}} ,$$

molar mass or photochromic unit

$$[ {M}_{p h} ] = \frac{ℊ}{mol} ,$$

and Avogadro's number

$$[ {N}_{A} ] = \frac{m o l e c u l e s}{m o l} .$$

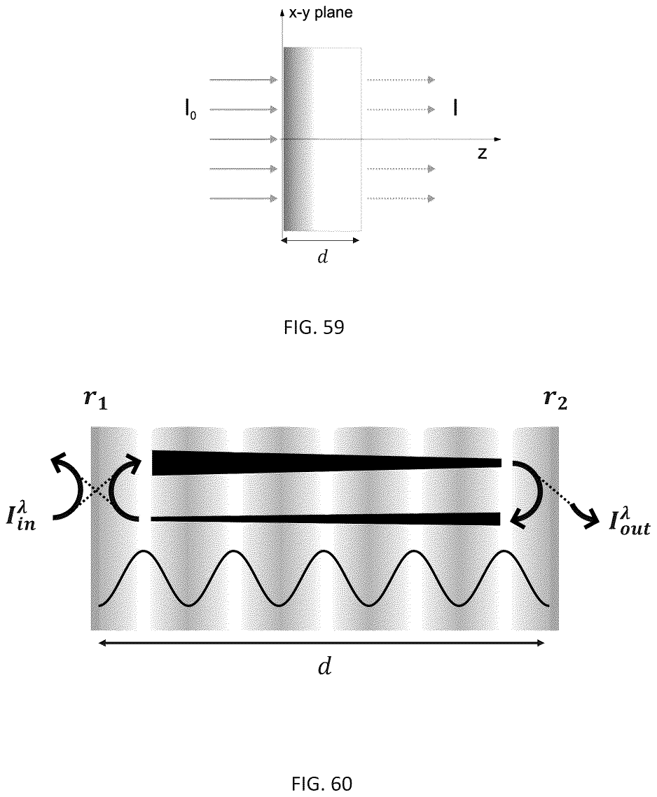

FIG. 59 is a diagram depicting exemplary transmission through a film. For the case of a simple film Beer's Law applies, with the absorption coefficient the weighted average of the two forms in the film. These, in turn, depend on the illumination as a function of time. Combining the chemical model with an optical model yields:

$${I}^{λ} ( z , t ) = {I}_{0}^{λ} {e}^{- {\int }_{0}^{z} {dz}^{′} \{ {ϵ}_{O}^{λ} {x}_{O} ( {z}^{′} , t ) C + {ϵ}_{C}^{λ} [ 1 - {x}_{O} ( {z}^{′} , t ) ] C + {α}^{λ} \}} \qquad ( 39 )$$

$$\frac{{dx}_{O}}{dt} = - {I}^{λ} ( z , t ) \cdot [ {ϵ}_{C}^{λ} {Φ}_{C \to O}^{λ} {x}_{C} - {ϵ}_{O}^{λ} {Φ}_{C \to O}^{λ} ( 1 - {x}_{O} ) ] \qquad ( 40 )$$

$${T}^{λ} ( t , {I}_{0} ) = \frac{{I}^{λ} ( d , t )}{{I}_{0}^{λ}} = {e}^{- {\int }_{0}^{d} {dz}^{′} \{ {ϵ}_{O}^{λ} {x}_{O} ( {z}^{′} , t ) C + {ϵ}_{C}^{λ} [ 1 - {x}_{O} ( {z}^{′} , t ) ] C + {α}^{λ} \}} \approx {e}^{- \{ [ {ϵ}_{O}^{λ} - {ϵ}_{C}^{λ} ] 〈 {x}_{O} ( t ) 〉 C + {ϵ}_{C}^{λ} C + {α}^{λ} \} d} \qquad ( 41 )$$

FIG. 60 depicts exemplary transmission through a film. The field seen by the compound is increased leading to faster chemical dynamics, and a smaller changing in x is required for the same transmission change leading to faster system dynamics. This can be described by:

$$\frac{d {x}_{O}}{d t} = - ( 1 - {R}_{1}^{λ} ) {A}_{c i r c} ( {x}_{O} ) {I}_{i n} \cdot [ {ϵ}_{O}^{λ} {Φ}_{O \to C}^{λ} {x}_{O} - {ϵ}_{C}^{λ} {Φ}_{C \to O}^{λ} ( 1 - {x}_{O} ) ] \qquad ( 42 )$$

$${T}^{λ} ( t , {I}_{i n} ) = \frac{{I}_{o u t}^{λ}}{{I}_{i n}^{λ}} = {A}_{c i r c}^{λ} ( {x}_{O} ) ( 1 - {R}_{1}^{λ} ) ( 1 - {R}_{2}^{λ} ) {e}^{- 2 \{ [ {ϵ}_{O}^{λ} - {ϵ}_{C}^{λ} ] {x}_{O} ( t ) C + {ε}_{C}^{λ} C + {α}^{λ} \} d} \qquad ( 43 )$$

$${A}_{c i r c}^{λ} ( {x}_{O} ) = \vert 1 - {r}_{1}^{λ} {r}_{2}^{λ} {e}^{- 2 i {ϕ}^{λ}} {e}^{- 2 \{ [ {ϵ}_{O}^{λ} - {ϵ}_{C}^{λ} ] {x}_{O} ( t ) C + {ϵ}_{C}^{λ} C + {α}^{λ} \} d} {\vert}^{- 2} \qquad ( 44 )$$

with the cavity optical timescale defined by:

$$\frac{d}{d t} S ( t ) = - \frac{1}{{τ}_{c}} S ( t ) \qquad ( 45 )$$

where

$${τ}_{c} < {( - \frac{ln ( {r}_{1} {r}_{2} )}{2 dn / c} )}^{- 1} .$$

If τ_{c}<<τₓ, intensity buildup is instant. For weak absorption, cavity modes are intact leading to effective complex index (no z-dep).

It was then considered what happens when the photonic environment around the photochromic film in modified through insertion into an optical cavity. Assuming the film is thin enough, the spatial dependence of the molecules can be brushed away (even without this approximation, the general result still holds). The main differences with simple propagation through a film is that there is an optical field buildup for wavelengths resonant with the cavity, and hence the chemical rate is increased. Furthermore, the cavity transmission is also modified by the presence (and optical state) of the film and is in fact more sensitive to the film state then the transmission through the film without the cavity.

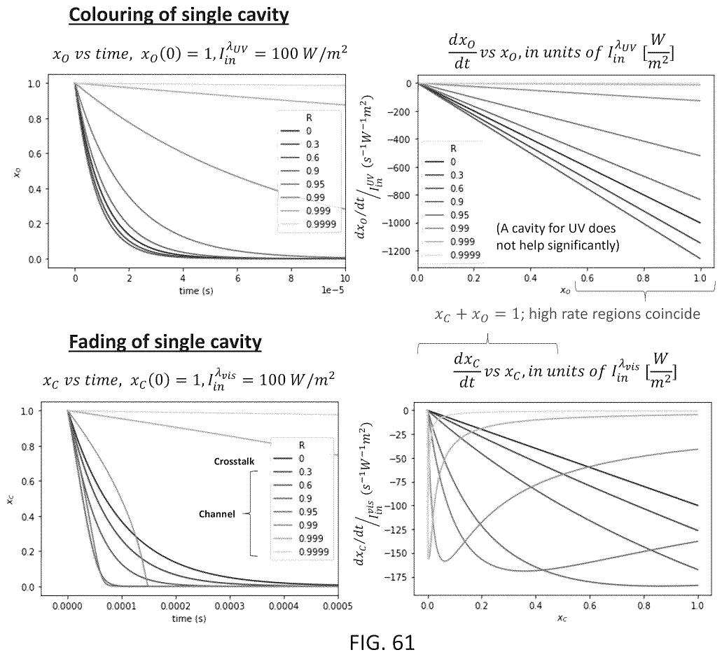

FIG. 61 are plots showing coloring of a single cavity and fading of a single cavity. Equations 41-44 solved to create the plots, with cavity parameters R₁=R₂=R, R^{λ}^{_{UV}}≠R^{λ}^{ᵥᵢₛ} and d˜20 nm=2×10⁻⁷ m, and source parameters as “Monochromatic” λ=λ₀ (φ=0) and assuming the cavity remains aligned. On the y-axis, the fraction of species in one of the states, and on x-axis time. For the top row consider a film initially in the transparent state and being colored by (resonant) UV light, and the bottom row a film initially in the colored state being bleached by (resonant) visible light. The main difference between the two situations is that under UV illumination, both species have roughly the same absorption coefficient, and so the cavity enhancement coefficient does not vary much as a function of time. In the visible, however, one specie is fully transparent, and hence the enhancement factor has strong dependence on the film state and time. This manifests in the differing concavities of the curves. The main takeaway is that the population dynamics can be changed and accelerated under the action of an optical cavity, which can be seen by comparing the time traces (left) or rates (right) for different cavity reflectances (different color curves), with deep purple being the cavity-free, R=0 case.

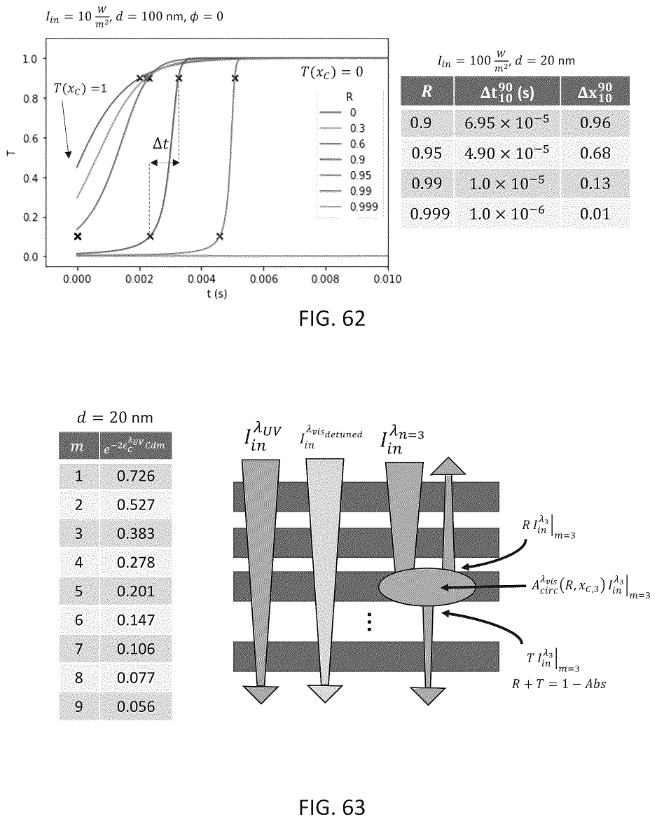

Speedup is also possible as shown in FIG. 62 plot showing destructive (absorption) actuation. When using absorbed light as weight, the device can weight spectrally broad sources with only a small concentration range needed to cover 0-100% transmission. Processing signal powers must be low enough not to modify the state or chosen where φ=0 but ϵ≠0, but learning algorithms can be implemented if the above is violated. For example, with decoloring:

$$\frac{d {x}_{C}}{d t} = - ( 1 - R ) {A}_{c i r c} ( {x}_{C} ) {I}_{i n} \cdot {ϵ}_{C}^{λ} {Φ}_{C \to O}^{λ} {x}_{C} ( t ) \qquad ( 46 )$$

$$T ( t , {I}_{i n} ) = {A}_{c i r c} ( {x}_{C} ) {( 1 - R )}^{2} {e}^{- 2 {ϵ}_{C}^{λ} Cd \cdot {x}_{C} ( t )} \qquad ( 47 )$$

$${A}_{c i r c}^{{λ}_{ν i s}} = \vert 1 - {R}^{{λ}_{ν i s}} {e}^{- 2 {ϵ}_{C}^{λ} Cd \cdot {x}_{C} ( t )} {\vert}^{- 2} \qquad ( 48 )$$

with

$${A}_{c i r c} ( {x}_{C} = 0 ) = \frac{1}{{( 1 - R )}^{2}}$$

(good cavity) and A_{circ}(x_{C}=1)→1 (worse cavity).

Another possibility is to consider nondestructive (index) actuation where transmission in wavelength ranges where the chemical does not convert from one form to another (for instance, in the infrared). For example, choosing a signal wavelength ϵ^{λ}^{_{IR}}≈0 but with n(x_{C}=1)−n(x_{C}=0)=Δn there would be no crosstalk, no loss thus enabling low-power processing, and the transmission state will be left intact. The weighting depends strongly on the effective cavity length. This can be defined by:

$$T ( {x}_{C} ) = {A}_{c i r c}^{{λ}_{IR}} ( {x}_{C} ) {( 1 - {R}^{{λ}_{IR}} )}^{2} \qquad ( 49 )$$

$${A}_{c i r c} ( λ ) = {\vert 1 - {R e}^{- 2 i [ \frac{2 π}{λ} n d ]} \vert}^{- 2} \qquad ( 50 )$$

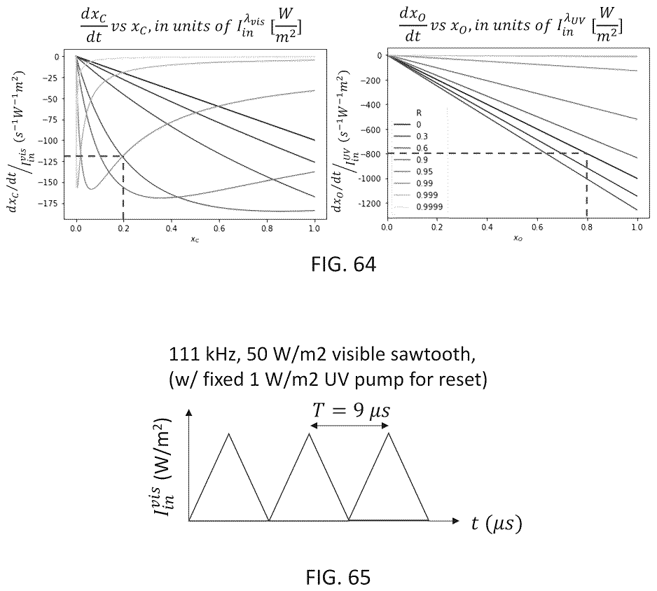

Referring now to FIG. 63 and FIG. 64, a photochromic film stack is described. By using the wavelength-selectivity of the cavities, it is possible to expose one of the films to more light than the others, allowing independent actuation. To make up for the crosstalk (the single pass of light in the other, non-resonant cavities), extra reverse illumination is required, but as long as differential rates are expressed any multi-weight configuration is accessible.

For example, assuming no UV cavities

$$( {R}_{m}^{UV} = 0 ∀ m )$$

and assuming independent visible cavities

$$( {R}_{m}^{{λ}_{n}} = R {δ}_{mn} )$$

than transmission is purely exponential for m<n. Coloring irradiance is seen by deeper layers screened by earlier ones in a fixed manner described by:

$${I}_{in}^{{λ}_{UV}} {\vert}_{m} \approx {I}_{in}^{{λ}_{UV}} {e}^{- 2 {ϵ}^{{λ}_{UV}} Cd \cdot m} \qquad ( 51 )$$

Given the state-dependence of visible reaction, the simplest approach to set states involves “cancelling” of the coloring of the upper layers with appropriate tones. UV irradiance can be used to hold uppermost layers at a steady-state of x_{C}=1−x₀=0.2 for I^{vis}≈100 W/m² where

$${I}^{UV} = {\dot{x}}_{C}^{vis} ( 0 \text{.2} ) / {\dot{x}}_{O}^{UV} ( 0 \text{.8} ) {I}^{vis} \approx 15 W / {m}^{2} .$$

Hence coloring rate at lowermost layer (N=9) is ˜600 s⁻¹. Thus, the reconfiguration rates are Δt˜1's ms, but can be improved with smaller stacks, higher pump irradiances, or less conservative algorithms. Assuming all weights can be updated during this time, energy would be

$$Δ t ( {\sum }_{i = 1}^{N} {I}^{vis} + {I}^{UV} ) \approx 0.1 N W / {m}^{2} .$$

The system is further defined by:

$$[ \begin{matrix}{x}_{C , 1} \\ {x}_{C , 2} \\ ⋮ \\ {x}_{C , N}\end{matrix} ] = - ( 1 - R ) {I}_{in}^{{λ}_{vis}} {ϵ}_{C}^{{λ}_{vis}} {Φ}_{C \to O}^{{λ}_{vis}} [ \begin{matrix}{A}_{circ}^{{λ}_{vis}} ( R , {x}_{C , 1} ) & 0 & … & 0 \\ - 2 {ϵ}_{C}^{{λ}_{vis}} {Cdx}_{C , 2} & {A}_{circ}^{{λ}_{vis}} ( R , {x}_{C , 2} ) & … & 0 \\ ⋮ & ⋮ & ⋱ & ⋮ \\ - 2 {ϵ}_{C}^{{λ}_{vis}} {Cdx}_{C , N} & - 2 {ϵ}_{C}^{{λ}_{vis}} {Cdx}_{C , N} & … & {A}_{circ}^{{λ}_{vis}} ( R , {x}_{C , N} )\end{matrix} ] [ \begin{matrix}{x}_{C , 1} \\ {x}_{C , 2} \\ ⋮ \\ {x}_{C , N}\end{matrix} ] \qquad ( 52 )$$

$$\frac{{dx}_{C}}{d t} = - ( 1 - R ) {A}_{circ}^{{λ}_{vis}} ( R , {x}_{C} ) {I}_{in}^{{λ}_{vis}} {ϵ}_{C}^{{λ}_{vis}} {Φ}_{C \to O}^{{λ}_{vis}} {x}_{C} ( t ) \qquad ( 53 )$$

$${I}_{in}^{{λ}_{n}} {\vert}_{m} \approx {I}_{in}^{{λ}_{n}} {\prod }_{i = 1}^{m} {e}^{- 2 {ϵ}_{C}^{{λ}_{vis}} Cd \cdot {x}_{C , i}} \approx {I}_{in}^{{λ}_{vis}} [ 1 - 2 {ϵ}_{C}^{{λ}_{ν i s}} Cd {\sum }_{i = 1}^{m} {x}_{C , i} ] \qquad ( 54 )$$

If the signals are able to change the weight state, in-memory memristive behavior can be achieved. There is a use for weights that are modified by the signals they are intended to process. In neuroscience for example, synaptic connections can be strengthened automatically if a signal causes a neuron to fire and reduced if it does not, an effect known as spike-time-dependent-plasticity. This effect is captured by memristor equations:

$$\dot{w} = f ( w , {v}_{MR} ) \qquad ( 55 )$$

$${i}_{MR} = g ( w , {v}_{MR} ) {v}_{MR} \qquad ( 56 )$$

Nanoelectronics devices attempt to implement this effect for memristive computing (top right). Photochromic weights present similar dynamics and can therefore act as “photonic memristors” based on:

$${\dot{x}}_{O} = f ( {x}_{O} , {I}_{in} ) \qquad ( 57 )$$

$${I}_{out}^{λ} = {g}^{λ} ( {x}_{O} ) {I}_{i n}^{λ} \qquad ( 58 )$$

$$f ( {x}_{O} , {I}_{in} ) = - {\sum }_{λ} ( 1 - {R}^{λ} ) {A}_{circ}^{λ} ( {R}^{λ} , {x}_{O} ) {I}_{in}^{λ} \cdot [ {ϵ}_{O}^{λ} {Φ}_{O \to C}^{λ} x - {ϵ}_{C}^{λ} {Φ}_{C \to O}^{λ} ( 1 - {x}_{O} ) ] \qquad ( 59 )$$

$${g}^{λ} ( {x}_{O} ) = {T}^{λ} ( {x}_{O} ) = {A}_{circ}^{λ} ( {R}^{λ} , {x}_{O} ) {( 1 - {R}^{λ} )}^{2} {e}^{- 2 \{ [ {ϵ}_{O}^{λ} - {ϵ}_{C}^{λ} ] {x}_{O} ( t ) C + {ϵ}_{C}^{λ} C + {α}^{λ} \} d} \qquad ( 60 )$$

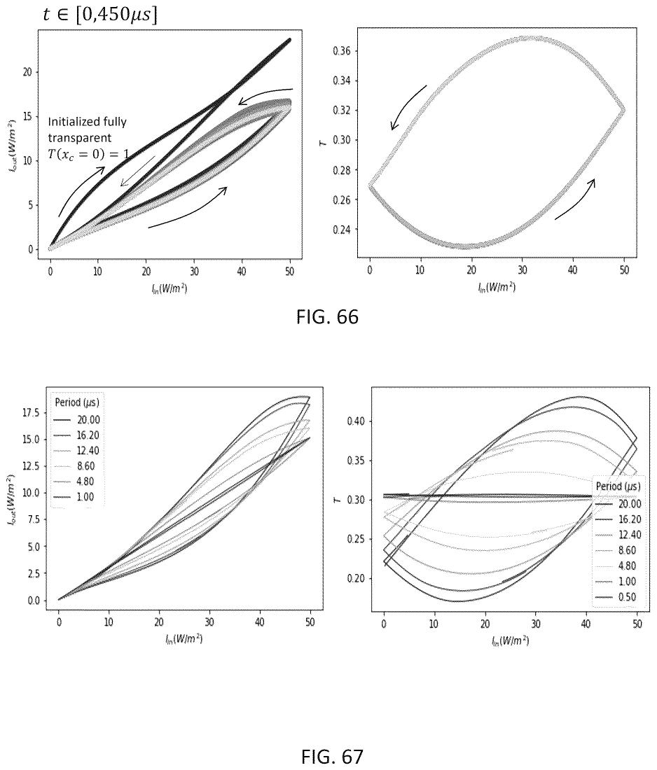

Referring now to FIGS. 65-67, the memristivity was evaluated. FIG. 65 shows a sawtooth wave that was utilized in the evaluation. FIGS. 66-67 are plots showing the response of the system. Memristor criteria include steady-state periodic response under periodic excitation, pinched hysteresis loop (2-valued everywhere except origin, where 0), loop area monotonically decreases with frequency, and the transfer function becomes single-valued as frequency tends to infinity. The plots of FIG. 66 confirm the first two criteria, where under periodic excitation (the sawtooth wave of visible light presented in FIG. 65, with a constant UV background for reset), the response eventually also becomes periodic (left). In the steady state, the periodic response is a pinched hysteresis loop (right). AS shown in FIG. 67, as the period of the sawtooth is reduced (frequency increased), the pinched hysteresis loop area is reduced (left). Converting the left figure to transmission, the transfer function (transmission) settles to a single value as the frequency is increased (right).

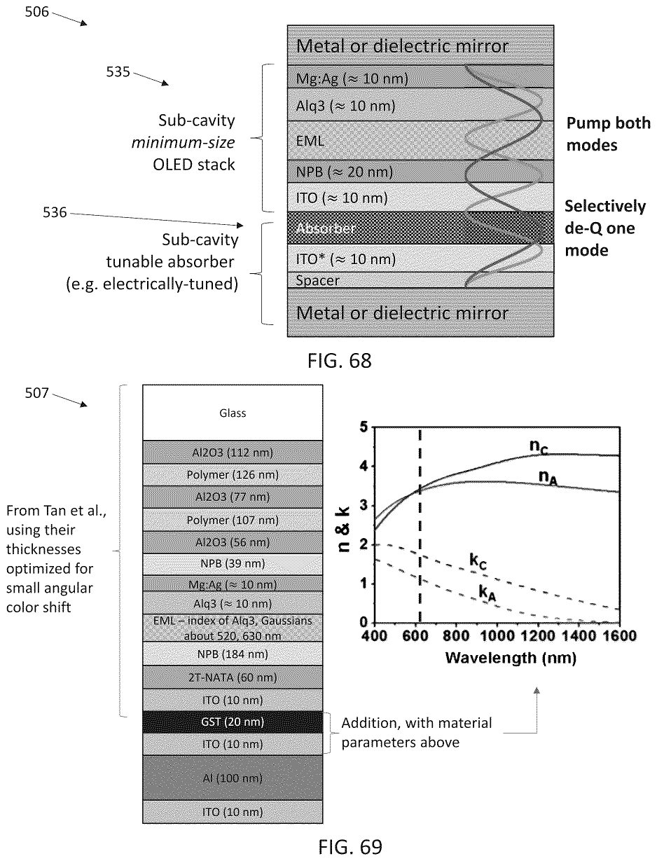

FIG. 68 is a diagram showing an exemplary neuromorphic opto-electronic device 506. Device 506 comprises a thin-film emitter structure comprised of an optical cavity, an emissive stack 535, and a tunable complex index stack 536. The cavity defines optical modes which can be populated by the emissive stack. The cavity modes can be modified depending on the state in which the tunable complex index film is set to, forming a programmable emissive pixel. The behavior depends on the choice of emitter stack, choice of tunable film stack, the mirror reflection as a function of wavelength, and the thickness of every film. ITO or other suitable transparent electrodes can be used for electrical control of the emissive and tunable absorption stack. In some embodiments, the device 506 can include electrochromic, thermochromic, photochromic and/or phase-change material. Parameters of the device 506 can be defined by:

$${\vert {EL}_{out} ( λ , θ ) \vert}^{2} = ( 1 - {R}_{2} ) {A}_{circ} ( λ , θ ) {e}^{- {α}^{λ} d} \times {\vert {EL}_{emit} ( λ ) \vert}^{2} \qquad ( 61 )$$

$${A}_{circ} ( λ , θ ) = {\vert 1 - {r}_{1}^{λ} {r}_{2}^{λ} {e}^{- 2 i {ϕ}^{λ} ( θ )} {e}^{- 2 {α}^{λ} d} \vert}^{- 2} \qquad ( 62 )$$

$$ϕ ( θ ) = \frac{2 π}{λ} nd \sqrt{1 - {( \frac{1}{n} )}^{2} {sin}^{2} θ} \qquad ( 63 )$$

For a tunable optical film comprising phase-change materials, when heated above a melting temperature and quickly quenched, their atomic structure can be scrambled, putting the film into an “amorphous” phase that is more transparent. When heated above a crystallization temperature for a longer period of time, the structure can be annealed back into a crystalline form that is more opaque. Refractive index changes are also observed. There is a wide range of phase change materials available, as well as other thin film materials with tunable optical properties such as electrochromic devices, photochromic devices, and epsilon near-zero materials, for example. Typically, individual films will require thicknesses of order wavelength to act as mirrors/cavities. Mirror film materials should have low absorption in the wavelength ranges of interest, and dielectrics are typically used. For absorption-based tuning, materials such as phase-change materials, chromic molecules (e.g. electrochromic, photochromic, thermochromic), III-V modulator or detector materials, and carrier-based films (e.g. pn junctions, epsilon-near zero stacks, etc.), or any other suitable material can be utilized.

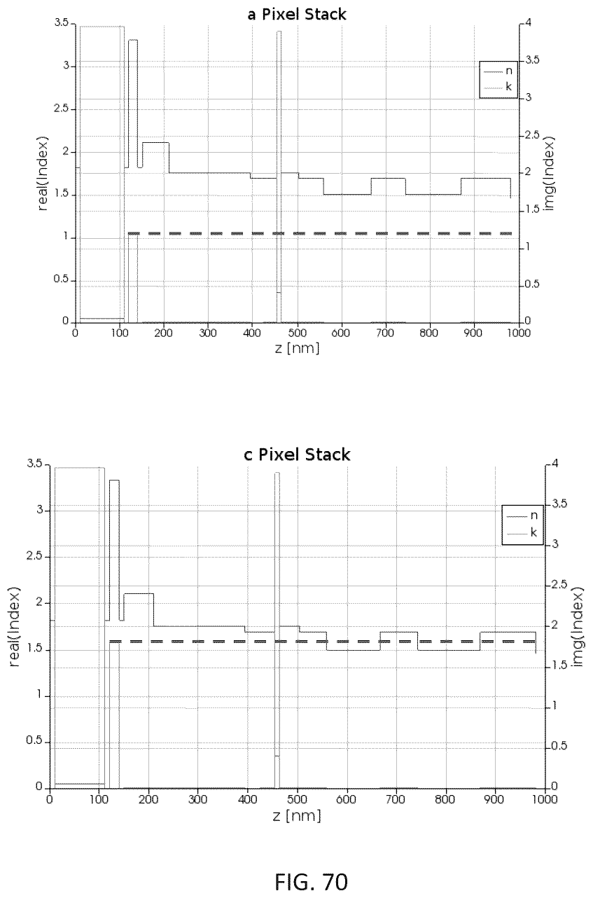

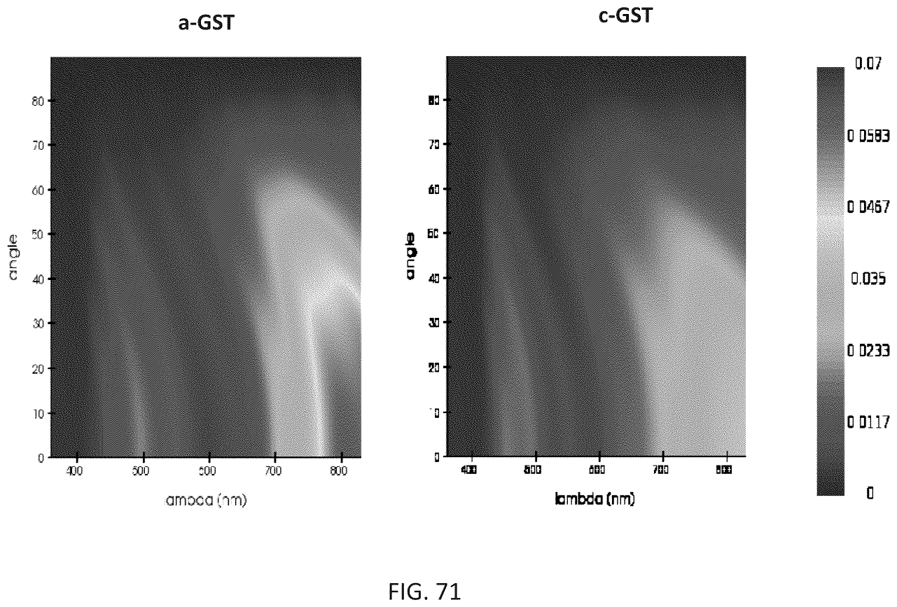

FIG. 69 is a diagram showing an exemplary experimental device 507. The emission was studied of a realistic microcavity OLED stack from the literature is affected by incorporating a thin GST (phase change material) film in the stack. The stack composition (left), and the different optical constants of the GST in amorphous (A) and crystalline (C) states are used (right) are shown. FIG. 70 shows the resulting complex index profile of the stack when the GST is amorphous (top) or crystalline (bottom). FIG. 71 shows normalized emission spectrum of the experimental stack as a function of wavelength (x-axes) and viewing angle (y-axes), for the GST film set to the amorphous state (left) or crystalline state (right). The emission is modified, leading to angle and color changes to a human viewer.

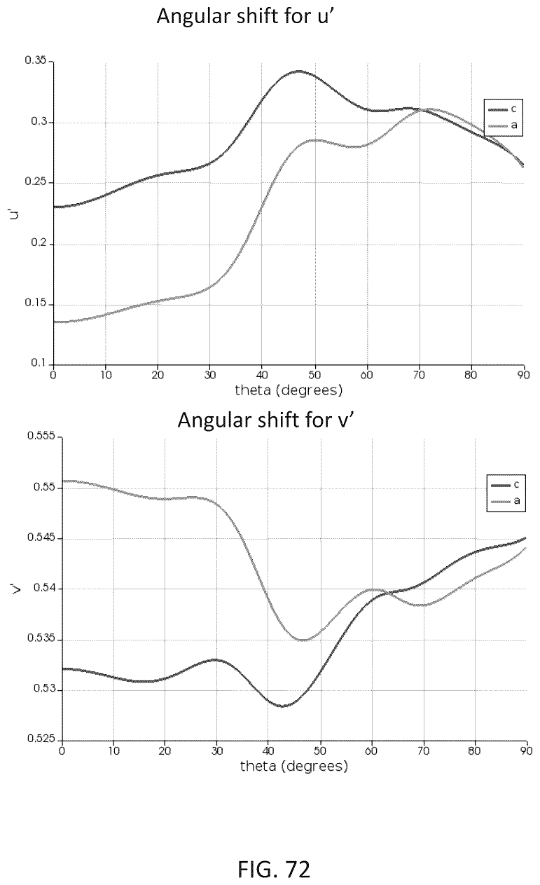

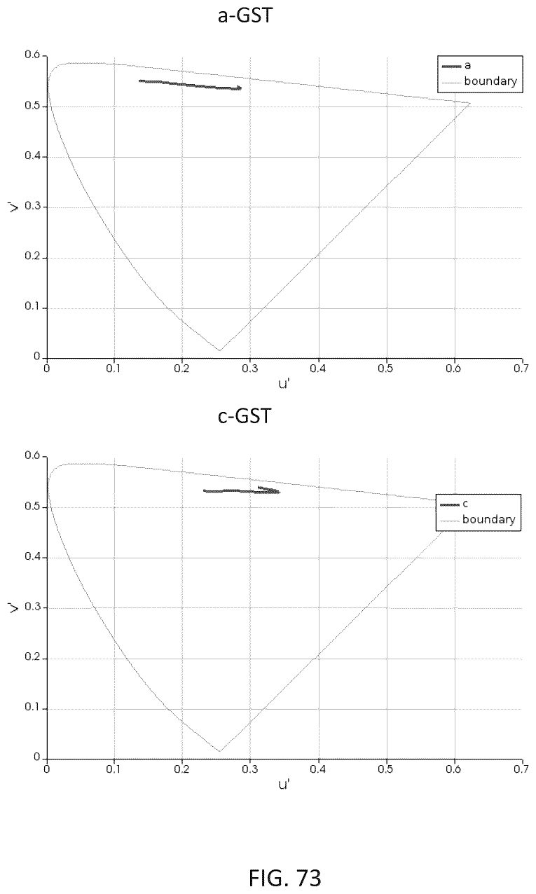

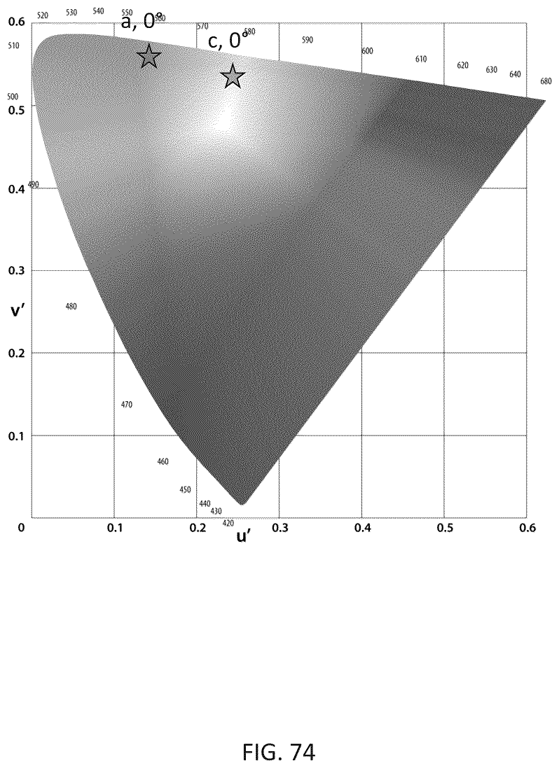

The spectra from the FIG. 71 were then converted to u*, v* color space coordinates. FIG. 72 shows angular dependence of the u* coordinate (top) and v* coordinate (bottom) if the GST is in the amorphous (green) or crystalline (blue) states. FIG. 73 shows the two curves from FIG. 72 plotted onto the u*-v* plane. Amorphous GST is the top, and crystalline bottom. FIG. 73 shows u*, v* color coordinates at 0 degree viewing angle for the stack having amorphous (a) or crystalline (c) film states. The change in emission angle and color of the entire stack as a function of tunable film state is demonstrated.

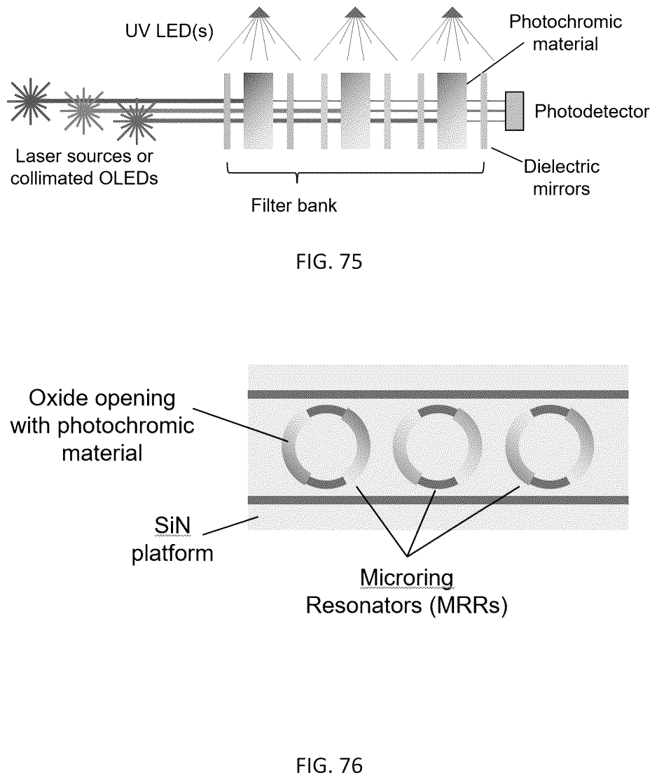

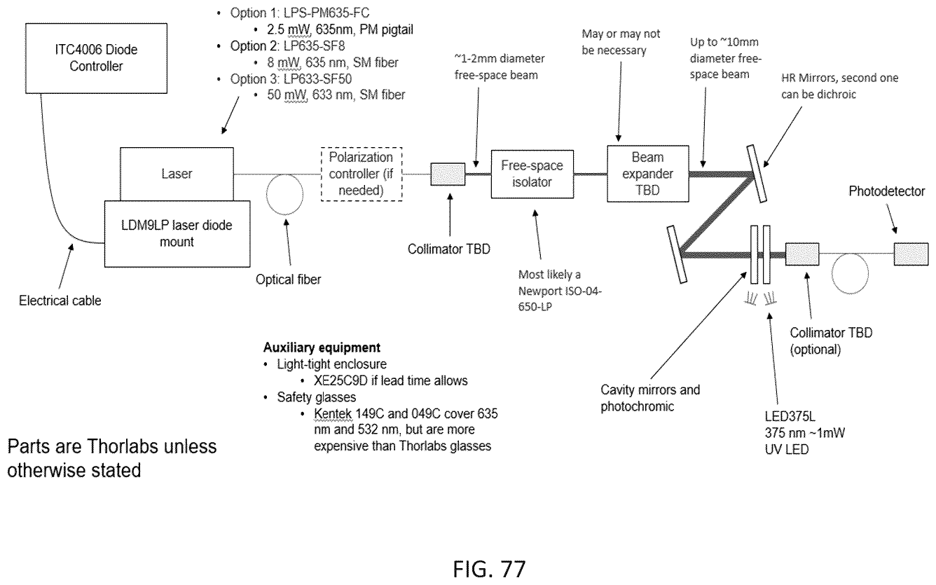

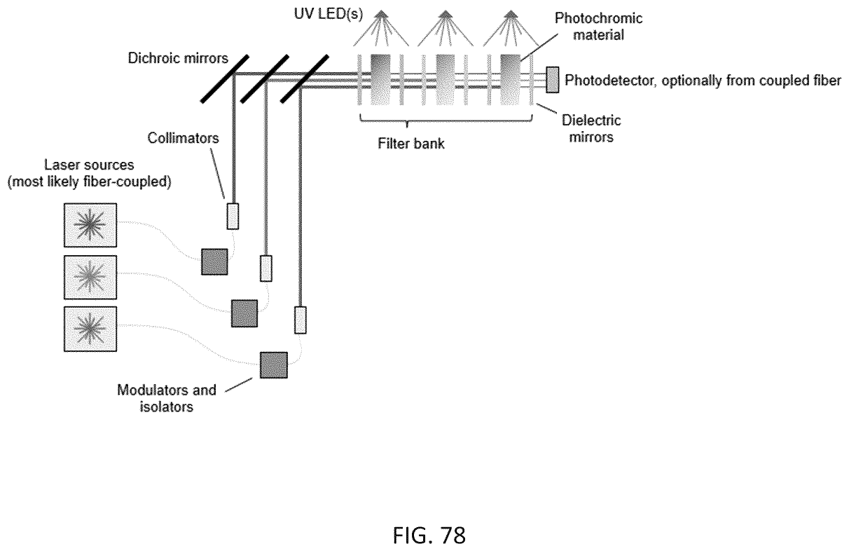

FIGS. 75-77 show details of experimental approaches. FIG. 75 shows a high-level overview of an experiment to validate the photochemical memristor device using free-space optics and discrete components. FIG. 76 shows the same, but for an integrated approach leveraging photonic integrated circuits. In the free-space approach the filter bank can be made up of discrete optical elements or a single thin-film stack and utilizing free-space optics allows for quick and easy setup and testing. The integrate approach allows for direct comparison with other integrated neuromorphic photonic approaches and allows for exploration of integration metrics such as on-chip footprint. FIG. 77 outlines components to be used for free-space experimentation. FIG. 78 shows further details on the free-space optics. The overall goal was to emulate OLED microcavities and integrated micro-resonators to inform future applications. The free-space approach allows for flexibility in component choice and rapid iteration. Large optics meant special care needed to be taken to properly emulate micro-scale physics.

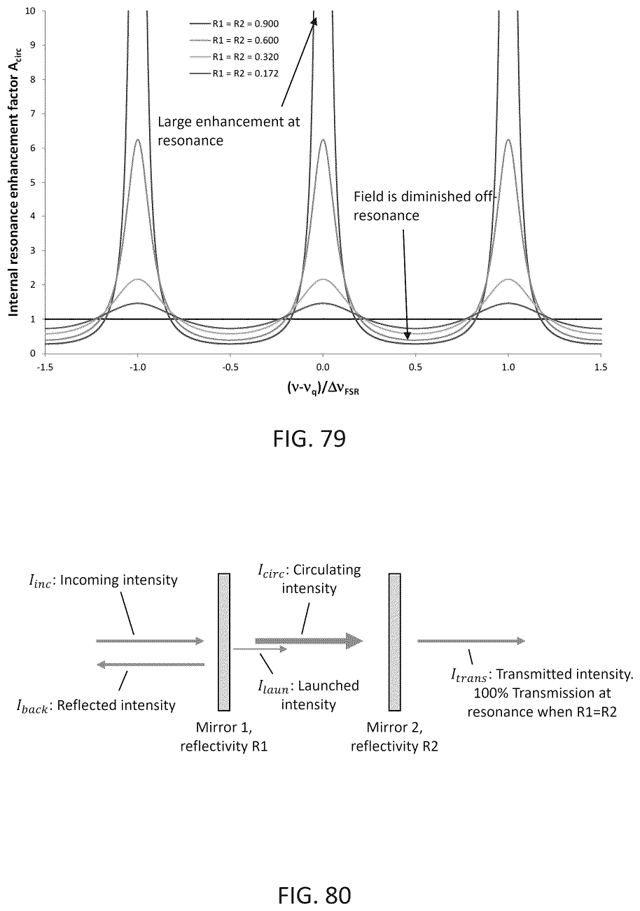

FIGS. 79-80 outline Fabry-Perot resonance enhancement presented in Ismail et al. (2016). The cavity field relative to light launched into the cavity is an internal enhancement. OLED micro-cavities behave similarly, but mode overlap affects resonance as well. The cavity field relative to light incident on mirror 1 is an external enhancement.

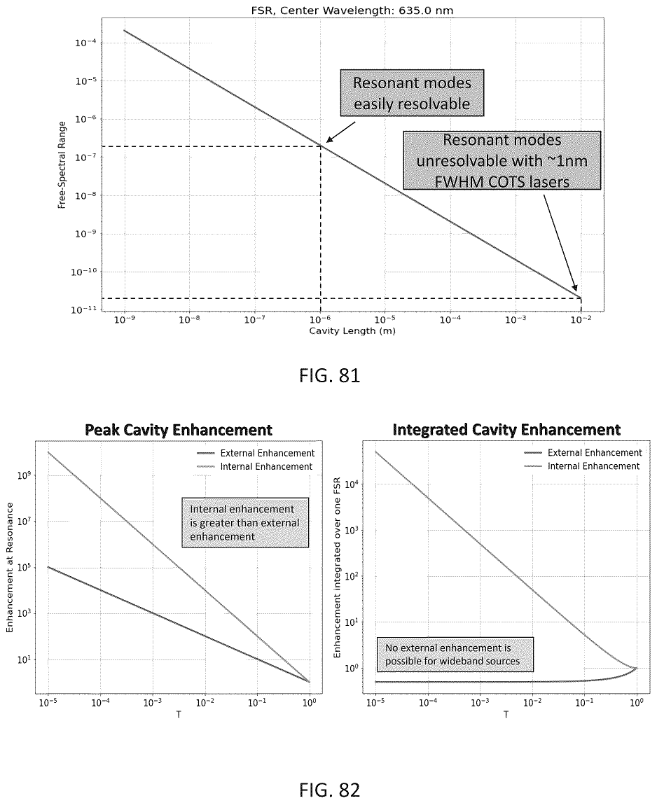

FIG. 81 outlines the spacing between modes as a function of optical cavity length. Modes are evenly spaced in frequency, so a particular wavelength needs to be chosen in order to convert to wavelength space. Cavity size (physical length and material index) determines the free-spectral range (FSR) which is the distance between adjacent resonant modes in frequency or wavelength space. At ˜μm cavity lengths, a VIS-band cavity will have an FSR of ˜10s of nm and resonant modes are easily resolved from one another. At ˜cm cavity lengths, a VIS-band cavity will have an FSR of ˜10s of pm and resonant modes will be impossible to resolve without exceptionally narrow-band lasers with active stabilization. FIG. 82 shows Integrated cavity enhancement refers to the enhancement for a light beam whose spectrum extends to greater than a cavity free-spectral range. Peak enhancement refers to the maximum enhancement for a monochromatic (single wavelength) light beam.

FIG. 83 outlines a way that ultra-thin cavities can be created using mirrors whose substrates are considerably larger than the cavity length. The cavity is formed by two closely spaced optical elements with front-surface high-reflectivity (HR) coatings. The cavity length can be reduced to small enough sizes to resolve FP resonance peaks and avoid mode-washout. The scanning intra-mirror distance can allow for mode tuning, thus removing the need for a tunable laser source. The substrate thickness doesn't impose additional cavity length, and process-sensitive photochromic compounds can be deposited as the final manufacturing step, thus increasing reliability.

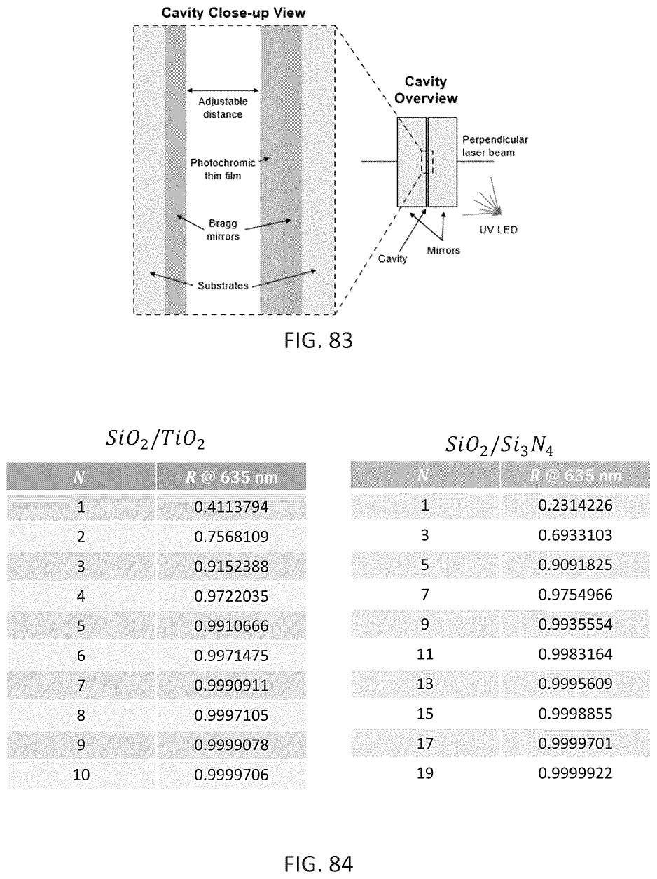

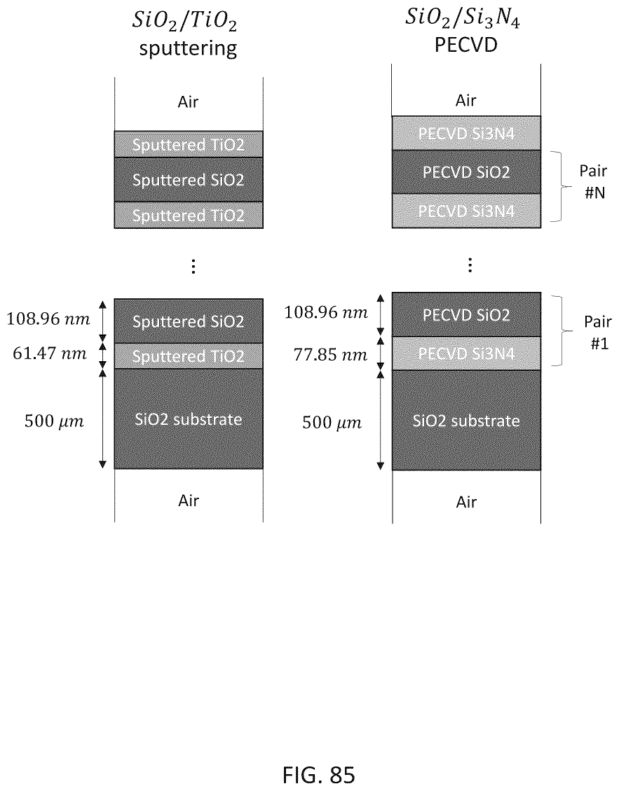

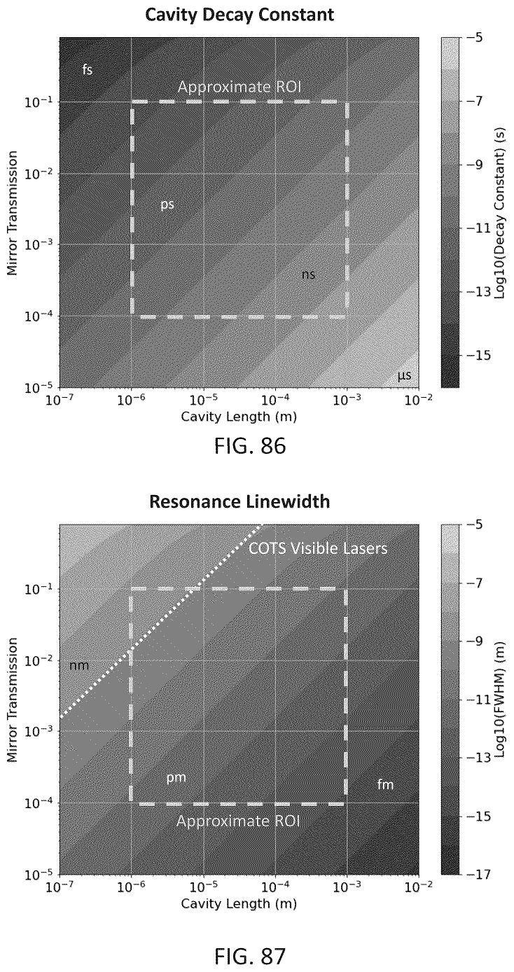

FIGS. 84-85 outline options for creating Bragg mirrors. FIGS. 86-87 are plots showing resonance cavity properties. FIG. 86 shows the cavity decay constant as a function of mirror transmission and cavity length. This is a measure of how long it takes to build up intra-cavity energy as well as how long intra-cavity energy remains once the source has been turned off. The cavity decay constant for small (<1 mm) cavities and relevant reflectivities (R˜0.99) will be much shorter than target photochromic dynamics and be on the order of milliseconds. FIG. 87. shows the resonance linewidth as a function of mirror transmission and cavity length. This is a measure of how far the wavelength of a source can be from the resonant wavelength of the cavity and still experience significant enhancement. The full width at half max (FWHM) for small (<1 mm) cavities and relevant reflectivities (R˜0.99) will be much smaller than most COTS visible lasers (Δλ˜1 nm).

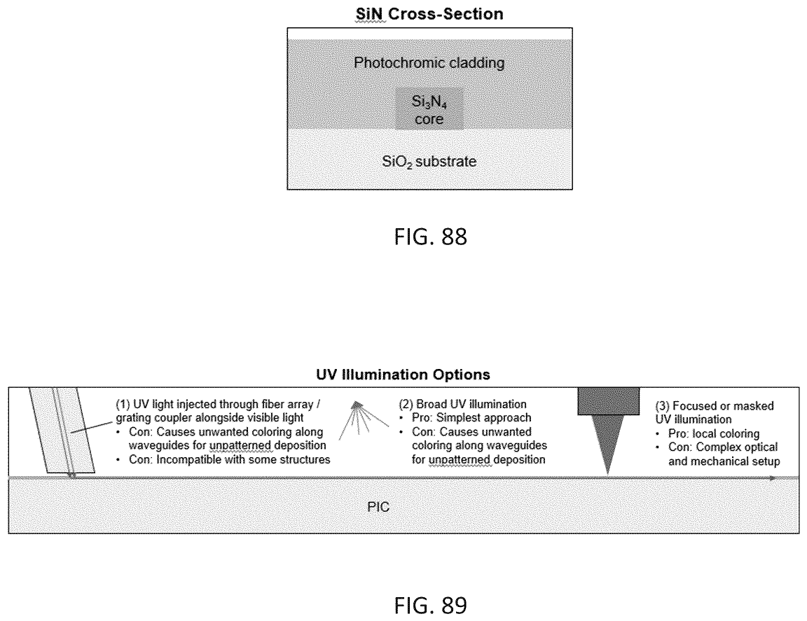

FIG. 88 outlines the material cross-section for an integrated approach, and FIG. 89 outlines ways by which one can deliver UV light to the photochromic cladding on the chip. Chips can be cladded with photochromic through evaporative deposition. Shadow-masking may allow photochromic patterning. Coloring will be driven by UV light, with several illumination options available. Decoloring will be driven by propagating visible light

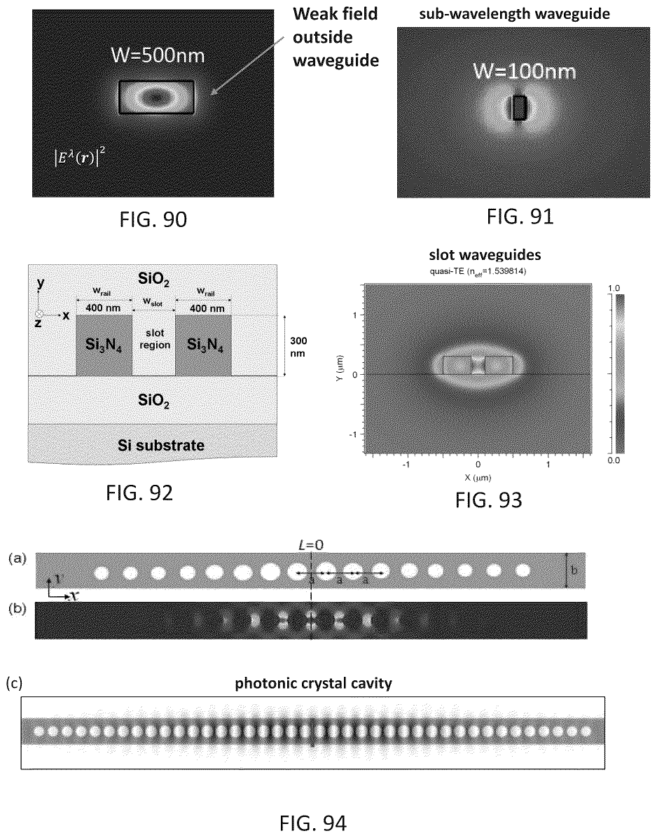

FIG. 90 shows a typical waveguide mode. Evanescent field is too weak for efficient interaction between UV and photochromic film. The interaction strength can be improved using sub-wavelength waveguides, slot waveguides, and/or photonic crystal cavities as shown in FIGS. 91-94. Shrinking a waveguide laterally can enhance its field outside of the waveguide itself as shown in FIG. 91. This can be defined by:

$$\frac{d {x}_{O} ( z , t )}{d t} = - {\sum }_{λ} {I}^{λ} ( z , t ) \cdot [ {ϵ}_{O}^{λ} {Φ}_{O \to C}^{λ} \cdot {x}_{O} ( z , t ) - {ϵ}_{C}^{λ} {Φ}_{C \to O}^{λ} \cdot {x}_{C} ( z , t ) ] with {x}_{O} + {x}_{C} = 1 , and {x}_{O / C} ( z , t ) = {N}_{O / C} ( z , t ) / N ( z ) . \qquad ( 64 )$$

In nanophotonic structures, the single mode profile can be defined as:

$${I}^{λ} ( r , t ) \to {I}_{0}^{λ} ( t ) \cdot {\vert {E}^{λ} ( r ) \vert}^{2} \qquad ( 65 )$$

and the modal index/loss as:

$${α}^{λ} = \frac{\int dV \cdot {\vert {E}^{λ} ( r ) \vert}^{2} \cdot [ ( {ϵ}_{O}^{λ} - {ϵ}_{C}^{λ} ) {x}_{O} ( r , t ) + {ϵ}_{C}^{λ} ] C ( r )}{\int dV \cdot {\vert {E}^{λ} ( r ) \vert}^{2}} \qquad ( 66 )$$

$$C ( r ) = \{ \begin{matrix}0 & for core , BOX \\ {w}_{\%} ρ {N}_{A} / {M}_{ph} & for clad\end{matrix} \qquad ( 67 )$$

FIG. 92 shows a typical slot waveguide, which is intended to enhance field presence outside of waveguides. FIG. 93 shows a top view of a photonic integrated circuit utilizing slot-waveguide microring resonators. Dielectric boundary conditions force the electric field in the slot region to be large compared to the field inside of the high-index regions. This can be defined by:

$${D}_{core} \cdot \hat{n} = {D}_{slot} \cdot \hat{n} \qquad ( 68 )$$

$${ε}_{core} {E}_{⊥}^{core} = {ε}_{slot} {E}_{⊥}^{slot} \qquad ( 69 )$$

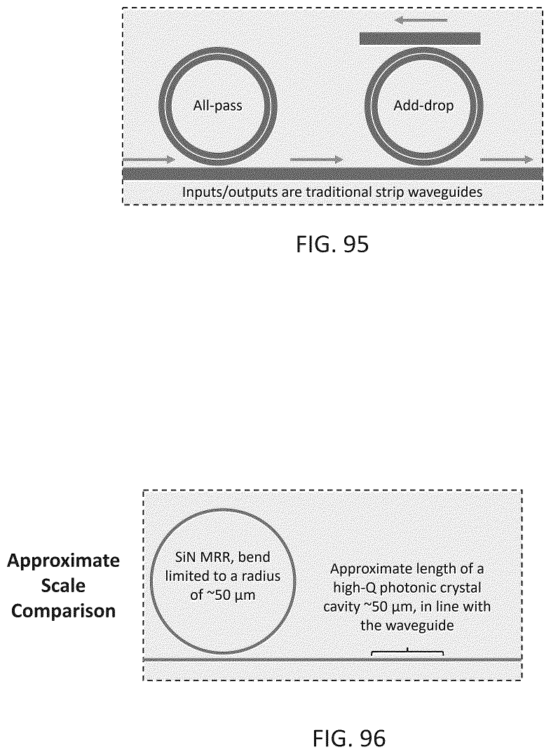

If εₛₗₒₜ<ε_{core}, then E_{⊥}^{slot}>E_{⊥}^{core}. Since the slot (and cladding) material will be photochromic, this results in interaction strength enhancement. FIG. 95 shows a PIC layout top view.

FIG. 94 shows an outline of photonic crystal design and performance. FIG. 96 shows an approximate comparison between the size of a microring resonator and a photonic crystal cavity. Tapered symmetrical holes in-line with a waveguide form a resonant cavity. Quadratic tapering forms a “Gaussian mirror,” which minimizes scattering to non-guided modes (radiation loss) while a symmetrical cavity results in high transmission. Field enhancement is proportional to the cavity Q-factor, which increases exponentially with the number of holes. Sub-wavelength structures increase field strength in cladding regions. In-line geometry can allow UV light to co-propagate with visible light without the need for precise mode control.

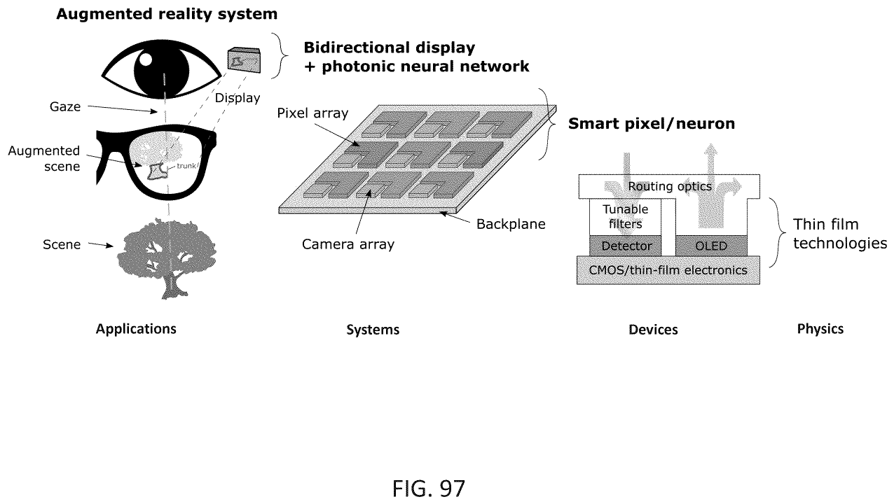

FIG. 97 shows a conceptual schematic of a system including imaging, processing, and display capabilities. AI applications can be enabled by photonic “smart pixels” that communicate through reconfigurable optical interconnections.

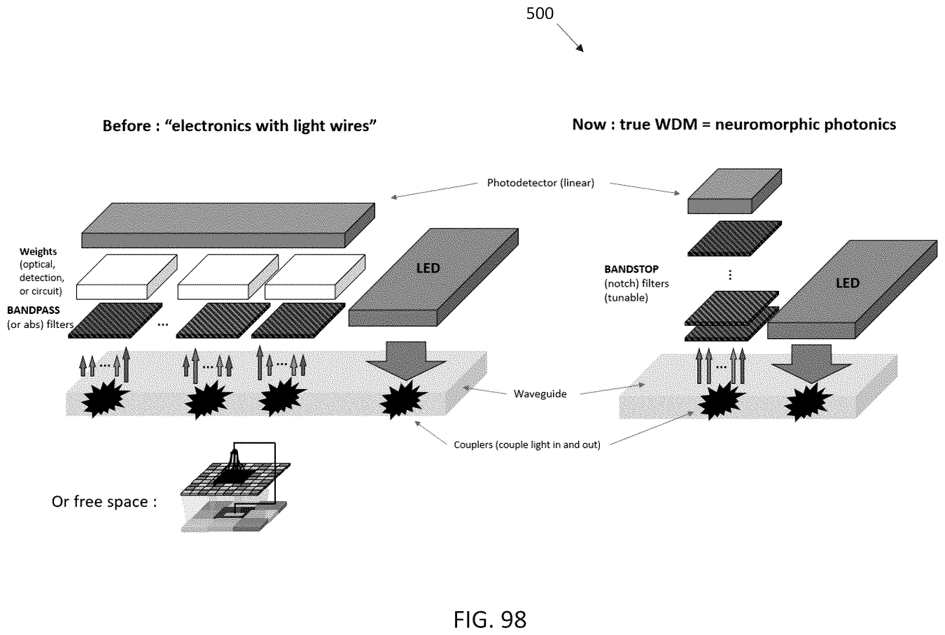

FIG. 98 generally contrasts between the past (left) and present (right) device architectures. For all-to-all interconnections of N neurons, the neuron footprint on the right has O(1) footprint scaling whereas the one on the left has O(N) footprint scaling, thus making it the present device architecture compact and scalable. The device 500 provides for true WDM, thus providing for neuromorphic photonics.

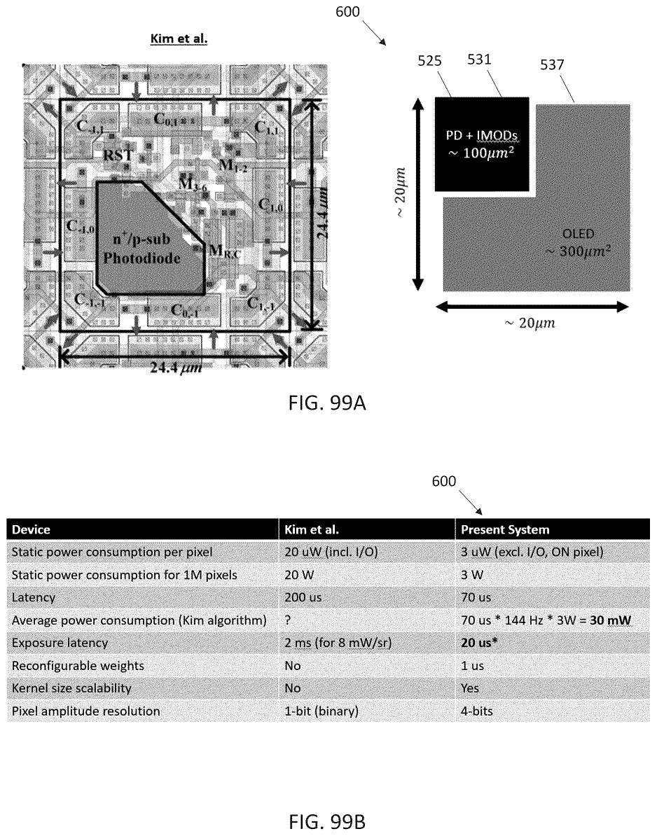

FIG. 99A generally contrasts between the past (left) electrical implementation system architecture and the equivalent present (right) neuromorphic opto-electronic system 600 architecture. FIG. 99B is a table showing further comparative details. In some embodiments, the neuromorphic opto-electronic system 600 includes at least one photodiode (PD), a thin film weight bank such as at least one interferometric modulator filter stack (IMODs), and at least one organic light emitting diode (OLED). In some embodiments, the photodetector can be used both for processing and imaging (input). In the example shown, the system 600 comprises 4-bits, 30A/W PD, 3×3 kernel, and weights, but any suitable number and arrangement of components is possible.

A variety of options were considered when designing a neuromorphic opto-electronic system 600 equivalent to the electrical implementation of Kim at al. Options for the interconnects included an 8-channel WDM, bidirectional synaptic waveguide, and scalability to more channels in the same waveguide. Options for the weighted sum included bandstop filter synaptic weighting, fast switching (1 us), a single photodetector and phototransistor, and scalability to more channels in the same area. Options for nonlinearity included a nonlinear analog circuit with direct OLED modulation (ReLU), fast dynamics (up to 250 MHz), OLED being the dominant power cost (static), and a good ON/OFF power ratio.

Advantages of optical interconnects for the OLED-based neuromorphic processor include re-use of information transmission medium (WDM in waveguides) providing a N:1 advantage, use of a single photodetector 525 for summing channels (one component for many channels) providing a N:1 advantage, and scalability where area x fan-in tradeoff is eliminated by stacking optical filters 531 which can increase fan-in without jeopardizing area and thus speed. The advantages over CMOS increase with increasing pixel resolution. Exposure latency can also be improved in CMOS electronics.

The system 600 can be manufactured in any suitable way. In some embodiments, the system 600 is manufactured via a first die (die 1) including a BiCMOS backplane with analog electronics, amplifiers, digital logic and memory, thin-film IMODs weights with MEMS or other thin film filter weight banks, and thin-film OLEDs deposited on top. A second die (die 2) including 3D-printed microoptic lenses and waveguides on a transparent substrate is then manufactured. A flip-chip bond placing die 2 on top of die 1 with micrometric alignment tolerance is then done. Alternatively, in some embodiments, if 3D-printing is non-abrasive, die 2 and flip-chip bonding will not be required.

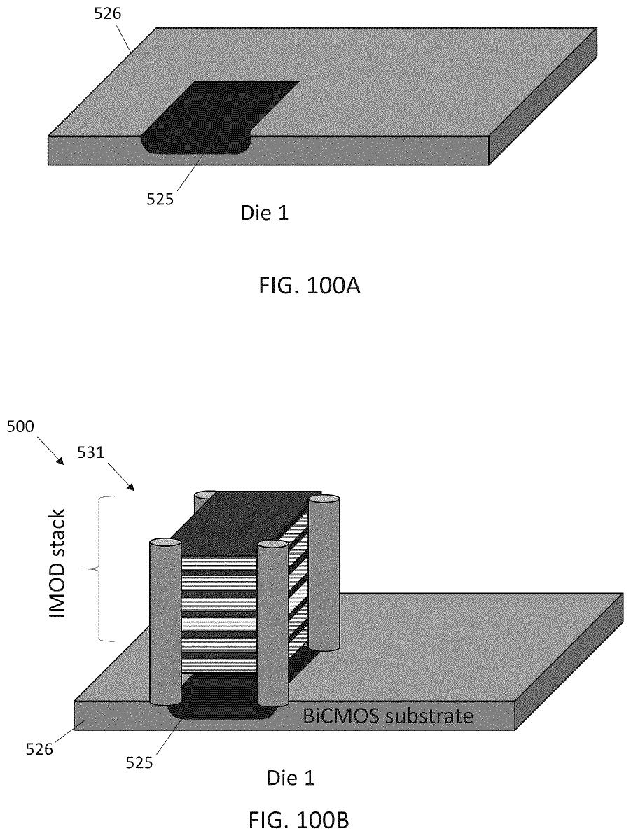

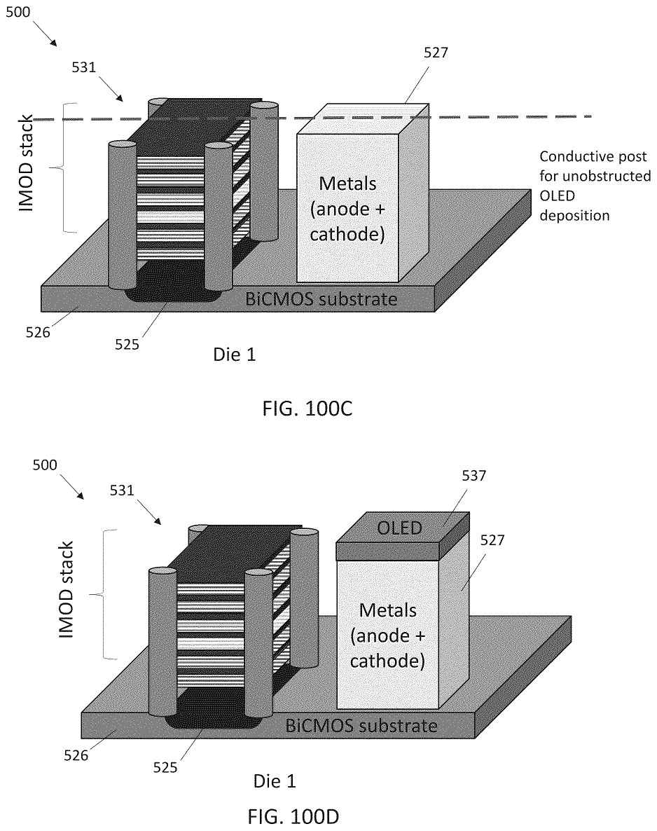

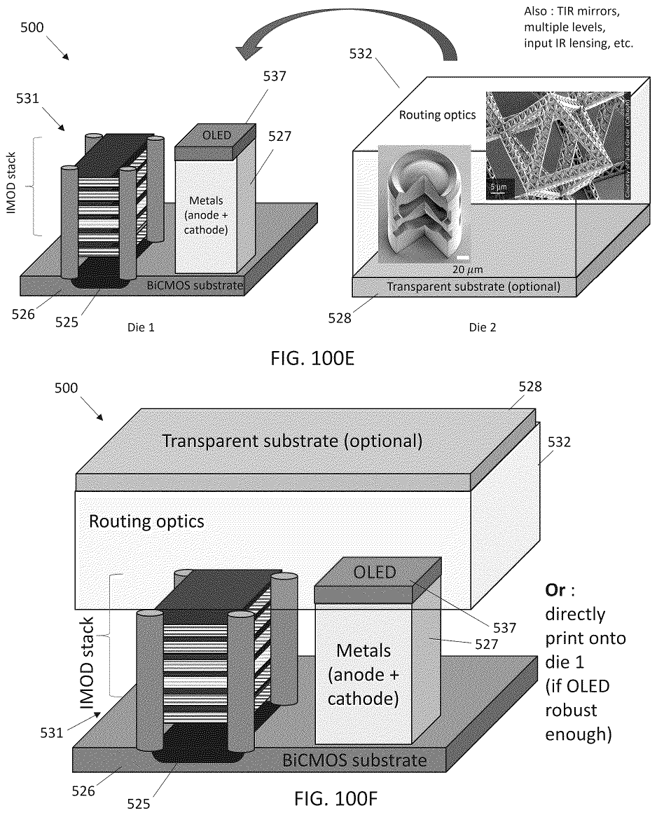

FIGS. 100A-F illustrate an exemplary manufacturing process for the system 600. FIG. 100A shows a first die (die 1) comprising a CMOS (of BiCMOS) substrate 526 with photodetectors 525. FIG. 100B shows the fabrication of a weight stack 531 (such as those described above for the neuromorphic device 500) above the photodetectors 525. FIG. 100C shows anode 527 formation adjacent to the weight stack 531, which provides a conductive post for unobstructed OLED deposition. The anode 527 can be thin if routing waveguides can be printed directly onto OLEDs. FIG. 100D shows OLED 537 deposition on the anode 527. FIG. 100 E and FIG. 100F show waveguide 532 formation. In some embodiments, the waveguide 532 is printed on a separate substrate 528 (die 2) and then heterogeneously integrated as shown in FIG. 100E. In some embodiments, the waveguide can be printed directly onto the structure as shown in FIG. 100F. The waveguide 532 can include 3D printed microoptics, TIR mirrors, multiple levels, input IR lensing, and/or other suitable structures.

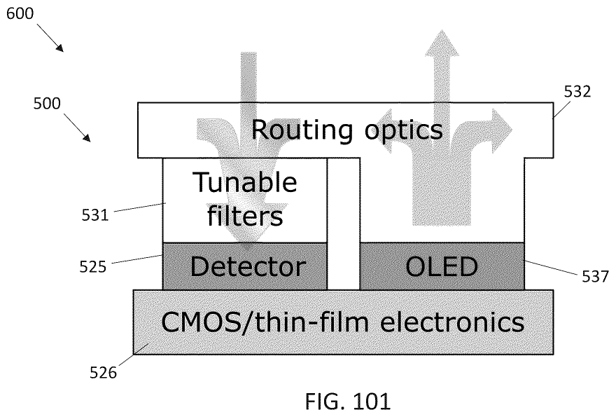

FIG. 101 depicts a general overview of an exemplary neuromorphic opto-electronic system 600. The system comprises a plurality of neuromorphic opto-electronic devices 500 including tunable filters 531 atop a photodetector 525 positioned on substrate 526 including CMOS and thin-film electronics. The system 600 further includes an OLED 537 adjacent to the photodetector 525, the OLED 537 being optically connected via a waveguide 532 to the photodetector 525.

In some embodiments, limitations on fabrication and/or performance may limit the number of available wavelengths for wavelength division multiplexing (WDM) weighting. By time multiplexing is implemented, the number of wavelengths required for computation can be reduced at the cost of additional time steps per operation. Simple bounds emerge for the general case of arbitrarily weighted convolution kernels. Convolution kernels with redundant weights allow for reduction in wavelengths and/or time steps used.

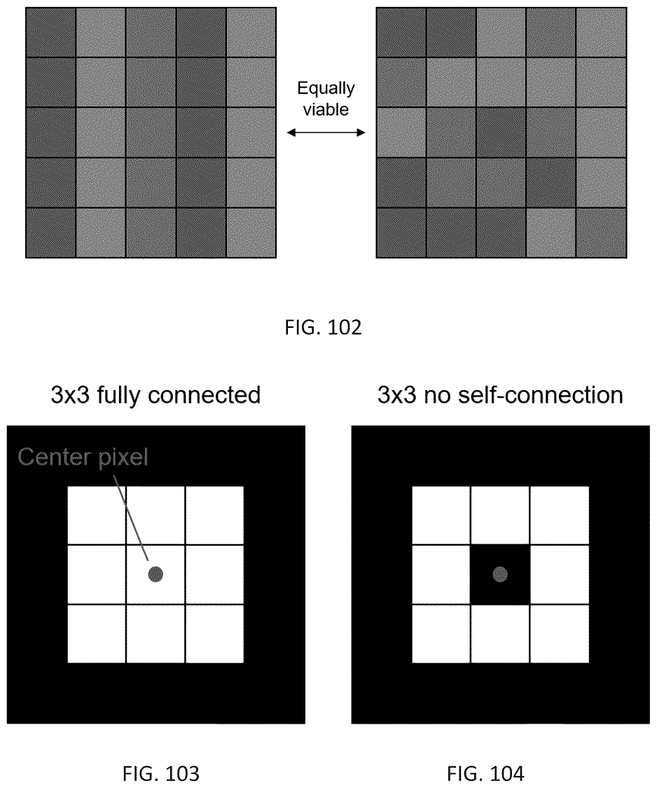

Referring now to FIGS. 102-104, time multiplexing assumptions are described. For the purposes of this explanation, assume a device with an arbitrarily large square arrangement of pixels, where each pixel has a light emitter with a fixed wavelength (color), a weighting mechanism that allows light of a chosen wavelength to be selectively attenuated without affecting light of other wavelengths, and a detector that is uniformly sensitive to all wavelengths (colors).

FIG. 102 illustrates that this scheme assumes pixels can be assigned wavelengths (colors) arbitrarily. For creating a device from scratch this point is somewhat arbitrary, but serves to say both that this scheme is compatible with conventional arrangements of pixels (e.g., RGB) and that this scheme does not require conventional arrangements of pixels. Assuming that the number of wavelengths available is fixed and that each pixel is assigned a fixed wavelength, in the general case, the pixel arrangement is chosen for optimal computing performance. In an example specific case of interest, RGB pixels are configured in a display-friendly arrangement.

FIGS. 103-104 serve to visually demonstrate what is meant by a connection neighborhood. The center pixel, illustrated as a red dot, emits light, which is subsequently routed to the detectors in each pixel, illustrated as a white square, within the connection neighborhood. FIG. 103 shows a 3×3 fully connected example, and FIG. 104 shows a 3×3 no self-connection example. A binary mask can be used to set what connections are available between pixels. In some embodiments, it can be assumed to be the same for every pixel and can furthermore correspond to physical connections. With arbitrary weighting, the connection neighborhood defines which elements of a convolution kernel can be nonzero.

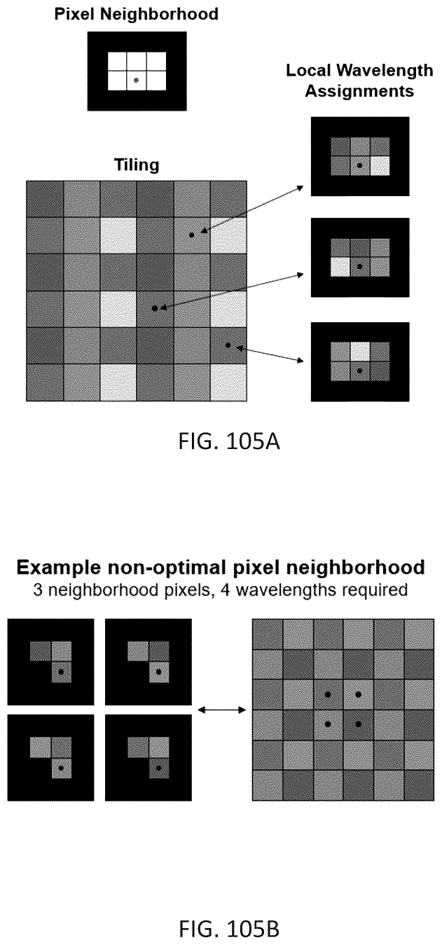

FIG. 105A shows a tiling with six colors implementing full wavelength-division multiplexing. With such an arrangement, all pixels are simultaneously illuminated. The “Local Wavelength Assignments” breakouts show how light incident on each pixel is distinguishable by wavelength. In other words, for each pixel in the array, light of a particular wavelength is known to have come from an unambiguous other pixel. When coupled with a wavelength-selective weighting mechanism, this allows arbitrary convolutional kernels with values in the range of [0,1] to be implemented, so long as the kernel being implemented matches the size of the connection neighborhood. Note that values in the range of [0,1] can be re-mapped to any bounded domain [a,b], where a and b are real numbers, which includes common choices for domain such as [−1,1]. FIG. 105B serves as an example of a wavelength assignment where four wavelengths are required to tile an array with a connection neighborhood of size 3. With enough assignable wavelengths, all computation can be performed in one time step as defined by:

$${N}_{H} \leq {N}_{λ} \leq {W}_{BB} {H}_{BB} \qquad ( 36 )$$

where N_{H} is the number of pixels in the pixel neighborhood, N_{λ} is the number of required wavelengths, and W_{BB}, H_{BB} are width and height, respectively of the pixel neighborhood bounding box.

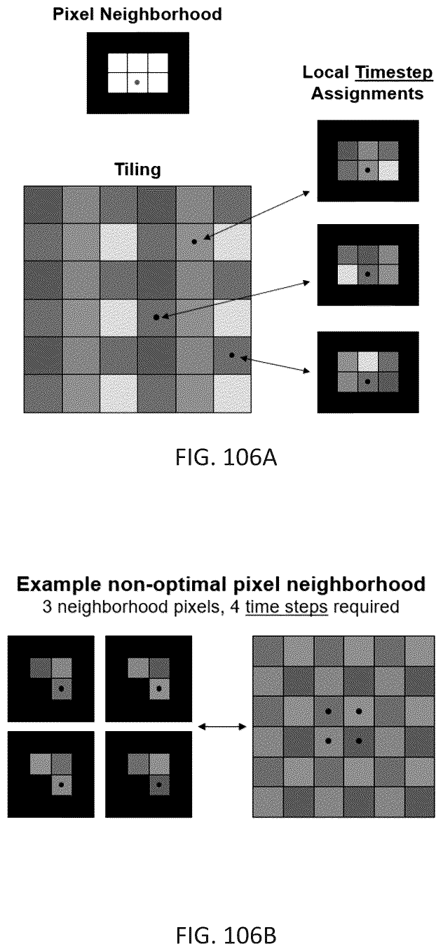

FIGS. 106A-B show a similar case to the case shown in FIGS. 105A-B, except in this case colors represent different steps in time (time-division multiplexing). In other words, only pixels with the same color are illuminated simultaneously, but all pixels can be a single wavelength. Rather than being distinguishable by wavelength, signals are distinguishable by the time at which they arrived at the detector. Weights can be re-adjusted between time steps in order to achieve the same behavior as a wavelength-selective weighting mechanism causes in the wavelength-division multiplexed case. With enough assignable time steps, all computation can be performed in one wavelength as defined by:

$${N}_{H} \leq {N}_{T} \leq {W}_{BB} {H}_{BB} \qquad ( 37 )$$

where N_{H} is the number of pixels in the pixel neighborhood, N_{T} is the number of required time steps, and W_{BB}, H_{BB} are width and height, respectively of the pixel neighborhood bounding box.

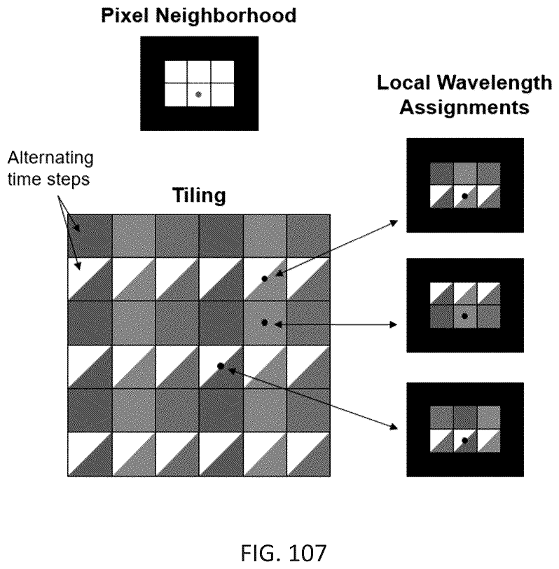

FIG. 107 demonstrates how wavelength-division multiplexing and time-division multiplexing can be used in conjunction with one another. The color refers to wavelength assignment while solid squares and half-filled squares represent two unique time steps. Signals incoming to a pixel's detector are then distinguishable both by their wavelength and by the time at which they arrived. This requires fewer time steps than the purely time-division multiplexed case and fewer unique wavelengths than the wavelength-division multiplexed case.

Performing different row operations on different time steps allows for a smaller number of wavelengths, where N_{λ}=W_{BB} is the number of required wavelengths, N_{T}=H_{BB} is the number of time steps, and W_{BB}, H_{BB} are the width and height of pixel neighborhood bounding box. In some embodiments, it is assumed that WDM weights are adjustable between multiplexing time steps. Furthermore, this is generalizable to any pixel neighborhood. Additionally, in some embodiments, wavelength and time multiplexing can be freely interchanged.

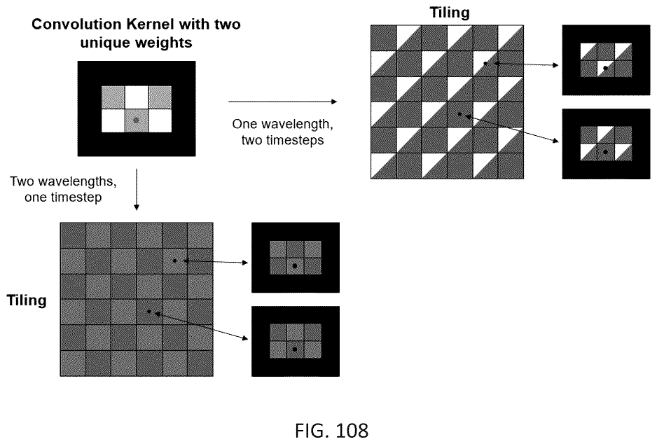

FIG. 108 illustrates how example convolutional kernels with redundant weights can allow fewer time steps (or unique wavelengths) than would be required in order to allow arbitrary convolutional kernels. In this case a connection neighborhood of size 6 requires only two time steps (or unique wavelengths) due to the redundancy of weight values in the convolutional kernel. If a convolution kernel has redundant weights, this can be leveraged to reduce the number of wavelengths and/or time steps necessary to carry out operations. One example application that this can be implemented in is an eye-tracking algorithm including a 3×3 kernel without self-connection only requiring one wavelength and timestep.

In some embodiments, wavelength multiplexing and time multiplexing can be traded off, allowing greater flexibility in system design where both dimensions behave identically for a convolution operation. In some embodiments, simple bounds exist at the limit of only wavelength division multiplexing (WDM) or time division multiplexing (TDM), as well as the intermediary case of WDM in one spatial dimension and TDM in another spatial dimension. Furthermore, convolution kernels with redundant weights allow for reduction in wavelengths and/or time steps used.

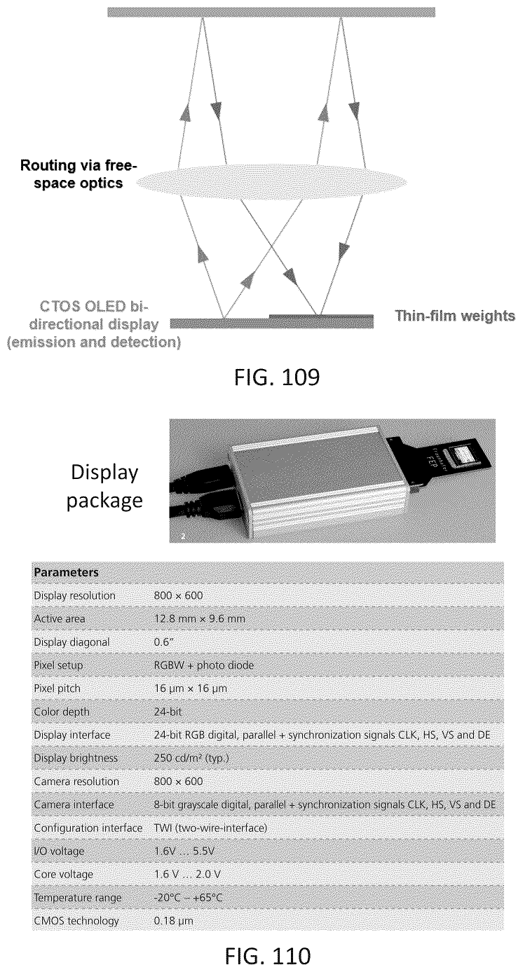

The integrated neuromorphic photonic system 600 of FIG. 101 was experimentally explored in a free-space emulation as shown in FIG. 109 using discrete components. Light routing, emission/detection, and weighting are separate components as compared to the system 600 of FIG. 101 where light routing, emission/detection, and weighting are all integrated on one substrate.

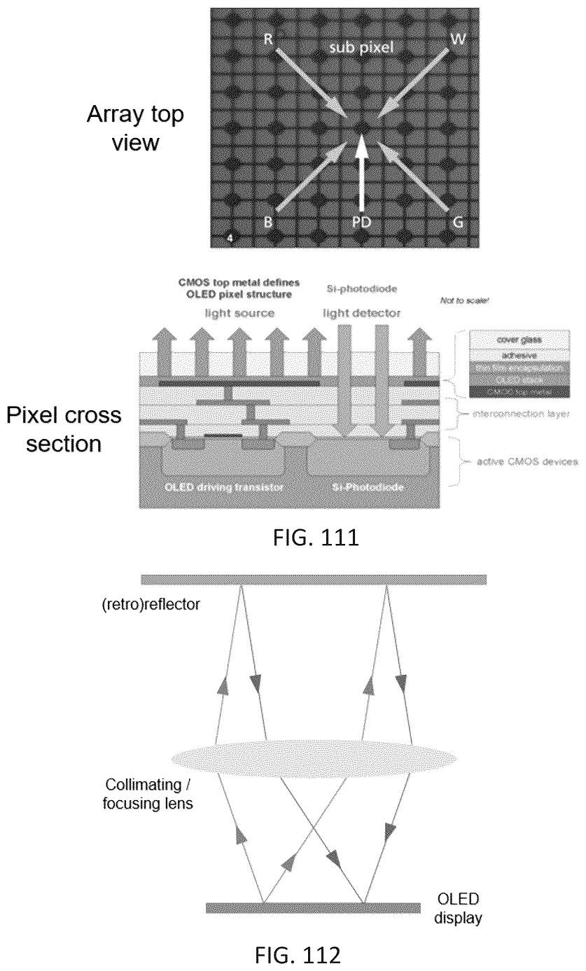

FIGS. 110-111 show details and specifications of a Fraunhofer bi-directional microdisplay used for experimentation. One important aspect was that every pixel had both emissive elements and a photodetector.

FIG. 112 shows the basic idea of a self-imaging concept. It was intended to emulate the connections that would be present in the integrated neuromorphic photonic system 600 through free-space optics rather than by 2-photon 3D printed waveguides, since doing so is considerably simpler and can be done using almost entirely commercially available parts. The convolution kernel is determined by the point-spread function (PSF) of the imaging system. Light from one part of the display is imaged onto another part for detection.

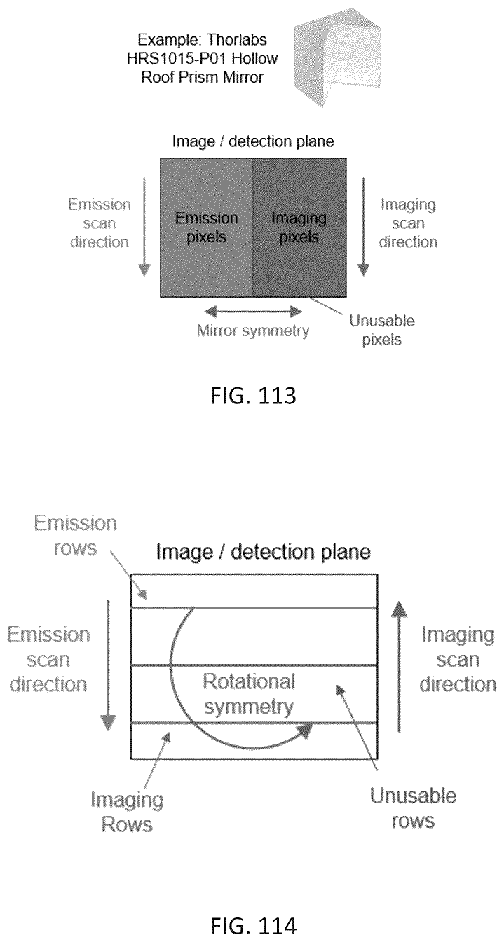

FIGS. 113-114 outline two ways in which part of the display can be used for emission while a separate part is used for detection. This eliminates the possibility of any nearby-pixel optical crosstalk. For the retroreflector example shown in FIG. 113, emission and imaging pixels scan in the same direction and slightly under half of each line is used for emission/imaging at a time. For the mirror example shown in FIG. 114, emission and imaging pixels scan in opposite directions, almost all full rows can be used, and only the center-most pixels self-image.

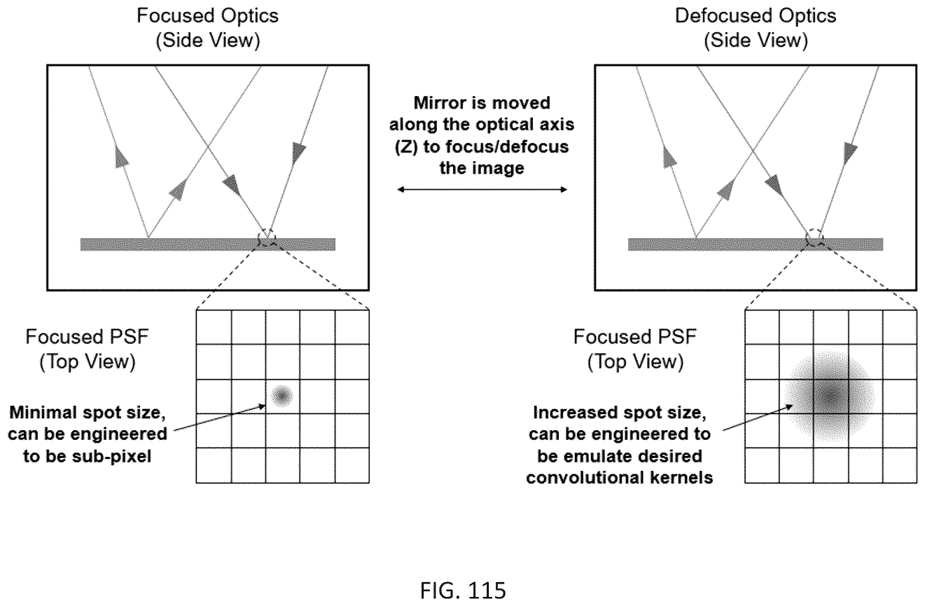

FIG. 115 outlines how defocusing can be used to create the desired convolutional kernel. One feature of free-space optics that is not generally applicable to the 3D-printed light routing case is that free-space PSFs, and consequently convolutional kernels, are typically radially symmetrical. This can be compensated for by adjusting weights accordingly, as long as some light is incident on each desired pixel.

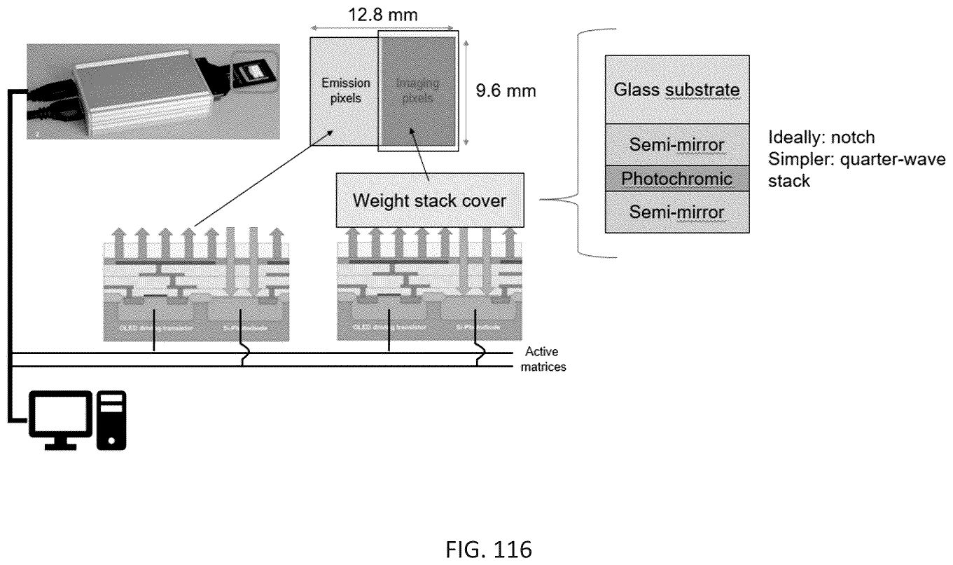

FIG. 116 shows how a separate thin-film weight stack can be used in conjunction with the Fraunhofer bi-directional display. A weight stack is placed over half of the array, so in conjunction with the free-space optics this forms the desired convolutional neural network of emission, networking (via free-space optics, not shown), weighting, and detection.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### REFERENCES

Each of the following publications are incorporated by reference herein in their entireties:
Kishino, K., Unlu, M. S., Chyi, J.-I., Reed, J., Arsenault, L., & Morkoc, H. (1991). Resonant cavity-enhanced (RCE) photodetectors. IEEE J. Quantum Electron., 27(8), 2025-2034. doi: 10.1109/3.83412
Van de Burgt, Y., Lubberman, E., Fuller, E. J., Keene, S. T., Faria, G. C., Agarwal, S., . . . . Salleo, A. (2017). A non-volatile organic electrochemical device as a low-voltage artificial synapse for neuromorphic computing. Nat. Mater., 16(4), 414-418. doi: 10.1038/nmat4856
Mao, J.-Y., Zhou, L., Zhu, X., Zhou, Y., & Han, S.-T. (2019). Photonic Memristor for Future Computing: A Perspective. Adv. Opt. Mater., 7(22), 1900766. doi: 10.1002/adom.201900766
Hosseini, P., Wright, C. D., & Bhaskaran, H. (2014). An optoelectronic framework enabled by low-dimensional phase-change films-Nature. Nature, 511(7508), 206-211. doi: 10.1038/nature13487
US Patent Application for TRANSFLECTIVE, PCM-BASED DISPLAY DEVICE Patent Application (Application #20200096795 issued Mar. 26, 2020)—Justia Patents Search. (2021 July 25). Retrieved from https://patents.justia.com/patent/20200096795
US Patent for Phase change material-based display device with resistive switching elements Patent (U.S. Pat. No. 10,884,267 issued Jan. 5, 2021)—Justia Patents Search. (2021 July 25). Retrieved from https://patents.justia.com/patent/10884267
Zhu, J., Zhang, T., Yang, Y., & Huang, R. (2020). A comprehensive review on emerging artificial neuromorphic devices. Appl. Phys. Rev., 7(1), 011312. doi: 10.1063/1.5118217
Zhuge, X., Wang, J., & Zhuge, F. (2019). Photonic Synapses for Ultrahigh-Speed Neuromorphic Computing. Phys. Status Solidi RRL, 13(9), 1900082. doi: 10.1002/pssr.201900082
Goi, E., Zhang, Q., Chen, X., Luan, H., & Gu, M. (2020). Perspective on photonic memristive neuromorphic computing. Photonix, 1(1), 1-26. doi: 10.1186/s43074-020-0001-6
Cheng, Z., Ríos, C., Pernice, W. H. P., Wright, C. D., & Bhaskaran, H. (2017). On-chip photonic synapse. Sci. Adv., 3(9), e1700160. doi: 10.1126/sciadv.1700160
Ramos, M., Bharadwaj, V., Sotillo, B., Gholipour, B., Giakoumaki, A. N., Ramponi, R., . . . . Soci, C. (2021). Photonic implementation of artificial synapses in ultrafast laser inscribed waveguides in chalcogenide glass. Appl. Phys. Lett., 119(3), 031104. doi: 10.1063/5.0055067
Gholipour, B., Bastock, P., Craig, C., Khan, K., Hewak, D., & Soci, C. (2015). Amorphous Metal-Sulphide Microfibers Enable Photonic Synapses for Brain-Like Computing. Adv. Opt. Mater., 3(5), 635-641. doi: 10.1002/adom.201400472
Rhim, S.-Y., Ligorio, G., Hermerschmidt, F., Hildebrandt, J., Pätzel, M., Hecht, S., & List-Kratochvil, E. J. W. (2020). Using Active Surface Plasmons in a Multibit Optical Storage Device to Emulate Long-Term Synaptic Plasticity. Phys. Status Solidi A, 217(20), 2000354. doi: 10.1002/pssa.202000354
Tanimoto, K., Amemiya, Y., & Yokoyama, S. (2018). Optical waveguides with memory effect using photochromic material for neural network. Jpn. J. Appl. Phys., 57(4S), 04FH02. doi: 10.7567/jjap.57.04fh02
Shelton, D. P. (1997). Bacteriorhodopsin optoelectronic synapses. Opt. Lett., 22 (22), 1728-1730. doi: 10.1364/OL.22.001728
Y. LeCun, Y. Bengio, and G. Hinton, “Deep learning,” Nature, vol. 521, no. 7553, pp. 436-444, May 2015. [Online]. Available: https://www.nature.com/articles/nature14539
V. Sze, Y.-H. Chen, T.-J. Yang, and J. S. Emer, “Efficient Processing of Deep Neural Networks: A Tutorial and Survey,” Proceedings of the IEEE, vol. 105, no. 12, pp. 2295-2329 December 2017.
N. P. Jouppi, C. Young, N. Patil, D. Patterson, G. Agrawal, R. Bajwa, S. Bates, S. Bhatia, N. Boden, A. Borchers, R. Boyle, P.-I. Cantin, C. Chao, C. Clark, J. Coriell, M. Daley, M. Dau, J. Dean, B. Gelb, T. V. Ghaemmaghami, R. Gottipati, W. Gulland, R. Hagmann, C. R. Ho, D. Hogberg, J. Hu, R. Hundt, D. Hurt, J. Ibarz, A. Jaffey, A. Jaworski, A. Kaplan, H. Khaitan, A. Koch, N. Kumar, S. Lacy, J. Laudon, J. Law, D. Le, C. Leary, Z. Liu, K. Lucke, A. Lundin, G. MacKean, A. Maggiore, M. Mahony, K. Miller, R. Nagarajan, R. Narayanaswami, R. Ni, K. Nix, T. Norrie, M. Omernick, N. Penukonda, A. Phelps, J. Ross, M. Ross, A. Salek, E. Samadiani, C. Severn, G. Sizikov, M. Snelham, J. Souter, D. Steinberg, A. Swing, M. Tan, G. Thorson, B. Tian, H. Toma, E. Tuttle, V. Vasudevan, R. Walter, W. Wang, E. Wilcox, and D. H. Yoon, “In-Datacenter Performance Analysis of a Tensor Processing Unit,” arXiv: 1704.04760 [cs], April 2017, arXiv: 1704.04760. [Online]. Available: http://arxiv.org/abs/1704.04760
B. Rumberg and D. W. Graham, “A low-power field-programmable analog array for wireless sensing,” in Sixteenth International Symposium on Quality Electronic Design, March 2015, pp. 542-546, ISSN: 1948-3295.
H.-T. Peng, J. Lederman, L. Xu, T. F. de Lima, C. Huang, B. Shastri, D. Rosenbluth, and P. Prucnal, “A Photonic-Circuits-Inspired Compact Network: Toward Real-Time Wireless Signal Classification at the Edge,” arXiv: 2106.13865 [cs, eess], June 2021, arXiv: 2106.13865. [Online]. Available: http://arxiv.org/abs/2106.13865
L. Chua and L. Yang, “Cellular neural networks: theory,” IEEE Transactions on Circuits and Systems, vol. 35, no. 10, pp. 1257-1272 October 1988.
L. Chua and L. Yang, “Cellular neural networks: applications,” IEEE Transactions on Circuits and Systems, vol. 35, no. 10, pp. 1273-1290 October 1988. [Online]. Available: https://ieeexplore.ieee.org/document/7601/
D. Kim and G. Han, “A 200 s Processing Time Smart Image Sensor for an Eye Tracker Using Pixel-Level Analog Image Processing,” IEEE Journal of Solid-State Circuits, vol. 44, no. 9, pp. 2581-2590 September 2009.
G. Gallego, T. Delbruck, G. M. Orchard, C. Bartolozzi, B. Taba, A. Censi, S. Leutenegger, A. Davison, J. Conradt, K. Daniilidis, and D. Scaramuzza, “Event-based Vision: A Survey,” IEEE Transactions on Pattern Analysis and Machine Intelligence, pp. 1-1, 2020. [Online]. Available: https://ieeexplore.ieee.org/document/9138762/
J. W. Goodman, “Fan-in and Fan-out with Optical Interconnections,” Optica Acta: International Journal of Optics, vol. 32, no. 12, pp. 1489-1496 December 1985. [Online]. Available: https://doi.org/10.1080/713821684
A. N. Tait, A. X. Wu, T. F. de Lima, E. Zhou, B. J. Shastri, M. A. Nahmias, and P. R. Prucnal, “Microring Weight Banks,” IEEE Journal of Selected Topics in Quantum Electronics, vol. 22, no. 6, pp. 312-325, November 2016.
“Optical Microresonator Theory,” in Optical Microresonators: Theory, Fabrication, and Applications, ser. Optical Sciences, J. Heebner, R. Grover, and T. Ibrahim, Eds. New York, NY: Springer, 2008, pp. 71-103. [Online]. Available: https://doi.org/10.1007/978-0-387-73068-43 P. Yeh, Optical waves in layered media. Hoboken, NJ: Wiley, 2005.
N. Ismail, C. C. Kores, D. Geskus, and M. Pollnau, “Fabry-Perot resonator: spectral line shapes, generic and related Airy distributions, linewidths, finesses, and performance at low or frequency-dependent reflectivity,” Optics Express, vol. 24, no. 15, pp. 16 366-16 389, July 2016. [Online]. Available: https://www.osapublishing.org/oe/abstract.cfm?uri=oe-24-15-16366
M. S. Unlu and S. Strite, “Resonant cavity enhanced photonic devices,” Journal of Applied Physics, vol. 78, no. 2, pp. 607-639, July 1995. [Online]. Available: https://aip.scitation.org/doi/10.1063/1.360322
J.-B. A. Perot and C. Fabry, “Theorie et applications d'une nouvelle methode de spectroscopie interferentielle,” Ann. Chim. Phys, vol. 16, no. 7.
K. Kishino, M. Unlu, J.-I. Chyi, J. Reed, L. Arsenault, and H. Morkoc, “Resonant cavity-enhanced (RCE) photodetectors,” IEEE Journal of Quantum Electronics, vol. 27, no. 8, pp. 2025-234 August 1991. [Online]. Available: http://ieeexplore.ieee.org/document/83412/
E. F. Schubert, Y. Wang, A. Y. Cho, L. Tu, and G. J. Zydzik, “Resonant cavity light-emitting diode,” Applied Physics Letters, vol. 60, no. 8, pp. 921-923, February 1992. [Online]. Available: https://aip.scitation.org/doi/10.1063/1.106489
P. Hosseini, C. D. Wright, and H. Bhaskaran, “An optoelectronic framework enabled by low-dimensional phase-change films,” Nature, vol. 511, no. 7508, pp. 206-211, July 2014. [Online]. Available: https://www.nature.com/articles/nature13487
C. Williams, N. Hong, M. Julian, M. Julian, S. Borg, H. J. Kim, and H. J. Kim, “Tunable mid-wave infrared Fabry-Perot bandpass filters using phase-change GeSbTe,” Optics Express, vol. 28, no. 7, pp. 10 583-10 594, March 2020. [Online]. Available: https://www.osapublishing.org/oe/abstract.cfm?uri=oe-28-7-10583
Y. Wang, B. Siegmund, Z. Tang, Z. Ma, J. Kublitski, S. Xing, V. C. Nikolis, S. Ullbrich, Y. Li, J. Benduhn, D. Spoltore, K. Vandewal, and K. Leo, “Stacked Dual-Wavelength Near-Infrared Organic Photodetectors,” Advanced Optical Materials, vol. 9, no. 6, p. 2001784, 2021. [Online]. Available: https://onlinelibrary.wiley.com/doi/abs/10.1002/adom.202001784
M. Wuttig, H. Bhaskaran, and T. Taubner, “Phase-change materials for non-volatile photonic applications,” Nature Photonics, vol. 11, no. 8, pp. 465-476, August 2017. [Online]. Available: https://www.nature.com/articles/nphoton.2017.126
S. J. Byrnes, “Multilayer optical calculations,” arXiv: 1603.02720 [physics], December 2020, arXiv: 1603.02720 version: 5. [Online]. Available: http://arxiv.org/abs/1603.02720
S. Ilyas, T. B\ddot{ } ocking, K. Kilian, P. J. Reece, J. Gooding, K. Gaus, and M. Gal, “Porous silicon based narrow line-width rugate filters,” Optical Materials, vol. 29, no. 6, pp. 619-622, February 2007. [Online]. Available: https://www.sciencedirect.com/science/article/pii/S092534670500491X
“Fundamental Building Blocks,” in Silicon Photonics Design: From Devices to Systems, L. Chrostowski and M. Hochberg, Eds. Cambridge: Cambridge University Press, 2015, pp. 92-161. [Online]. Available: https://www.cambridge.org/core/books/silicon-photonics-design/fundamentalbuilding-blocks/BDB9B04BEF6D0B02AC7FF32909E1D1FB
G. Kovacs, N. Maluf, and K. Petersen, “Bulk micromachining of silicon,” Proceedings of the IEEE, vol. 86, no. 8, pp. 1536-1551 August 1998.
W. H. Southwell, “Using apodization functions to reduce sidelobes in rugate filters,” Applied Optics, vol. 28, no. 23, pp. 5091-594 December 1989. [Online]. Available: https://www.osapublishing.org/ao/abstract.cfm?uri=ao-28-23-5091
E. P. Papageorgiou, B. E. Boser, and M. Anwar, “Chip-Scale Angle-Selective Imager for In Vivo Microscopic Cancer Detection,” IEEE transactions on biomedical circuits and systems, vol. 14, no. 1, pp. 91-103, February 2020. [Online]. Available: https://www.ncbi.nlm.nih.gov/pmc/articles/PMC7800072/
J. A. Dobrowolski, “The impact of computers on the design and manufacture of optical multilayer coatings during the past 50 years,” 50th Annual Technical Conference Proceedings, pp. 289-301, 2008.
S. Larouche and L. Martinu, “OpenFilters: open-source software for the design, optimization, and synthesis of optical filters,” Applied Optics, vol. 47, no. 13, pp. C219-C230, May 2008. [Online]. Available: https://www.osapublishing.org/ao/abstract.cfm?uri=ao-47-13-C219
E. Delano, “Fourier Synthesis of Multilayer Filters*,” JOSA, vol. 57, no. 12, pp. 1529-1533 December 1967. [Online]. Available: https://www.osapublishing.org/josa/abstract.cfm?uri=josa-57-12-1529
W. J. Gunning, R. L. Hall, F. J. Woodberry, W. H. Southwell, and N. S. Gluck, “Codeposition of continuous composition rugate filters,” Applied Optics, vol. 28, no. 14, pp. 2945-2948 July 1989. [Online]. Available: https://www.osapublishing.org/ao/abstract.cfm?uri=ao-28-14-2945
M. M. Hawkeye and M. J. Brett, “Glancing angle deposition: Fabrication, properties, and applications of micro- and nanostructured thin films,” Journal of Vacuum Science & Technology A: Vacuum, Surfaces, and Films, vol. 25, no. 5, p. 1317, 2007. [Online]. Available: http://scitation.aip.org/content/avs/journal/jvsta/25/5/10.1116/1.2764082
J. Zhang, Y. Xie, X. Cheng, H. Jiao, and Z. Wang, “Thin-film thickness-modulated designs for optical minus filter,” Applied Optics, vol. 52, no. 23, pp. 5788-5793 August 2013. [Online]. Available: https://www.osapublishing.org/ao/abstract.cfm?uri=ao-52-23-5788
Oggioni L, Pariani G, Zamkotsian F, Bertarelli C, Bianco A. Holography with Photochromic Diarylethenes. Materials (Basel). 2019; 12(17): 2810. Published 2019 Sep. 1. doi: 10.3390/ma12172810
A. V. Tikhonravov, M. K. Trubetskov, and G. W. DeBell, “Application of the needle optimization technique to the design of optical coatings,” Applied Optics, vol. 35, no. 28, pp. 5493-558 October 1996. [Online]. Available: https://www.osapublishing.org/ao/abstract.cfm?uri=ao-35-28-5493
A. Jiang, Y. Osamu, and L. Chen, “Multilayer optical thin film design with deep Q learning,” Scientific Reports, vol. 10, no. 1, p. 12780, July 2020. [Online]. Available: https://www.nature.com/articles/s41598-020-69754-w
C. Errando-Herranz, A. Y. Takabayashi, P. Edinger, H. Sattari, K. B. Gylfason, and N. Quack, “MEMS for Photonic Integrated Circuits,” IEEE Journal of Selected Topics in Quantum Electronics, vol. 26, no. 2, pp. 1-16, March 2020.
C.-d. Liao and J.-c. Tsai, “The Evolution of MEMS Displays,” IEEE Transactions on Industrial Electronics, vol. 56, no. 4, pp. 1057-165 April 2009.
H. Durr and H. Bouas-Laurent, Eds., Photochromism: molecules and systems, rev. ed ed. Amsterdam; Boston: Elsevier, 2003.
M. Irie, T. Fukaminato, K. Matsuda, and S. Kobatake, “Photochromism of Diarylethene Molecules and Crystals: Memories, Switches, and Actuators,” Chemical Reviews, vol. 114, no. 24, pp. 12 174-12 277, December 2014. [Online]. Available: https://pubs.acs.org/doi/10.1021/cr500249p
P. M. S. Monk, R. J. Mortimer, and D. R. Rosseinsky, Electrochromism and electrochromic devices. Cambridge: Cambridge University Press, 2007, oCLC: 850409784.
S. S. Mirshafieyan and D. A. Gregory, “Electrically tunable perfect light absorbers as color filters and modulators,” Scientific Reports, vol. 8, no. 1, p. 2635 February 2018. [Online]. Available: https://www.nature.com/articles/s41598-018-20879-z
C. R'IOS, M. Stegmaier, P. Hosseini, D. Wang, T. Scherer, C. D. Wright, H. Bhaskaran, and W. H. P. Pernice, “Integrated all-photonic non-volatile multi-level memory,” Nature Photonics, vol. 9, no. 11, pp. 725-732, November 2015. [Online]. Available: https://www.nature.com/articles/nphoton.2015.182
Z. Cheng, C. R'IOS, W. H. P. Pernice, C. D. Wright, and H. Bhaskaran, “On-chip photonic synapse,” Science Advances, vol. 3, no. 9, p. e1700160. [Online]. Available: https://www.science.org/doi/10.1126/sciadv.1700160
V. S. R. S. P. Kumar, P. Sunita, M. Kumar, N. Kumari, V. Karar, and A. L. Sharma, “Design of multiple stop band optical filter using refractive index modulation,” Journal of Optics, vol. 47, no. 1, pp. 35-39, March 2018. [Online]. Available: https://doi.org/10.1007/s12596-017-0430-1
R. R. Willey, Practical Design of Optical Thin Films, Fifth Edition. Lulu.com, January 2018, google-Books-ID: a8WFDwAAQBAJ.
Miles, M. W., & Inc, E. (1994 May 5). Visible spectrum modulator arrays. Retrieved from https://patents.google.com/patent/U.S. Pat. No. 5,835,255A/en
Govil, A., Bita, I., & Gusev, E. (2012). MEMS Display based on Interferometric Modulation Technology. Encyclopedia of Nanotechnology. Springer. doi: 10.1007/978-90-481-9751-4
Kothari, M., Sethi, G., Griffiths, J. C., Khazeni, K., & Inc, Q. M. T. (2008 September 09). Semitransparent/transflective lighted interferometric devices. Retrieved from https://patents.google.com/patent/U.S. Pat. No. 7,848,003B2/en
Surya Ganti, Kasra Khazeni, Jeff Sampsell (2008 March 7). Interferometric modulator in transmission mode. Retrieved from https://patents.google.com/patent/US20090225395A1/en
Kothari, M., & Inc, Q. M. T. (2005 June 03). Analog interferometric modulator device. Retrieved from https://patents.google.com/patent/U.S. Pat. No. 8,008,736B2/en
Seo, J. H., Govil, A., Tung, M.-H., Martin, R. A., & Inc, Q. M. T. (2013 August 28). Systems, devices, and methods for driving an analog interferometric modulator. Retrieved from https://patents.google.com/patent/U.S. Pat. No. 9,305,497B2/en
Amotchkina, T. V. (2013). Analytical estimations for the reference wavelength reflectance and width of high reflection zone of two-material periodic multilayers. Appl. Opt., 52(19), 4590-4595. doi: 10.1364/AO.52.004590
Ramuz, Marc, et al. “Coupling light from an organic light emitting diode (OLED) into a single-mode waveguide: Toward monolithically integrated optical sensors.” J. Appl. Phys., vol. 105, no. 8, 15 Apr. 2009, p. 084508, doi: 10.1063/1.3097276.
Gehring, H., Eich, A., Schuck, C., & Pernice, W. H. P. (2019). Broadband out-of-plane coupling at visible wavelengths. Opt. Lett., 44(20), 5089-5092. doi: 10.1364/OL.44.005089
Genco, A., Giordano, G., Carallo, S., Accorsi, G., Duan, Y., Gambino, S., & Mazzeo, M. (2018). High quality factor microcavity OLED employing metal-free electrically active Bragg mirrors. Org. Electron., 62, 174-180. doi: 10.1016/j.orgel.2018.07.034
Xi, J.-Q., Schubert, M. F., Kim, J. K., Schubert, E. F., Chen, M., Lin, S.-Y., . . . . Smart, J. A. (2007). Optical thin-film materials with low refractive index for broadband elimination of Fresnel reflection. Nat. Photonics, 1(3), 176-179. doi: 10.1038/nphoton.2007.26
Pervak, V., Tikhonravov, A. V., Trubetskov, M. K., Pistner, J., Krausz, F., & Apolonski, A. (2007). Band filters: two-material technology versus rugate. Appl. Opt., 46 (8), 1190-1193. doi: 10.1364/AO.46.001190
Hsu, K. Y. J., Shen, K. S. H., & Chang, Y.-S. (2016). Enhancing the photoresponsivity of bipolar phototransistors for near-infrared detection. Appl. Phys. Lett., 108(3), 031112. doi: 10.1063/1.4940395
Can Huang, Dongni Li, Tiancheng He, Yedong Peng, Wei Zhou, Zhihong Yang, Jianmei Xu, and Qing Wang ACS Photonics 2020 7(11), 3166-3176 DOI: 0.1021/acsphotonics.0c01234
Wolfgang Heni, Yasar Kutuvantavida, Christian Haffner, Heiner Zwickel, Clemens Kieninger, Stefan Wolf, Matthias Lauermann, Yuriy Fedoryshyn, Andreas F. Tillack, Lewis E. Johnson, Delwin L. Elder, Bruce H. Robinson, Wolfgang Freude, Christian Koos, Juerg Leuthold, and Larry R. Dalton ACS Photonics 2017 4(7), 1576-1590 DOI: 10.1021/acsphotonics.7b00224
Haffner, C., Heni, W., Fedoryshyn, Y. et al. All-plasmonic Mach-Zehnder modulator enabling optical high-speed communication at the microscale. Nature Photon 9, 525-528 (2015). https://doi.org/10.1038/nphoton.2015.127
Pariani, G., Castagna, R., Menon, R., Bertarelli, C., & Bianco, A. (2013). Modeling absorbance-modulation optical lithography in photochromic films. Opt. Lett., 38 (16), 3024-3027. doi: 10.1364/OL.38.003024
Bouas-Laurent, H. (Ed.). (1990). Photochromism: Molecules and systems. New York, NY, U.S.A.: Distributors for the U.S. and Canada, Elsevier Science Pub. Co.
Pariani, G., Bianco, A., Castagna, R., & Bertarelli, C. (2011). Kinetics of Photochromic Conversion at the Solid State: Quantum Yield of Dithienylethene-Based Films. The Journal of Physical Chemistry A, 115(44), 12184-12193. https://doi.org/10.1021/jp207210p
Kobatake, S., Yamada, T., Uchida, K., Kato, N., & Irie, M. (1999). Photochromism of 1,2-Bis(2,5-dimethyl-3-thienyl) perfluoro-cyclopentene in a Single Crystalline Phase. Journal of the American Chemical Society, 121(11), 2380-2386.
Linares-Barranco, B., & Serrano-Gotarredona, T. (2009). Memristance can explain Spike-Time-Dependent-Plasticity in Neural Synapses. Nature Precedings, 1-1. https://doi.org/10.1038/npre.2009.3010.1 Marković, D., Mizrahi, A., Querlioz, D., & Grollier, J. (2020). Physics for neuromorphic computing. Nature Reviews Physics, 2 (9), 499-510. https://doi.org/10.1038/s42254-020-0208-2
S. P. Adhikari, M. P. Sah, H. Kim and L. O. Chua, “Three Fingerprints of Memristor,” in IEEE Transactions on Circuits and Systems I: Regular Papers, vol. 60, no. 11, pp. 3008-321 November 2013, doi: 10.1109/TCSI.2013.2256171.
Liu, L. C. (2020). Photocyclization Dynamics of Diarylethene. Chemistry in Action: Making Molecular Movies with Ultrafast Electron Diffraction and Data Science. Springer. doi: 10.1007/978-3-030-54851-3_4

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations

What is claimed is:

1. A photonic device, comprising:
a material layer, wherein a refractive index of the material layer can be modified; and
a microring resonator (MRR), wherein a resonant frequency of the MRR can be tuned by modifying the refractive index of the material layer.

2. The photonic device of claim 1, wherein the material layer comprises a photochromic material.

3. The photonic device of claim 2, wherein the refractive index of the material layer can be modified by optical excitation of the photochromic material.

4. The photonic device of claim 1, wherein the material layer comprises a thermochromic material.

5. The device of claim 4, wherein the refractive index of the material layer can be modified by changing a temperature of the thermochromic material.

6. The photonic device of claim 1, wherein the material layer comprises an electrochromic material.

7. The photonic device of claim 6, wherein the refractive index of the material layer can be modified by changing an electrical field applied to the electrochromic material.

8. The photonic device of claim 1, wherein the MRR has a radius less than 50 μm.

9. The photonic device of claim 3, wherein the optical excitation comprises one or more selected from a group consisting of: visible light, ultraviolet light, and infrared light.

10. The photonic device of claim 1, further comprising a second MRR, wherein a resonant frequency of the second MRR can be tuned by modifying the refractive index of the material layer.

11. The photonic device of claim 10, wherein the resonant frequency of the MRR and the resonant frequency of the second MRR are modified at a same time.

12. The photonic device of claim 10, wherein the resonant frequency of the MRR and the resonant frequency of the second MRR are modified at a different time.

13. The photonic device of claim 1, further comprising a second material layer, wherein a second refractive index of the second material layer can be modified; and
a second MRR, wherein a second resonant frequency of the second MRR can be tuned by modifying the second refractive index of the second material layer.

14. The photonic device of claim 13, wherein the resonant frequency of the MRR and the second resonant frequency of the second MRR are modified at a same time.

15. The photonic device of claim 13, wherein the resonant frequency of the MRR and the second resonant frequency of the second MRR are modified at a different time.

16. The photonic device of claim 1, wherein the material layer is adjacent to the MRR.

17. The photonic device of claim 1, wherein the MRR propagates an optical signal in the photonic device.

18. The photonic device of claim 1, wherein the MRR modulates an optical signal in the photonic device.

19. The photonic device of claim 15, wherein the first material layer and the second material are deposited in a single deposition.

20. A product comprising:
a material layer, wherein a refractive index of the material layer can be modified; and
a microring resonator (MRR), wherein a resonant frequency of the MRR can be tuned by modifying the refractive index of the material layer; and
wherein the product is selected from the group consisting of a flat panel display, a curved display, a computer monitor, a computer, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro-display, a 3-D display, a virtual reality or augmented reality display or device, a vehicle, a video wall comprising multiple displays tiled together, a theater or stadium screen, a light therapy device, and a sign.
